(19) United States
(12) Patent Application Publication
(10) Pub. No.: US 2016/0131976 A1
(43) Pub. Date: May 12, 2016

(54) RESIST COMPOSITION FOR SEMICONDUCTOR MANUFACTURING PROCESS; RESIST FILM, RESIST-COATED MASK BLANKS, PHOTOMASK, AND RESIST PATTERNING METHOD USING SAID RESIST COMPOSITION; ELECTRONIC-DEVICE MANUFACTURING METHOD; AND ELECTRONIC DEVICE

(71) Applicant: FUJIFILM Corporation, Tokyo (JP)

(72) Inventors: Tomotaka TSUCHIMURA, Haibara-gun (JP); Kyouhei SAKITA, Haibara-gun (JP)

(73) Assignee: FUJIFILM Corporation, Tokyo (JP)

(21) Appl. No.: 14/995,356

(22) Filed: Jan. 14, 2016

Related U.S. Application Data
(63) Continuation of application No. PCT/JP2014/066876, filed on Jun. 25, 2014.

(30) Foreign Application Priority Data
Jul. 17, 2013 (JP) 2013-148762

(51) Int. Cl. G03F 7/039; G03F 7/004; G03F 7/32; G03F 1/76; G03F 1/50; G03F 7/20

(52) U.S. Cl. CPC G03F 7/039; G03F 1/50; G03F 7/20; G03F 7/32; G03F 1/76; G03F 7/0045

(57) ABSTRACT

Provided a resist composition for a semiconductor manufacturing process comprising (A) a compound expressed by General Formula (I) below:

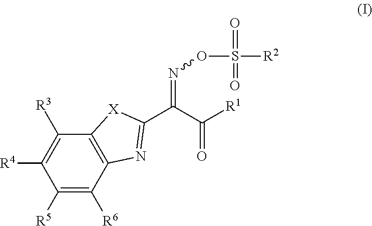

wherein, in General Formula (I) above, R¹ represents an alkyl group, a cycloalkyl group, or an aryl group, R² represents a univalent organic group, each of R³ to R⁶ represents a hydrogen atom, an alkyl group, a cycloalkyl group, an aryl group, or a halogen atom, R³ and R⁴, R⁴ and R⁵, or R⁵ and R⁶ may be bonded to each other to form an alicyclic ring or an aromatic ring, and X represents an oxygen atom or a sulfur atom.

### CROSS REFERENCE TO RELATED APPLICATION

This is a continuation of International Application No. PCT/JP2014/066876 filed on Jun. 25, 2014, and claims priority from Japanese Patent Application No. 2013-148762 filed on Jul. 17, 2013, the entire disclosures of which are incorporated herein by reference.

### BACKGROUND OF THE INVENTION

1. Field of the Invention

The present invention relates to a resist composition for a semiconductor manufacturing process that is suitably used in an ultramicrolithography process or other fabrication processes for manufacturing VLSI or high capacity microchips, or the like and that can form definition-enhanced patterns by using electron beams, extreme ultraviolet rays, or the like, a resist film using the same, a resist-coated mask blank, a photomask, a resist patterning method, an electronic-device manufacturing method, and an electronic device.

2. Description of the Related Art

In micromachining using a resist composition, according to the high integration of an integrated circuit, formation of hyperfine patterns is required. Accordingly, the exposure wavelength tends to become short, from a g line, through an i line, and to exciplex light, and thus, for example, a lithography technique using electron beams has been currently developed.

A resist film which is provided for exposure with exciplex light or electron beams is generally formed with a chemical amplification type resist composition, and various compositions have been developed with respect to photo-acid generators which are a main component of a chemical amplification type resist composition. For example, JP2012-42836A discloses an oxime sulfonic acid ester compound having a heterocyclic structure and an electron-withdrawing group, as an acid generator.

However, in view of overall performances as a resist, it is very difficult to find a suitable combination of a resin, a photo-acid generator, a basic compound, an additive, and a solvent, to be used. Particularly, in view of the current demands for highly efficient formation of ultrafine patterns (for example, line width of 50 nm or lower), this technique is not sufficient.

Particularly, in lithography with electron beams or EUV, the exposure amount is not sufficient, sensitivity improvement is required in order to obtain high productivity, and also high temporal stability is required.

In addition, when a light source such as electron beams, X rays, or EUV is used, since exposure is performed in vacuum, a problem of outgassing in that low boiling point compounds such as solvents and resist materials which are decomposed by high energy are volatilized thereby contaminating an exposure apparatus becomes serious. Recently, with respect to the decrease of outgassing, various studies have been conducted, and thus it is desired to contrive the outgassing decrease with respect to acid generators.

In addition, a resist form after development is influenced depending on substrates such as a coating film (SiO₂, TiN, and Si₃N₃) on a silicon wafer or a chromium oxide on a mask blank, and thus, in order to maintain high resolution or a form after etching, maintaining a pattern profile of a resist to be a rectangle regardless of a type of substrate becomes one of important performances.

In addition, micromachining by a resist composition is not only used for direct manufacturing of an integrated circuit but also applied to manufacturing of a so-called imprint mold structure body and the like, recently (for example, see JP2008-162101A). Therefore, in order to sufficiently respond to these uses, formation of ultrafine patterns (for example, line width of 50 nm or lower) in a state of having high sensitivity and resolving power, small line edge roughness (LER), excellent pattern forms and temporal stability, and decreased generation of outgassing, becomes an important object.

### SUMMARY OF THE INVENTION

For example, the present inventors have found that an oxime sulfonic acid ester compound disclosed in JP2012-42836A as an acid generator has low sensitivity and deteriorated preservation stability.

In view of the problems described above in the related art, an object of the invention is to provide a resist composition for a semiconductor manufacturing process having high sensitivity and resolving power, small line edge roughness (LER), an excellent pattern form, excellent temporal stability, and decreased generation of outgassing, when ultrafine patterns (for example, line width of 50 nm or less) are formed.

Another object of the invention is to provide a resist film, a resist-coated mask blank, a photomask, a resist patterning method, an electronic-device manufacturing method, and an electronic device which use the resist composition for a semiconductor manufacturing process described above.

The present inventors of the invention have diligently researched in order to find that the objects described above are achieved by a resist composition for a semiconductor manufacturing process containing an acid generator having a specific structure and have realized the invention based on this knowledge.

That is, the invention is as follows.

A resist composition for a semiconductor manufacturing process including:

(A) a compound expressed by General Formula (I) below:

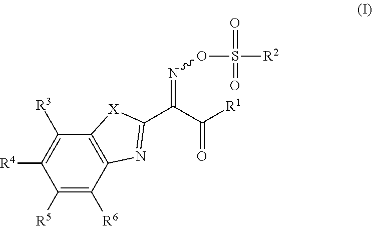

wherein, in General Formula (I) above,

R¹ represents an alkyl group, a cycloalkyl group, or an aryl group, RR represents a univalent organic group, each of R³ to R⁶ represents a hydrogen atom, an alkyl group, a cycloalkyl group, an aryl group, or a halogen atom. R³ and R⁴, R⁴ and R⁵, or R⁵ and R⁶ are bonded to each other to form an alicyclic ring or an aromatic ring, and X represents an oxygen atom (—O—) or a sulfur atom (-s-).

[2]

The resist composition for a semiconductor manufacturing process according to [1], in which R¹ represents an alkyl group having 3 to 10 carbon atoms, a cycloalkyl group having 3 to 10 carbon atoms, and an aryl group having 6 to 12 carbon atoms.

[3]

The resist composition for a semiconductor manufacturing process according to [1] or [2], in which R¹ represents an alkyl group having a branch structure, a cycloalkyl group, or a phenyl group.

[4]

The resist composition for a semiconductor manufacturing process according to any one of [1] to [3], further including: (P) a compound having a phenolic hydroxy group.

[5]

The resist composition for a semiconductor manufacturing process according to any one of [1] to [4], in which the compound (P) is a resin having a repeating unit expressed by General Formula (1) below:

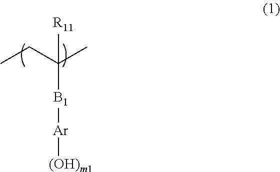

where, in General Formula (1) above, R₁₁ represents a hydrogen atom, a methyl group, or a halogen atom, B₁ represents a single bond or a bivalent linking group, Ar represents an aromatic ring, and m1 represents an integer of 1 or greater.

The resist composition for a semiconductor manufacturing process according to any one of [1] to [5], further including: (C) an acid crosslinking compound.

The resist composition for a semiconductor manufacturing process according to [6], in which the compound (C) includes 2 or more of hydroxymethyl groups or alkoxymethyl groups in a molecule.

[8]

The resist composition for a semiconductor manufacturing process according to any one of [1] to [7], in which the resist composition is for exposure with electron beams or extreme ultraviolet rays.

[9]

A resist film which is formed of the resist composition for a semiconductor manufacturing process according to any one of [1] to [8].

[10]

A resist-coated mask blank which is coated with the resist film according to [9].

[11]

A photomask obtained by exposing and developing the resist-coated mask blank according to [10].

[12]

A resist patterning method including: a step of exposing the resist film according to [9]; and a step of developing the exposed film.

[13]

A resist patterning method including: a step of exposing the resist-coated mask blank according to [10]; and a step of developing the exposed mask blank.

[14]

An electronic-device manufacturing method comprising:

the resist patterning method according to [12] or [13].

[15]

An electronic device manufactured by the electronic-device manufacturing method according to [14].

The invention preferably further includes following configurations.

[16]

The resist composition for a semiconductor manufacturing process according to any one of [1] to [8], in which the compound (A) expressed by General Formula (I) above is a compound that generates an acid having a volume of 240 Å³ or greater by irradiation of active rays or radial rays.

[17]

The resist composition for a semiconductor manufacturing process according to any one of [1] to [8], in which the compound (A) expressed by General Formula (I) is a compound that generates a sulfonic acid expressed by General Formula (SA1) or (SA2) below, by irradiation of active rays or radial rays.

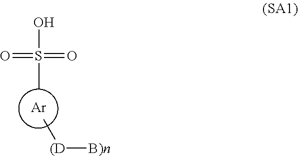

In General Formula (SA1) above.

Ar represents an (n+1)-valent aromatic ring, and may further has a substituent in addition to a sulfonic acid group and n items of -(D-B) groups in the general formula above.

n represents an integer of 0 or greater.

D represents a single bond or a bivalent linking group. When there are plural D's, the plural D's may be identical to or different from each other.

B represents a hydrocarbon group. When there are plural B's, the plural B's may be identical to or different from each other.

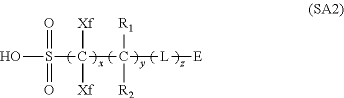

In General Formula (SA2) above,

each of Xf independently represents a fluorine atom, or an alkyl group that is substituted with at least one fluorine atom.

Each of R₁ and R₂ independently represents a hydrogen atom, a fluorine atom, or an alkyl group. When there are plural R₁'s and plural R₂'s, the plural R₁'s and the plural R₂'s may be identical to or different from each other.

L represents a bivalent linking group. When there are plural L's, the plural L's may be identical to or different from each other.

E represents a cyclic organic group.

x represents an integer of 1 to 20, y represents an integer of 0 to 10, and z represents an integer of 0 to 10.

[18]

The resist composition for a semiconductor manufacturing process according to [5], in which the compound (P) is a resin having a repeating unit represented by General Formula (A) below.

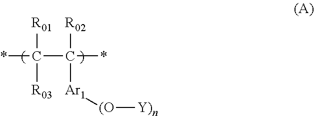

In the formula, each of R₀₁, R₀₂, and R₀₃ independently represents a hydrogen atom, an alkyl group, a cycloalkyl group, a halogen atom, a cyano group, or an alkoxycarbonyl group. Ar₁ represents an aromatic ring group. R₀₃ and Ar₁ are alkylene groups, and both may be bonded to each other, so as to form a 5-membered or 6-membered ring, together with a —C—C— chain.

Each of Y's independently represents a structure expressed by General Formula (B) below.

n represents an integer of 1 to 4.

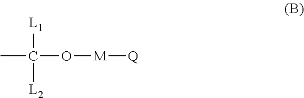

In the formula, each of L₁ and L₂ independently represents a hydrogen atom, an alkyl group, a cycloalkyl group, an aryl group, or an aralkyl group.

M represents a single bond or a bivalent linking group.

Q represents an alkyl group, a cycloalkyl group, an alicyclic group, an aromatic ring group, an amino group, an ammonium group, a mercapto group, a cyano group, or an aldehyde group. In addition, these alicyclic groups and aromatic ring groups may include hetero atoms.

In addition, 2 or more of Q, M, and L₁ may be bonded to each other, so as to form a 5-membered or 6-membered ring.

According to the invention, it is possible to provide a resist composition for a semiconductor manufacturing process having high sensitivity and resolving power, small LER, excellent pattern forms and temporal stability, and decreased generation of outgassing, in forming an ultrafine pattern (for example, line width of 50 nm or less).

In addition, according to the invention, it is possible to provide a resist film, a resist-coated mask blank, a photomask, a resist patterning method, an electronic-device manufacturing method, and an electronic device, which use the resist composition for the semiconductor manufacturing process.

### DESCRIPTION OF THE PREFERRED EMBODIMENTS

Hereinafter, detailed descriptions of the invention are specifically provided.

In addition, in the description of a group (atomic group) in this specification, a description of not indicating substitution or unsubstitution includes a group not having a substituent together with a group having a substituent. For example an “alkyl group” includes not only an alkyl group (unsubstituted alkyl group) not having a substituent but also an alkyl group (substituted alkyl group) having a substituent.

According to the invention, for example, “active rays” or “radial rays” refer to far ultraviolet rays represented by a bright line spectrum of a mercury lamp and an exciplex laser, extreme ultraviolet rays (EUV rays), X rays, and electron beams (EB). In addition, according to the invention, “light” refers to active rays or radial rays. According to the invention, unless described otherwise. “exposure” includes not only exposure by far ultraviolet rays represented by a mercury lamp and an exciplex laser, X rays, and EUV rays but also drawing by particle beams such as electron beams and ion beams.

The resist composition for the semiconductor manufacturing process according to the invention contains (A) a compound expressed by General Formula (I) below.

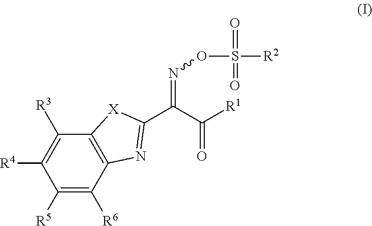

In General Formula (I) above,

R¹ represents an alkyl group, a cycloalkyl group, or an aryl group, and R² represents a univalent organic group. Each of R³ to R⁶ represents a hydrogen atom, an alkyl group, a cycloalkyl group, an aryl group, or a halogen atom. However, R³ and R⁴, R⁴ and R⁵, or R⁵ and R⁶ may be bonded to each other to form an alicyclic ring or an aromatic ring. X represents an oxygen atom (—O—) or a sulfur atom (—S—).

According to the invention, the resist composition for the semiconductor manufacturing process refers to an active ray sensitive or radial ray sensitive resist composition used in the process of manufacturing a semiconductor device.

The reason why the resist composition for the semiconductor manufacturing process according to the invention has high sensitivity and resolving power, less LER, excellent pattern forms and temporal stability, and decreased generation of outgassing, in the formation of ultrafine patterns according to the configuration described above (for example, line width of 50 nm or less) is not clear, but it is assumed as follows.

The oxime sulfonic acid ester compound expressed by General Formula (I) has a structure having a specific condensed heterocyclic structure including X and C(═O)R¹ as an electron-withdrawing group, and thus has high decomposition efficiency (acid generation efficiency) and contributes to sensitivity and resolving power. In addition, it is assumed that the oxine sulfonic acid ester compound above has excellent temporal stability and decreased generation of outgassing at the time of acid generation, by this structure.

In addition, it is assumed that an ionic acid generator in the related art can be adsorbed to an ionic portion of a resin in a resist composition by ionicity thereof such that even dispersion or distribution can be deteriorated, but the oxime sulfonic acid ester compound expressed by General Formula (I) described above has high decomposition efficiency (high acid generation efficiency) and non-ionicity, and thus can be evenly dispersed or distributed, in the resist composition (resist film) so as to contribute to decreasing LER and causing a pattern form to become rectangular.

The resist composition for the semiconductor manufacturing process according to the invention is preferably for exposure with electron beams or extreme ultraviolet rays.

The resist composition for the semiconductor manufacturing process according to the invention may be used as a positive resist composition or may be used as a negative resist composition.

Hereinafter, respective components of the resist composition for the semiconductor manufacturing process are described in detail.

(A) Compound Expressed by General Formula (I)

(A) The compound expressed by General Formula (I) (hereinafter, simply referred to as a “compound (A)”) contained in the resist composition for the semiconductor manufacturing process according to the invention functions as a photo-acid generator.

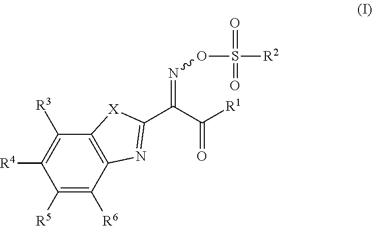

In General Formula (I) above,

R¹ represents an alkyl group, a cycloalkyl group, or an aryl group, and R² represents a univalent organic group. Each of R³ to R⁶ represents a hydrogen atom, an alkyl group, a cycloalkyl group, an aryl group, or a halogen atom. However, R³ and R⁴, R⁴ and R⁵, or R⁵ and R⁶ may be bonded to each other to form an alicyclic or aromatic ring. X represents an oxygen atom or a sulfur atom.

R¹ represents an alkyl group, a cycloalkyl group, or an aryl group. The alkyl group is preferably an alkyl group having a branch structure.

The number of carbon atoms in an alkyl group is preferably 3 to 10. Particularly, if the alkyl group has a branch structure, an alkyl group having 3 to 6 carbon atoms is preferable.

Examples of the alkyl group include a methyl group, an ethyl group, a propyl group, an isopropyl group, an n-butyl group, an s-butyl group, an isobutyl group, a tert-butyl group, a pentyl group, an isopentyl group, a neopentyl group, a 1,1-dimethylpropyl group, a hexyl group, a 1-ethylpentyl group, a 2-ethylhexyl group, and an octyl group, and preferably an isopropyl group, a tert-butyl group, and a neopentyl group.

The number of carbon atoms in a cycloalkyl group is preferably 3 to 10 and more preferably 5 to 7. Examples of the cycloalkyl group include a cyclopentyl group and a cyclohexyl group, and a cyclohexyl group is preferable.

The number of carbon atoms in an aryl group is preferably 6 to 12, more preferably 6 to 8, and still more preferably 6 or 7. Examples of the aryl group include a phenyl group and a naphthyl group, and the aryl group is preferably a phenyl group.

An alkyl group, a cycloalkyl group, and an aryl group represented by R¹ may have substituents. Examples of the substituent include a halogen atom (a fluorine atom, a chloro atom, a bromine atom, or an iodine atom), a straight chain or branched alkyl group (for example, a methyl group, an ethyl group, or a propyl group), a cycloalkyl group (a cyclohexyl group and the like), an alkenyl group, an alkynyl group, an aryl group, an acyl group, an alkoxycarbonyl group, an aryloxycarbonyl group, a carbamoyl group, a cyano group, a carboxyl group, a hydroxy group, an alkoxy group, an aryloxy group, an alkylthio group, an arylthio group, a heterocyclic oxy group, an acyloxy group, an amino group, a nitro group, a hydrazino group, and a heterocyclic group. In addition, the substituent may be further substituted with these groups. The substituent is preferably a halogen atom or a methyl group.

In view of compatibility between sensitivity and temporal stability, with respect to the resist composition for the semiconductor manufacturing process according to the invention, R¹ is preferably an alkyl group having 3 to 10 carbon atoms, a cycloalkyl group having 3 to 10 carbon atoms, or an aryl group having 6 to 12 carbon atoms, more preferably a branched alkyl group having 3 to 6 carbon atoms, a cycloalkyl group having 5 to 7 carbon atoms, or a phenyl group, and still more preferably a branched alkyl group having 3 to 6 carbon atoms, or a cycloalkyl group having 5 to 7 carbon atoms. If these bulky groups (particularly, bulky alkyl group or cycloalkyl group) are employed as R¹, transparency can be further improved.

Among the bulky groups, an isopropyl group, a tert-butyl group, a neopentyl group, and a cyclohexyl group are preferable, and a tert-butyl group and a cyclohexyl group are more preferable.

Examples of the univalent organic group with respect to R² include an alkyl group, a cycloalkyl group, an aryl group, and a heteroaryl group.

As the alkyl group expressed by the univalent organic group R², a straight chain or branched alkyl group having 1 to 10 carbon atoms is preferable. Examples of the alkyl group include a methyl group, an ethyl group, a propyl group, an isopropyl group, an n-butyl group, a tert-butyl group, a pentyl group, a neopentyl group, a hexyl group, and a cyclohexyl group.

The cycloalkyl group with respect to the univalent organic group R² may have a carbonyl group as a ring member and the number of carbon atoms having a cycloalkyl group is preferably 3 to 20 and more preferably 5 to 15. Examples of the cycloalkyl group include a cyclopentyl group, a cyclohexyl group, an adamantyl group, a norbornyl group, and a 7,7-dimethylbicyclo[2.2.1]heptanone group.

As the aryl group with respect to the univalent organic group R², an aryl group having 6 to 1.0 carbon atoms is preferable. Examples of the aryl group include a phenyl group, a naphthyl group, and a p-toluyl group (p-methylphenyl group), and is preferably a phenyl group and a p-toluyl group.

Examples of the heteroaryl group with respect to the univalent organic group R² include a pyrrole group, an indole group, a carbazole group, a furan group, and a thiophene group.

The alkyl group, the cycloalkyl group, the aryl group, and the heteroaryl group expressed by the univalent organic group R² may have substituents. Examples of the substituent include a halogen atom (a fluorine atom, a chloro atom, a bromine atom, and an iodine atom), a straight chain or branched alkyl group (for example, a methyl group, an ethyl group, an n-propyl group, an isopropyl group, and a t-butyl group), a cycloalkyl group (a cyclohexyl group and an adamantyl group), a cycloalkylcarbonyloxy group, a cycloalkyloxycarbonyl group, a cycloalkylalkyloxycarbonyl group (an adamantylmethyloxycarbonyl group), a 7,7-dimethylbicyclo[2.2.1]heptanone group, a decahydroisoquinolinesulfonyl group, an alkenyl group, an alkynyl group, an aryl group, an acyl group, an alkoxycarbonyl group, an aryloxycarbonyl group, a carbamoyl group, a cyano group, a carboxyl group, a hydroxy group, an alkoxy group, an aryloxy group, an alkylthio group, an arylthio group, a heterocyclic oxy group, an acyloxy group, an amino group, a nitro group, a hydrazino group, and a heterocyclic group. In addition, the substituent may be further substituted with these groups. Particularly, the substituent is preferably a bulky group such as a branched alkyl group, a cycloalkyl group, a cycloalkylcarbonyloxy group, a cycloalkyloxycarbonyl group, a cycloalkylalkyloxycarbonyl group, a 7,7-dimethylbicyclo[2.2.1]heptanone group, and a decahydroisoquinolinesulfonyl group. If R² has such a substituent, it is possible to control diffusion, of a generated acid, enhance resolving power, decrease LER, and improve a pattern form. In addition in view of sensitivity improvement, the substituent is preferably a fluorine atom.

R² is more preferably an alkyl group, a cycloalkyl group, or an aryl group, still more preferably an aryl group, and particularly preferably a phenyl group.

The compound (A) expressed by General Formula (I) above can generate an acid (a sulfonic acid) expressed by General Formula(s) below, by irradiation with active rays or radial rays.

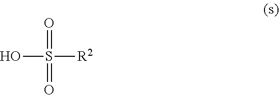

In General Formula (s) above, R² represents the same as R² in General Formula (I) above.

According to the invention, in view of controlling diffusion of the acid generated by exposure to an unexposed portion and causing resolution (resolving power, LER, and pattern form) to become satisfactory, the compound (A) expressed by General Formula (I) above is preferably a compound that generates an acid having a volume of 240 Å³ or greater by the irradiation of the active rays or the radial rays, more preferably a compound that generates an acid having a volume of 300 Å³ or greater, still more preferably a compound that generates an acid having a volume of 350 Å³ or greater, and particularly preferably a compound that generates an acid having a volume of 400 Å³ or greater. However, in view of the sensitivity and solubility of a coating solvent, the volume is preferably 2,000 Å³ or lower and still more preferably 1,500 Å³ or lower. The value of the volume can be obtained by using “WinMOPAC” manufactured by Fujitsu. It is possible to calculate “accessible volumes” of respective acids by inputting chemical structures of acids according to respective examples, determining the most stable conformation of the respective acids by molecular field calculation using an MM3 method with this structure as an initial structure, and then performing a molecular orbital calculation by using a PM3 method with respect to this most stable conformation.

In addition, as the sulfonic acid expressed by General Formula(s) that can be generated by the compound (A), a sulfonic acid expressed by General Formula (SA1) or (SA2) is preferable.

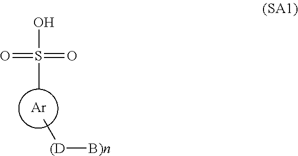

In General Formula (SA1) above,

Ar represents an (n+1)-valent aromatic ring, and may further have a substituent in addition to a sulfonic acid group and n items of -(D-B) groups in the general formulae above.

n represents an integer of 0 or greater.

D represents a single bond or a bivalent linking group. When there are plural D's, plural D's may be identical to or different from each other.

B represents a hydrocarbon group. When there are plural B's, the plural B's may be identical to or different from each other.

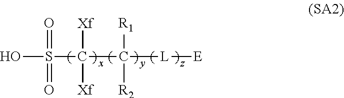

In General Formula (SA2) above,

each of Xf independently represents a fluorine atom or an alkyl group substituted with at least one fluorine atom.

Each of R₁ and R₂ independently represents a hydrogen atom, a fluorine atom, or an alkyl group. When there are plural R₁'s and plural R₂'s, the plural R₁'s and the plural R₂'s may be identical to or different from each other.

L represents a bivalent linking group. When there are plural L's, the plural L's may be identical to or different from each other.

E represents a cyclic organic group.

x represents an integer of 1 to 20, y represents an integer of 0 to 10, and z represents an integer of 0 to 10.

First, the sulfonic acid expressed by General Formula (SA1) is described in detail.

In General Formula (SA1) above, Ar is preferably an aromatic ring having 6 to 30 carbon atoms. Specific examples of Ar includes a benzene ring, a naphthalene ring, a pentalene ring, an indene ring, an azulene ring, a heptalene ring, an indesen ring, a perylene ring, a pentacene ring, an asetafutaren ring, a phenanthrene ring, an anthracene ring, a naphthacene ring, a chrysene ring, a triphenylene ring, a fluorene ring, a biphenyl ring, a pyrrole ring, a furan ring, a thiophene ring, an imidazole ring, an oxazole ring, a thiazole ring, a pyridine ring, a pyrazine ring, a pyrimidine ring, a pyridazine ring, an indolizine ring, an indole ring, a benzofuran ring, a benzothiophene ring, an isobenzofuran ring, a quinolizine ring, a quinoline ring, a phthalazine ring, a naphthyridine ring, a quinoxaline ring, a quinoxazoline ring, an isoquinoline ring, a carbazole ring, a phenanthridine ring, an acridine ring, a phenanthroline ring, a thianthrene ring, a chromene ring, a xanthene ring, a phenoxathiin ring, a phenothiazine ring, and a phenazine ring. Among them, in view of compatibility between improvement of roughness (LER) and sensitivity improvement, a benzene ring, a naphthalene ring, or an anthracene ring is preferable, and a benzene ring is more preferable.

If Ar further has a substituent in addition to the sulfonic acid group and n items of -(D-B) groups in the general formula above, examples of the substituent include a halogen atom such as a fluorine atom, a chlorine atom, a bromine atom, and an iodine atom; a hydroxy group; a carboxy group; and a sulfonic acid group.

In General Formula (SA1) above, n is preferably 1 to 4, more preferably 2 to 3, and most preferably 3.

In General Formula (SA1) above, examples of the bivalent linking group with respect to D include an alkylene group, an ether bond, a thioether bond, a carbonyl group, a sulfoxide group, a sulfonyl group, a sulfonic acid ester bond, and an ester bond, and a group obtained by combining 2 or more types of these groups or bonds.

In General Formula (SA1) above, D is preferably a single bond, an ether bond, or an ester bond. D is more preferably a single bond.

In General Formula (SA1) above,

examples of the hydrocarbon group B include an alkyl group (preferably, an alkyl group having 1 to 20 carbon atoms), a cycloalkyl group (preferably, a cycloalkyl group having 3 to 20 carbon atoms), an alkenyl group (preferably, an alkenyl group having 2 to 20 carbon atoms), an alkynyl group (preferably, an alkynyl group having 2 to 2) carbon atoms), and an aryl group (preferably, an aryl group having 6 to 30 carbon atoms).

The hydrocarbon group B is preferably an aliphatic hydrocarbon group, more preferably an alkyl group or a cycloalkyl group, and still more preferably a cycloalkyl group.

The alkyl group as the hydrocarbon group B is preferably a branched alkyl group. Examples of the branched alkyl group includes an isopropyl group, a tert-butyl group, a tert-pentyl group, a neopentyl group, a sec-butyl group, an isobutyl group, an isohexyl group, a 3,3-dimethylpentyl group, and a 2-ethylhexyl group.

The cycloalkyl group as the hydrocarbon group B may be a monocyclic cycloalkyl group or may be a polycyclic cycloalkyl group. Examples of the monocyclic cycloalkyl group include a cyclopropyl group, a cyclobutyl group, a cyclopentyl group, a cyclohexyl group, a cycloheptyl group, and a cyclooctyl group. Examples of the polycyclic cycloalkyl group include an adamantyl group, a norbornyl group, a bornyl group, a camphenyl group, a decahydronaphthyl group, a tricyclodecanyl group, a tetracyclodecanyl group, a camphoroyl group, a dicyclohexyl group, and a pinenyl group.

Examples of the alkenyl group as the hydrocarbon group B include a vinyl group, a propenyl group, and a hexenyl group.

Examples of the alkynyl group as the hydrocarbon group B include a propynyl group and a hexynyl group.

Examples of the aryl group as the hydrocarbon group B include a phenyl group and a p-tolyl group.

The alkyl group, the alkenyl group, the alkynyl group, the aryl group or the cycloalkyl group as the hydrocarbon group B may have substituents. Examples of the substituent include the following. That is, examples of the substituent include a halogen atom such as a fluorine atom, a chlorine atom, a bromine atom, and an iodine atom, an alkoxy group such as a methoxy group, an ethoxy group, and a tert-butoxy group; an aryloxy group such as a phenoxy group and a p-tolyloxy group; an alkylthioxy group such as a methylthioxy group, an ethylthioxy group, and a tert-butylthioxy group; an arylthioxy group such as a phenylthioxy group and a p-tolylthioxy group; an alkoxycarbonyl group such as a methoxycarbonyl group, a butoxycarbonyl group, and a phenoxycarbonyl group; an acetoxy group; a straight chain alkyl group such as a methyl group, an ethyl group, a propyl group, a butyl group, a heptyl group, a hexyl group, a dodecyl group, and a 2-ethylhexyl group; a branched alkyl group; a cycloalkyl group such as a cyclohexyl group; an alkenyl group such as a vinyl group, a propenyl group, and a hexenyl group; an alkynyl group such as an acetylene group; a propynyl group, and a hexynyl group; an aryl group such as a phenyl group and a tolyl group; a hydroxy group; a carboxy group; a sulfonic acid group; and a carbonyl group. Among these, in view of compatibility of roughness enhancement and sensitivity improvement, a straight chain alkyl group and a branched alkyl group are preferable.

Subsequently, a sulfonic acid expressed by General Formula (SA2) above is described in detail.

In General Formula (SA2) above, Xf represents a fluorine atom, or an alkyl group substituted with at least one fluorine atom. As the alkyl group, an alkyl group, an alkyl group having 1 to 10 carbon atoms is preferable, and an alkyl group having 1 to 4 carbon atoms is more preferable. In addition, an alkyl group substituted with a fluorine atom is preferably a perfluoroalkyl group.

Xf preferably represents a fluorine atom or a perfluoroalkyl group having 1 to 4 carbon atoms. Specifically, Xf preferably represents a fluorine atom, CF₃, C₂F₅, C₃F₇, C₄F₉, C₅F₁₁, CF₃F₁₃, C₇F₁₅, C₈F₁₇, CH₂CF₃, CH₂CH₂CF₃, CH₂C₂F₅, CH₂CH₂C₂F₅, CH₂C₃F₇, CH₂CH₂C₃F₇, CH₂C₄F₉, or CH₂CH₂C₄F₉. Among these, a fluorine atom or CF₃ is preferable, and a fluorine atom is most preferable.

In General Formula (SA2) above, each of R₁ and R₂ independently represents a hydrogen atom, a fluorine atom, or an alkyl group. The alkyl group may have a substituent (preferably, a fluorine atom) and is preferably a substituent having 1 to 4 carbon atoms. As the alkyl group that may have substituents of R₁ and R₂, a perfluoroalkyl group having 1 to 4 carbon atoms is particularly preferable. Specifically, examples of the alkyl group having substituents of R₁ and R₂ include, CF₃, C₂F₅, C₃F₇, C₄F₉, C₅F₁₁, C₆F₁₃, C₇F₁₅, C₈F₁₇, CH₂CF₃, CH₂CH₂CF₃, CH₂C₂F₅, CH₂CH₂C₂F₅, CH₂C₃F₇, CH₂CH₂C₃F₇, CH₂CH₄F₉, and C₂CH₂C₄F₉. Among these. CF₃ is preferable.

In General Formula (SA2) above, x preferably represents 1 to 8 and more preferably represents 1 to 4. y preferably represents 0 to 4 and more preferably represents 0. z preferably represents 0 to 8 and more preferably represents 0 to 4.

In General Formula (SA2) above, L represents a single bond or a bivalent linking group. Examples of the bivalent linking group include —COO—, —OCO—, —CO—, —O—, —S—, —SO—, —SO₂—, an alkylene group, a cycloalkylene group, and an alkenylene group, or a combination of 2 or more types of these groups. Among these, a group of which the total number of carbon atoms is 20 or less is preferable. Among these, —COO—, —OCO—, —CO—, —O—, —S—, —SO—, or —SO₂— is preferable, and —COO—, —OCO—, or —SO₂— is more preferable.

In General Formula (SA2) above, E represents a cyclic organic group. Examples of E include an alicyclic group, an aryl group, and a heterocyclic ring group.

The alicyclic group as E is preferably an alicyclic group of which the total number of carbon atoms is preferably 20 or less, may have a monocyclic structure, and may have a polycyclic structure. As the alicyclic group having a monocyclic structure, a monocyclic cycloalkyl group such as a cyclopentyl group, a cyclohexyl group, and a cyclooctyl group is preferable. As the alicyclic group having a polycyclic structure, a polycyclic cycloalkyl group such as a norbornyl group, a tricyclodecanyl group, a tetracyclodecanyl group, a tetracyclododecanyl group, and an adamantyl group is preferable. Particularly, if an alicyclic group having a bulky structure of a 6 or more-membered ring is employed as E, diffusion properties of a film in a post exposure baking (PEB) step are suppressed and thus resolving power is further improved, such that LER can be caused to be further satisfactory.

The total number of carbon atoms of the aryl group as E is preferably is 20 or less, and examples thereof include a benzene ring, a naphthalene ring, a phenanthrene ring, or an anthracene ring.

A heterocyclic ring group as E of which the total number of carbon atoms is 20 or less is preferable, and may have aromatic properties or may not have aromatic properties. As a hetero atom included in this group, a nitrogen atom or an oxygen atom is preferable. Specific examples of the heterocyclic ring structure include a furan ring, a thiophene ring, a benzofuran ring, a benzothiophene ring, a dibenzofuran ring, a dibenzotihiophene ring, a pyridine ring, a piperidine ring, and a morpholine ring. Among these, a furan ring, a thiophene ring, a pyridine ring, a piperidine ring, and a morpholine ring are preferable.

E may have a substituent. Examples of the substituent include an alkyl group (may be any one of a straight chain shape a branched shape, and a cyclic shape, and preferably has 1 to 12 carbon atoms), an aryl group (preferably has 6 to 14 carbon atoms), a hydroxy group, an alkoxy group, an ester group, an amide group, a urethane group, a ureido group, a thioether group, a sulfoneamide group, and a sulfonic acid ester group.

Hereinafter, specific examples and volume values of an acid that the compound (A) generates due to irradiation of active rays or radial rays are provided, but the invention is not limited thereto.

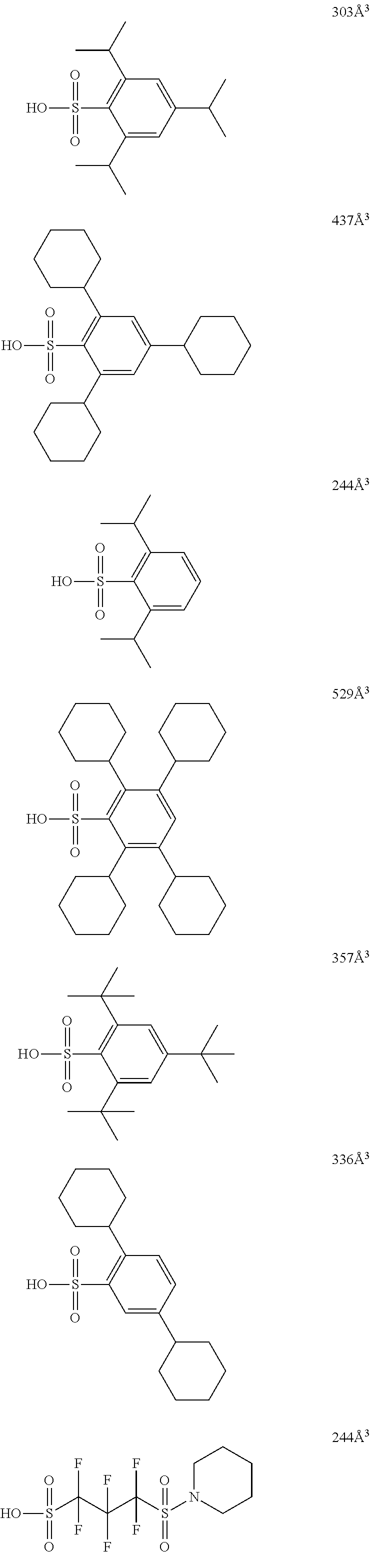

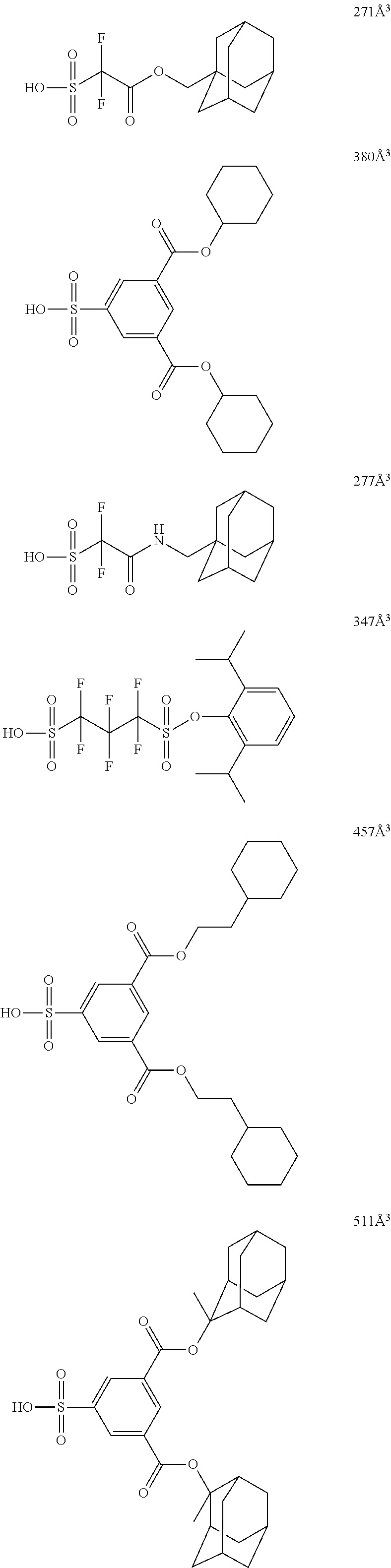

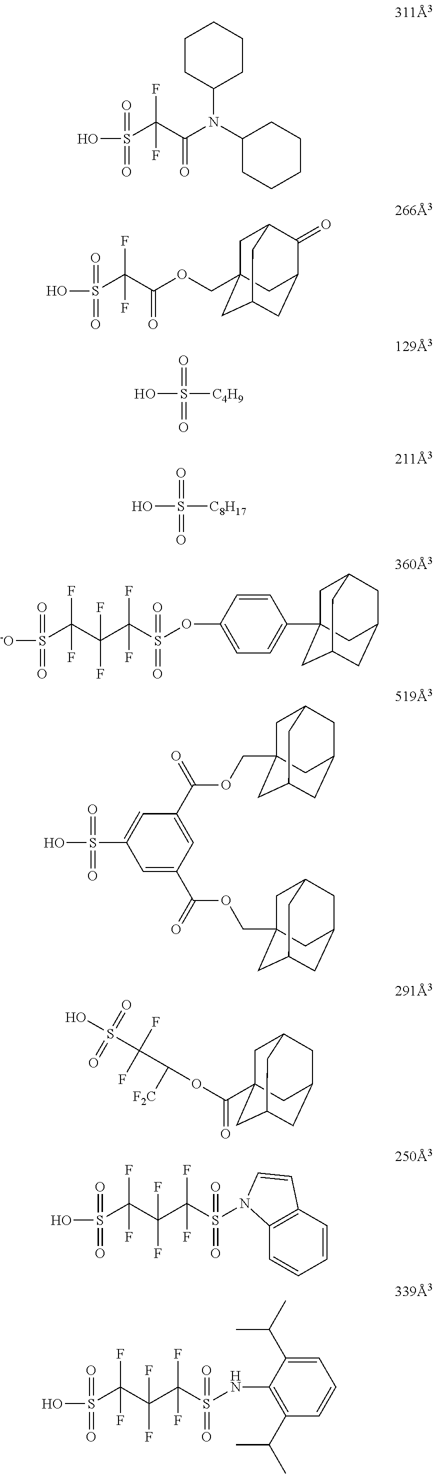

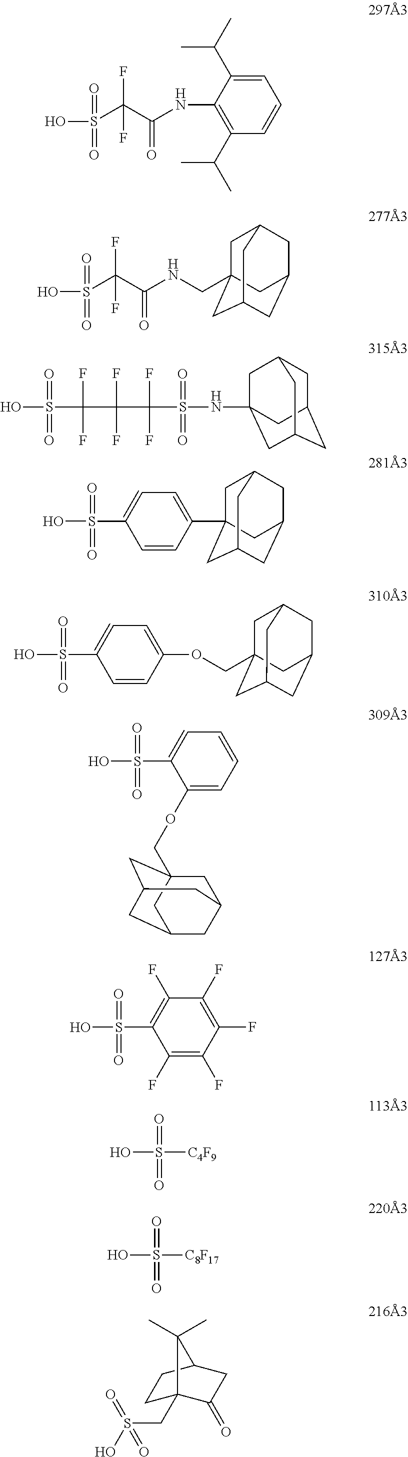

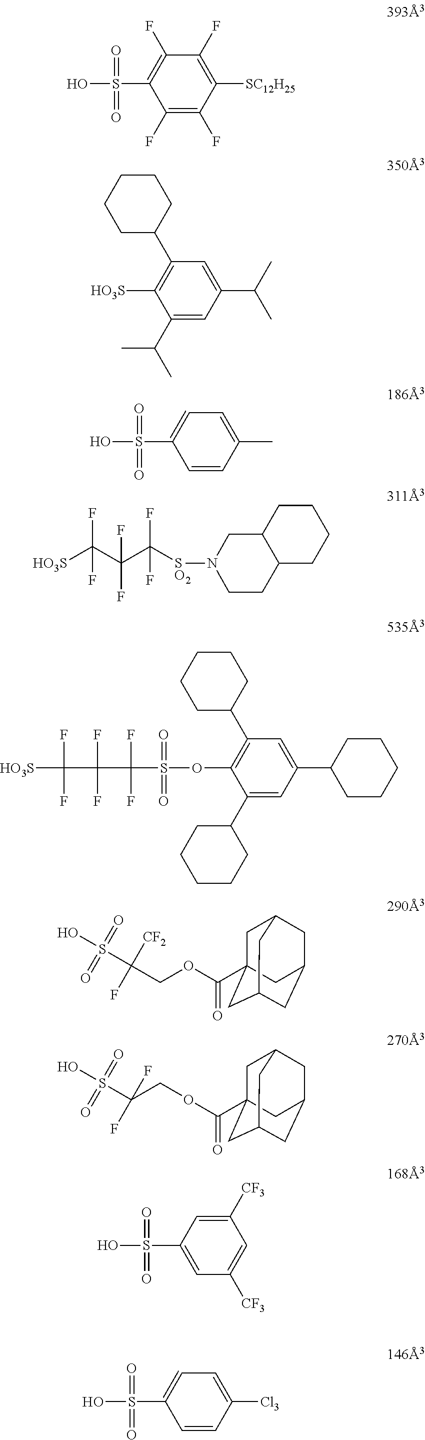

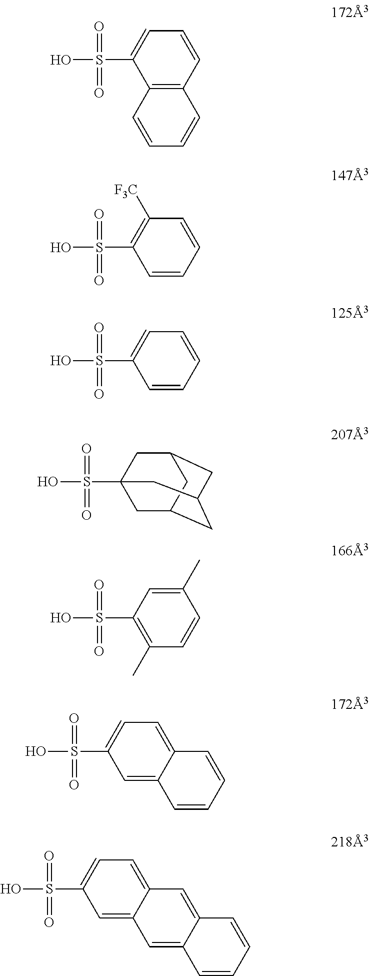

Each of R³ to R⁶ represents a hydrogen atom, an alkyl group, a cycloalkyl group, an aryl group, or a halogen atom (for example, a fluorine atom, a chloro atom, a bromine atom, or an iodine atom). Each of the alkyl groups and the cycloalkyl groups represented by R³ to R⁶ represents the same alkyl group and the same cycloalkyl group represented by R², and preferable ranges thereof are also the same. In addition, the aryl groups represented by R³ to R⁶ represent the same aryl group represented by R¹, and preferable ranges thereof are also the same.

Among R³ to R⁶, R³ and R⁴, R⁴ and R⁵, or R⁵ and R⁶ may be bonded to each other to form a ring. As the ring, an alicyclic or aromatic ring is preferably formed, and a benzene ring is more preferable.

It is preferably that R³ to R⁶ are hydrogen atoms, alkyl groups, and halogen atoms (fluorine atoms, chloro atoms, and bromine atoms), or R³ and R⁴, R⁴ and R⁵, or R⁵ and R⁶ are bonded to each other to form a benzene ring, and it is more preferable that R³ to R⁶ are hydrogen atoms, methyl groups, fluorine atoms, chloro atoms, or bromine atoms, or R³ and R⁴, R⁴ and R⁵, or R⁵ and R⁶ are bonded to each other to form a benzene ring.

Preferable aspects of R³ to R⁶ are as below.

(Aspect 1) At least 2 of R³ to R⁶ are hydrogen atoms.

(Aspect 2) The number of the alkyl groups, the cycloalkyl groups, the aryl groups, and the halogen atoms is 3 or less in total. 1 or less is preferable.

(Aspect 3) R³ and R⁴, R⁴ and R⁵, or R⁵ and R⁶ are bonded to each other to form a benzene ring.

(Aspect 4) An aspect in which Aspects 1 and 2 are satisfied, and/or an aspect in which Aspects 1 and 3 are satisfied.

In addition, in the compound (A) expressed by General Formula (I) above, a stereoisomer expressed by General Formula (I-1) or (I-2) below may exist, but the stereoisomer may be any stereoisomer. In addition, one type of stereoisomer may be used singly, or plural stereoisomers may be used in combination.

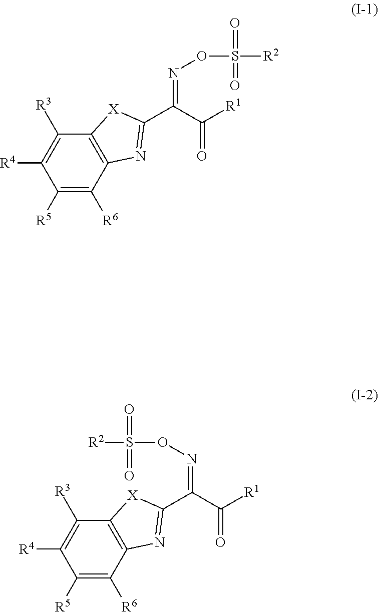

In the formula above, R¹ to R⁶, and X represent the same as R¹ to R⁶, and X expressed by General Formula (I).

Specific examples of the compound (A) expressed by General Formula (I) above include compounds as below, but the invention is not limited thereto. In addition, among the exemplified compounds, Ts represents a tosyl group (p-toluenesulfonyl group), Me represents a methyl group, Bu represents an n-butyl group, and Ph represents a phenyl group.

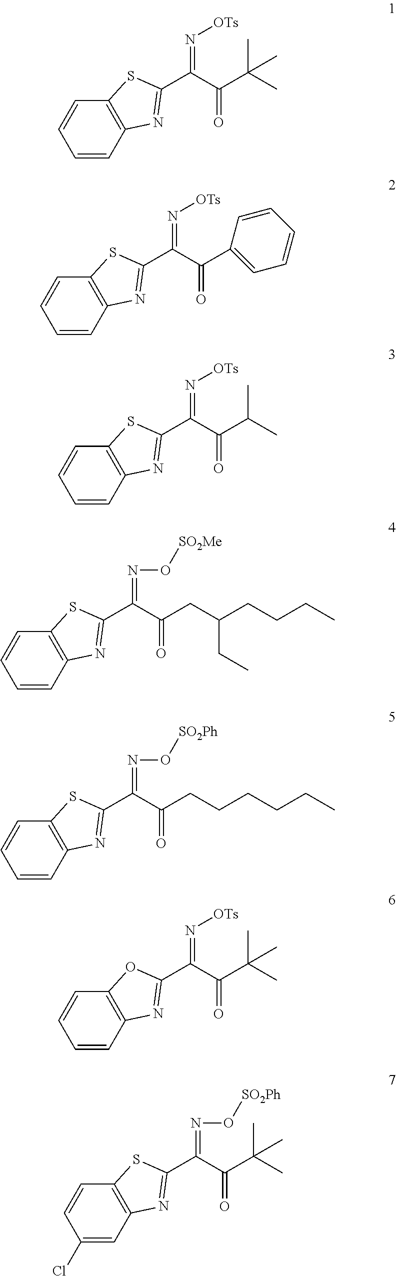

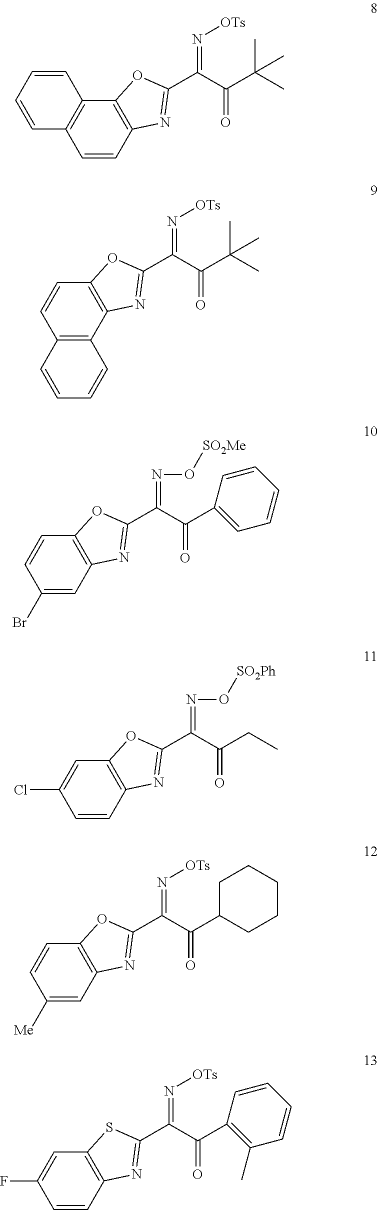

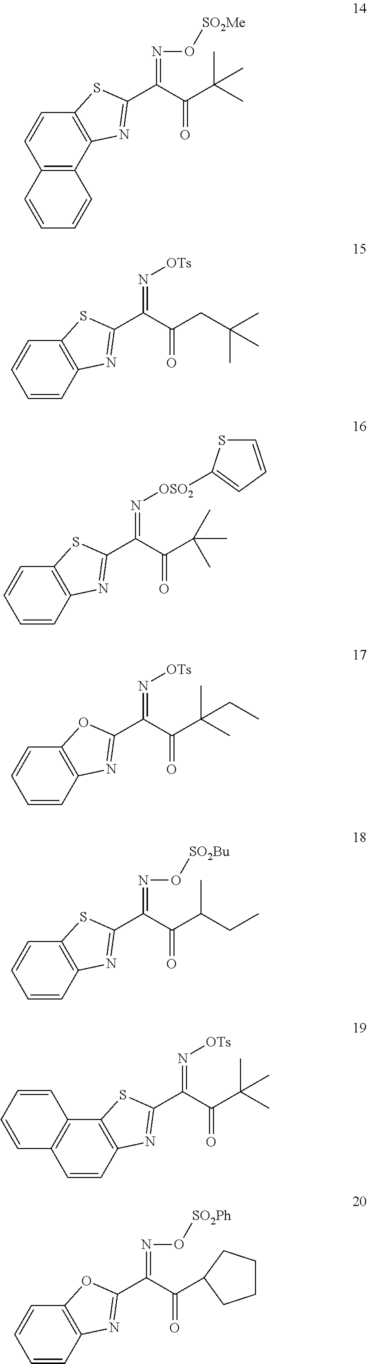

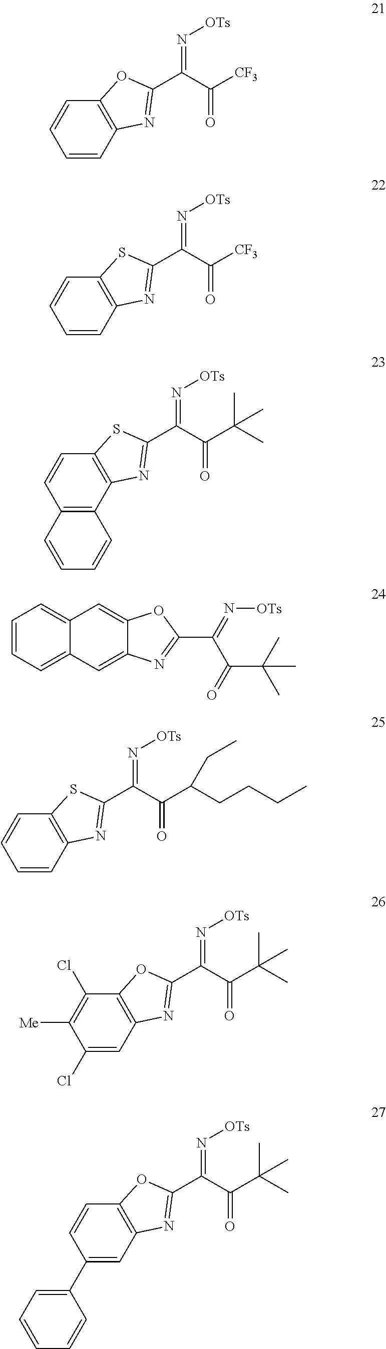

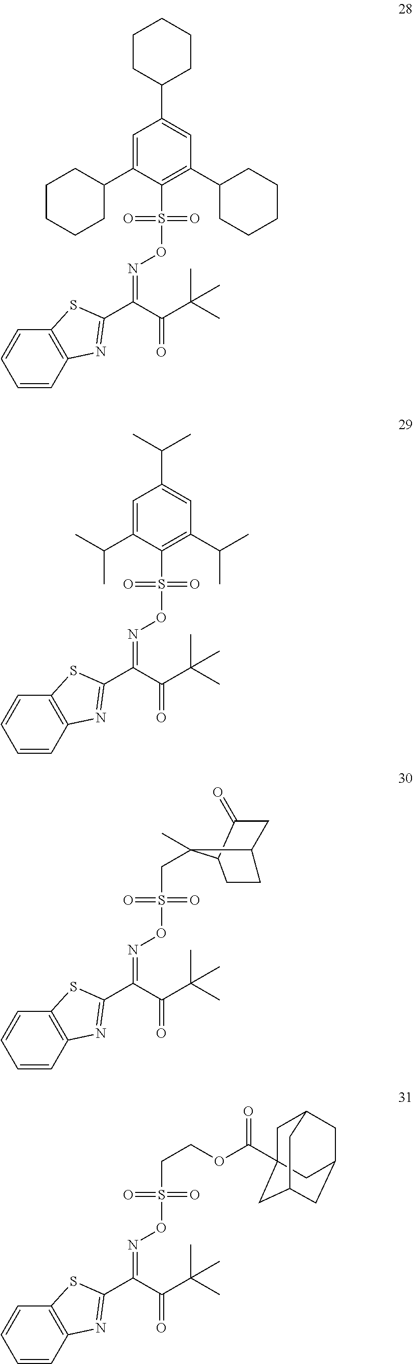

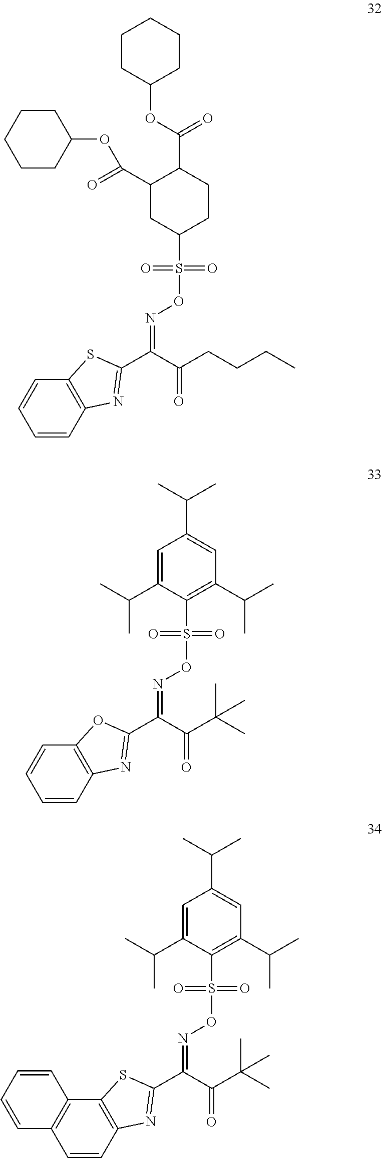

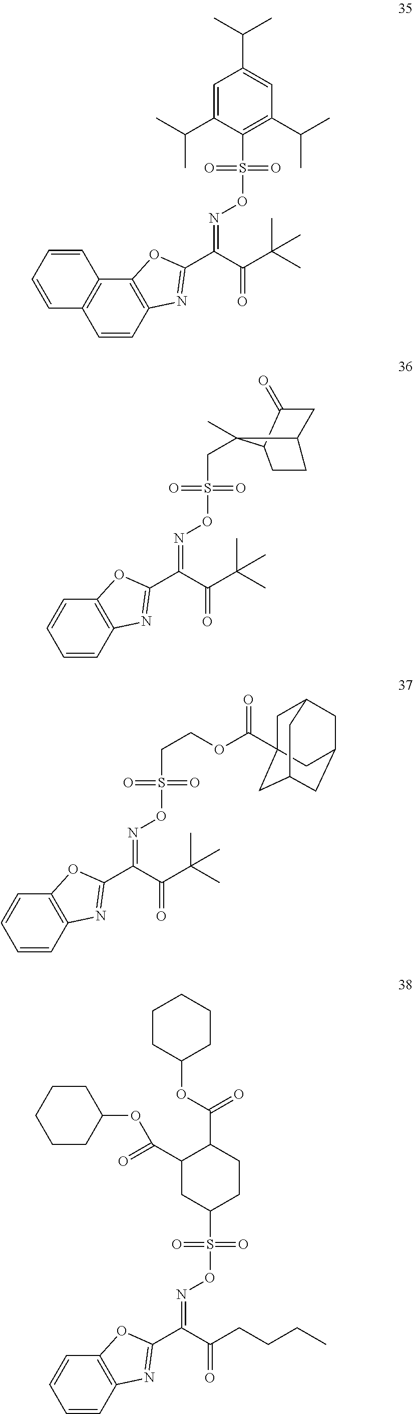

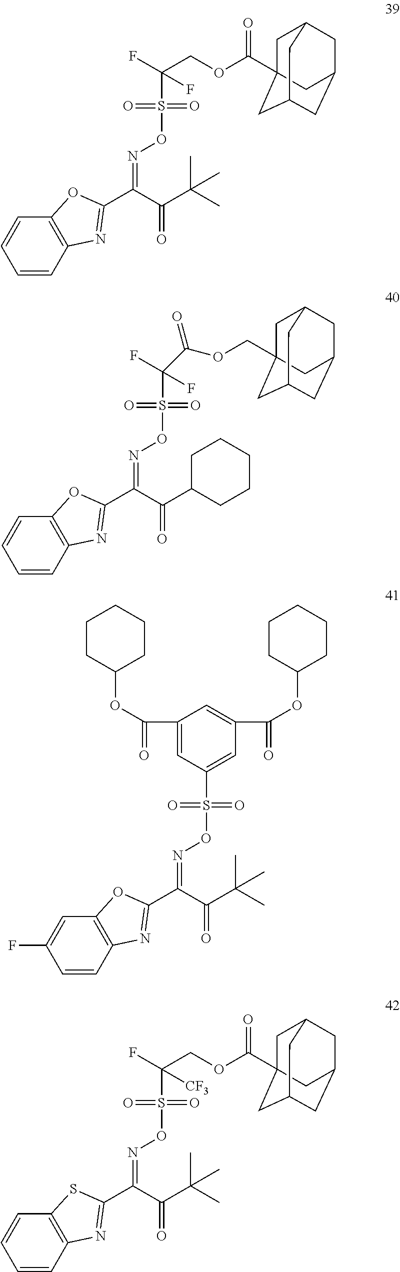

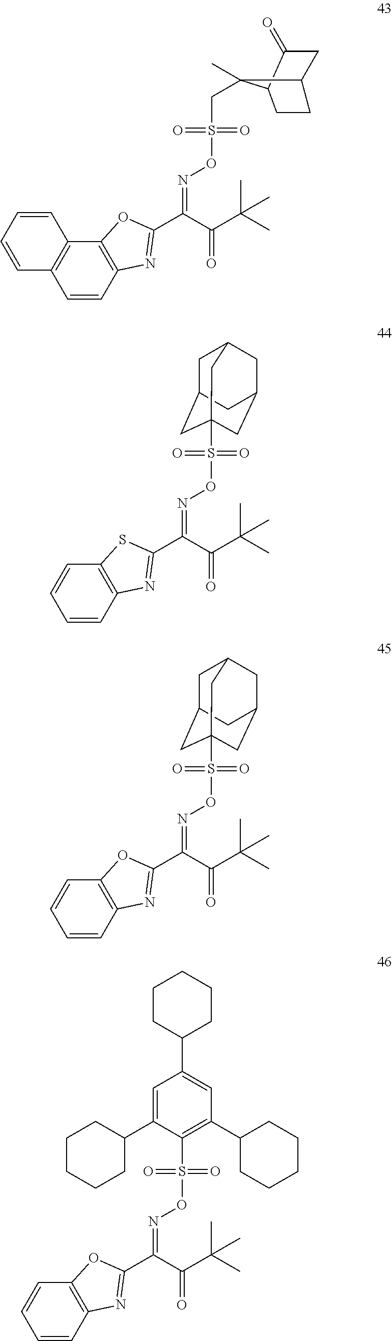

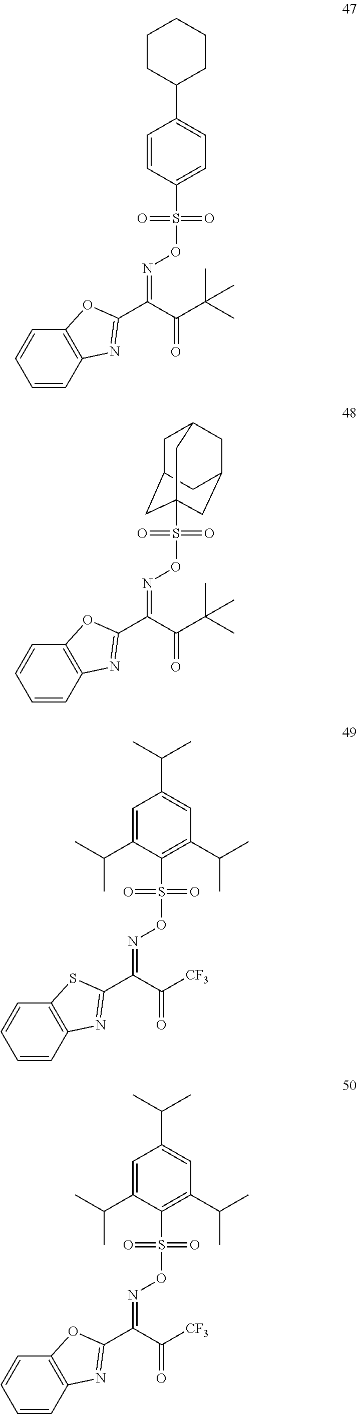

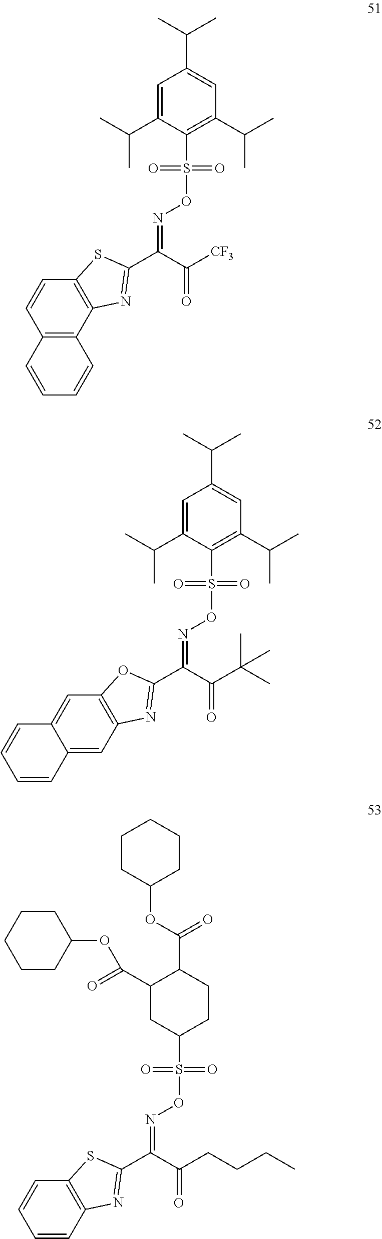

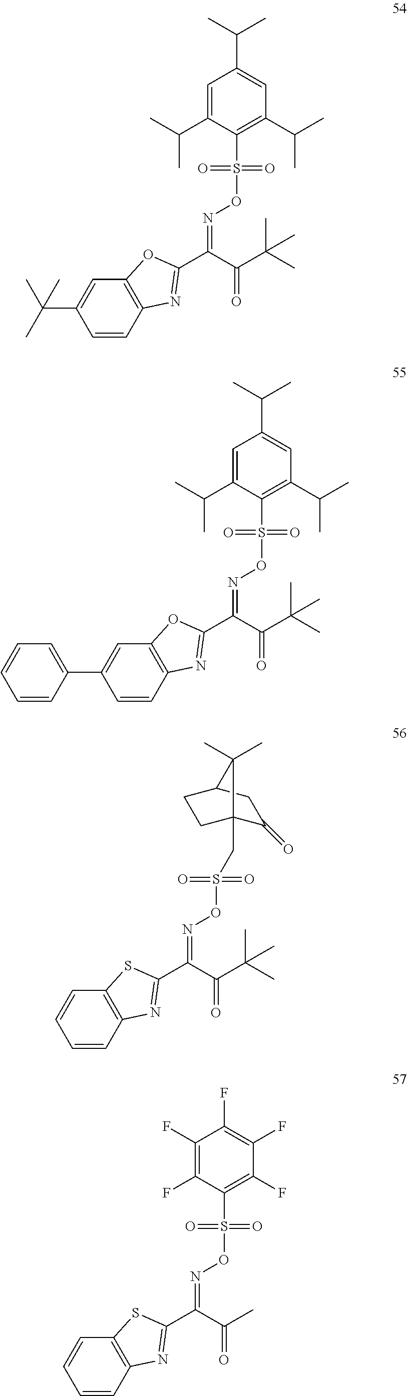

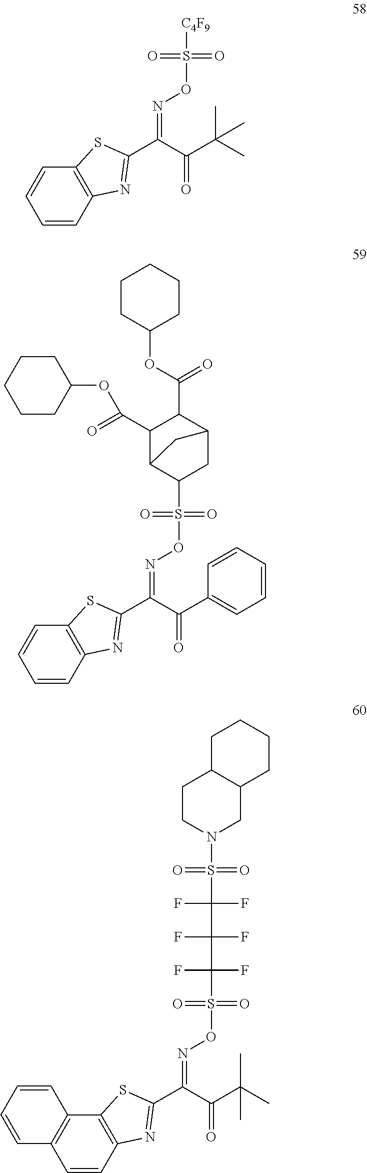

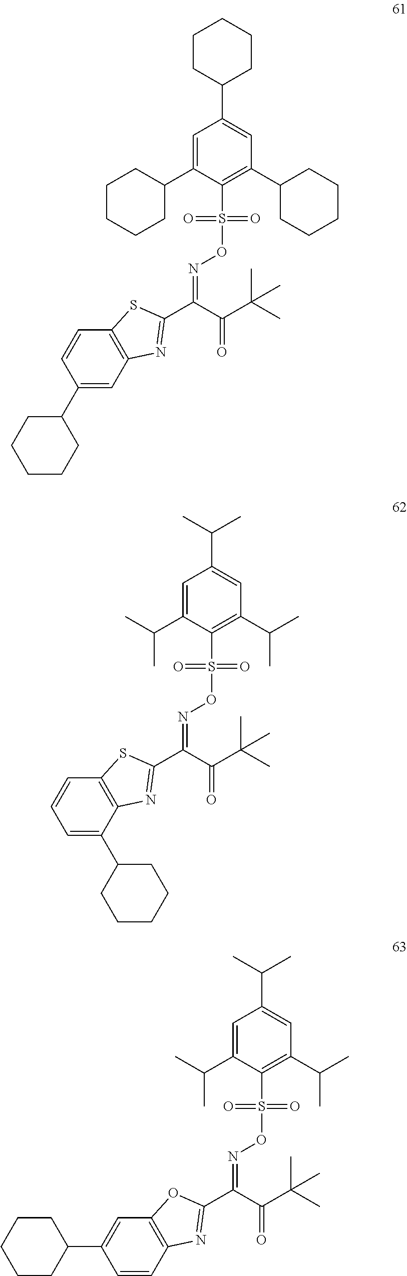

The content of the compound (A) expressed by General Formula (I) above is preferably 1% by mass to 40% by mass, more preferably 2% by mass to 30% by mass, and still more preferably 3% by mass to 25% by mass with respect to the total solid content of the resist composition for the semiconductor manufacturing process.

The compound (A) expressed by General Formula (I) above may be used singly, or 2 or more types thereof may be used in combination.

### [1′] Combined Acid Generator (A′)

The resist composition for the semiconductor manufacturing process according to the invention may further contain a compound (A′) (hereinafter, referred to as a “combined acid generator (A′)”) that generates an acid due to the irradiation of active rays or radial rays in addition to the compound (A).

Hereinafter, the combined acid generator (A′) in addition to the compound (A) is described.

As the combined acid generator (A′), a photoinitiator of photocationic polymerization, a photoinitiator of photoradical polymerization, light decolorizing agent of respective colors, a light color changing agent, or a well-known compound that generates an acid due to irradiation of active rays or radial rays which are used in a microresist, and a mixture of these can be appropriately selected to be used.

Examples thereof include a diazonium salt, a phosphonium salt, a suifonium salt, an iodonium salt, an imide sulfonate, oxime sulfonate, diazodisulfone, disulfone, and o-nitrobenzyl sulfonate.

The preferable compound among the combined acid generators is not particularly limited, as long as the compound is a well-known compound. However, it is preferable that an example thereof is a compound expressed by General Formula (ZI′), (ZII′), or (ZII′) below.

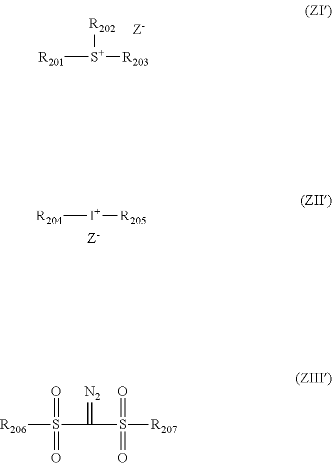

In General Formula (ZI′) above, each of R₂₀₁, R₂₀₂, and R₂₀₃ independently represents an organic group.

The number of carbon atoms of the organic group as R₂₀₁, R₂₀₂, and R₂₀₃ is generally 1 to 30 and preferably 1 to 20.

In addition, 2 of R₂₀₁ to R₂₀₃ may be bonded to each other to form a ring structure, and an oxygen atom, a sulfur atom, an ester bond, an amide bond, and a carbonyl group may be included in the ring. Examples of a ring formed by bonding 2 of R₂₀₁ to R₂₀₃ include an alkylene group (for example, a butylene group and a pentylene group).

Examples of the organic group expressed by R₂₀₁, R₂₀₁, and R₂₀₃ include groups corresponding to the compound (ZI′-1) described below.

In addition, an example thereof may be a compound having plural structures expressed by General Formula (ZI′). For example, the compound may be a compound having a structure of bonding at least one of R₂₀₁ to R₂₀₃ of the compound expressed by General Formula (ZI′) to at least one of R₂₀₁ to R₂₀₃ of one compound expressed by General Formula (ZI′) via a single bond or a linking group.

Z′ represents a non-nucleophilic anion (anion having extremely small capability of causing non-nucleophilic reaction).

Examples of Z′ include a sulfonate anion (an aliphatic sulfonate anion, an aromatic sulfonate anion, a camphorsulfonate anion, and the like), a carboxylate anion (an aliphatic carboxylate anion, an aromatic carboxylate anion, and an aralkylcarboxylate anion), a sulfonyl imide anion, a bis(alkylsulfonyl)imide anion, and a tris(alkylsulfonyl)methide anion.

An aliphatic portion in an aliphatic sulfonate anion and an aliphatic carboxylate anion may be an alkyl group or a cycloalkyl group. It is preferable that examples thereof include a straight chain or branched alkyl group having 1 to 30 carbon atoms and a cycloalkyl group having 3 to 30 carbon atoms.

The aromatic group in an aromatic sulfonate anion and an aromatic carboxylate anion is preferably an aryl group having 6 to 14 carbon atoms, and examples thereof include a phenyl group, a tolyl group, and a naphthyl group.

The alkyl group, the cycloalkyl group, and the aryl group described above may have substituents. Specific examples thereof include a halogen atom such as a nitro group and a fluorine atom, a carboxyl group, a hydroxy group, an amino group, a cyano group, an alkoxy group (preferably having 1 to 15 carbon atoms), a cycloalkyl group (preferably having 3 to 15 carbon atoms), an aryl group (preferably having 6 to 14 carbon atoms), an alkoxycarbonyl group (preferably having 2 to 7 carbon atoms), an acyl group (preferably having 2 to 12 carbon atoms), an alkoxycarbonyloxy group (preferably having 2 to 7 carbon atoms), an alkylthio group (preferably having 1 to 15 carbon atoms), an alkylsulfonyl group (preferably having 1 to 15 carbon atoms), an alkyliminosulfonyl group (preferably having 2 to 15 carbon atoms), an aryloxysulfonyl group (preferably having 6 to 20 carbon atoms), an alkylaryloxysulfonyl group (preferably having 7 to 20 carbon atoms), a cycloalkyaryaloxysulfonyl group (preferably having 10 to 20 carbon atoms), an alkyloxyalkyloxy group (preferably having 5 to 20 carbon atoms), and a cycloalkylalkyloxyalkyloxy group (preferably having 8 to 20 carbon atoms). Examples of the aryl group and the ring structure included in the respective groups further include an alkyl group (preferably having 1 to 15 carbon atoms), as a substituent.

The aralkyl group in the aralkylcarboxylate anion is preferably an aralkyl group having 7 to 12 carbon atoms, and examples thereof include a benzyl group, a phenethyl group, a naphthylimethyl group, a naphthylethyl group, and a naphthylbutyl group.

Examples of the sulfonylimide anion include a saccharin anion.

The alkyl group in the bis(alkylsulfonyl)imide anion and the tris(alkylsulfonyl)methide anion is preferably an alkyl group having 1 to 5 carbon atoms.

Two alkyl groups in the bis(alkylsulfonyl)imide anion may be linked to each other to form an alkylene group (preferably having 2 to 4 carbon atoms), and may form a ring together with an imide group and 2 sulfonyl groups.

Examples of the substituent that can be included in the alkylene group formed by linking 2 alkyl groups to each other in the alkyl group and the bis(alkylsulfonyl)imide anion include a halogen atom, an alkyl group substituted with a halogen atom, a alkoxy group, an alkylthio group, an alkyloxysulfonyl group, an aryloxysulfonyl group, and a cycloalkylaryloxysulfonyl group, and a fluorine atom and an alkyl group substituted with a fluorine atom is preferable.

Other examples of the Z′ include fluorinated phosphorus (for example, PF₆⁻), fluorinated boron (for example, BF₄⁻), and fluorinated antimony (for example, SbF₆⁻).

As Z′, an aliphatic sulfonate anion in which at least α-position of a sulfonic acid is substituted with a fluorine atom, a fluorine atom or an aromatic sulfonate anion substituted with a group having a fluorine atom, a bis(alkylsulfonyl)imide anion in which an alkyl group is substituted with a fluorine atom, and a tris(alkylsulfonyl)methide anion in which an alkyl group is substituted with a fluorine atom are preferable. As the non-nucleophilic anion, a perfluoroaliphatic sulfonate anion (still more preferably having 4 to 8 carbon atoms) and a benzenesulfonate anion having a fluorine atom is more preferable, and nonafluorobutanesulfonate anion, perfluorooctanesulfonate anion, pentafluorobenzenesulfonate anion, and 3,5-bis(trifluoromethyl)benzenesulfonate anion are further more preferable.

In view of acid strength, pKa of the generated acid is preferably −1 or less in order to improve sensitivity.

Examples of a still more preferable (ZI′) component include a compound (ZI′-1) described below.

The compound (ZI′-1) is an arylsulfonium compound in which at least one of R₂₀₁ to R₂₀₃ in General Formula (ZI′) above is an aryl group, that is, a compound having arylsulfonium as a cation.

In the arylsulfonium compound, all of R₂₀₁ to R₂₀₃ may be aryl group, a portion of R₂₀₁ to R₂₀₃ may be an aryl group and the rest may be an alkyl group or a cycloalkyl group, but it is preferable that all of R₂₀₁ to R₂₀₃ are an aryl group.

Examples of the arylsulfonium compound include a triarylsulfonium compound, a diarylalkylsulfonium compound, an aryldialkylsulfonium compound, a diarylcycloalkylsulfonium compound, and an aryldicycloalkylsulfonium compound, and the arylsulfonium compound is preferably a triarylsulfonium compound.

As the aryl group of the arylsulfonium compound, a phenyl group and a naphthyl group are preferable, and a phenyl group is more preferable. The aryl group may be an aryl group having a heterocyclic ring structure having an oxygen atom, a nitrogen atom, a sulfur atom, and the like. Examples of the heterocyclic ring structure include a pyrrole residue, a furan residue, a thiophene residue, an indole residue, a benzofuran residue, and a benzothiophene residue. When the arylsulfonium compound has 2 or more aryl groups, the 2 or more aryl groups may be identical to or different from each other.

As the alkyl group or the cycloalkyl group that is included in the arylsulfonium compound if necessary, a straight chain or branched alkyl group having 1 to 15 carbon atoms and a cycloalkyl group having 3 to 15 carbon atoms are preferable. Examples thereof include a methyl group, an ethyl group, a propyl group, an n-butyl group, a sec-butyl group, a t-butyl group, a cyclopropyl group, a cyclobutyl group, and a cyclohexyl group.

The aryl group, the alkyl group, and the cycloalkyl group of R₂₀₁ to R₂₀₃ may have an alkyl group (for example, having 1 to 15 carbon atoms), a cycloalkyl group (for example, having 3 to 15 carbon atoms), an aryl group (for example, having 6 to 14 carbon atoms), an alkoxy group (for example, having 1 to 15 carbon atoms), a halogen atom, a hydroxy group, and a phenylthio group, as a substituent. The substituent is preferably a straight chain or branched alkyl group having 1 to 12 carbon atoms, a cycloalkyl group having 3 to 12 carbon atoms, and a straight chain, branched, or cyclic alkoxy group having 1 to 12 carbon atoms, more preferably an alkyl group having 1 to 4 carbon atoms, and an alkoxy group having 1 to 4 carbon atoms. The substituent may be substituted with at least one of three of R₂₀₁ to R₂₀₃, or may be substituted with all three of R₂₀₁ to R₂₀₃. In addition, if R₂₀₁ to R₂₀₃ are aryl groups, the substituent is preferably substituted with at p-positions of the aryl groups.

Subsequently, General Formulae (ZII′) and (ZIII′) are described.

In General Formulae (ZII′) and (ZIII′).

each of R₂₀₄ to R₂₀₇ independently represents an aryl group, an alkyl group, or a cycloalkyl group.

The aryl group, the alkyl group, and, the cycloalkyl group of R₂₀₄ to R₂₀₇ are the same as the aryl groups described as the aryl group, the alkyl group, and the cycloalkyl group of R₂₀₁ to R₂₀₃ in the compound (ZI′-1) described above.

The aryl group, the alkyl group, and the cycloalkyl group of R₂₀₄ to R₂₀₇ may have substituents. Examples of the substituent may include substituents that may be included in the aryl group, the alkyl group, and the cycloalkyl group of R₂₀₁ to R₂₀₃ in the compound (ZI′-1).

Z′ represents a non-nucleophilic anion, and examples thereof include a non-nucleophilic anion that is the same of the non-nucleophilic anion of Z′ in General Formula (ZI′).

Examples of the acid generator (A′) that can be combined with the compound (A) according to the invention further include compounds represented by General Formula (ZIV′), (ZV′), and (ZVI′) below.

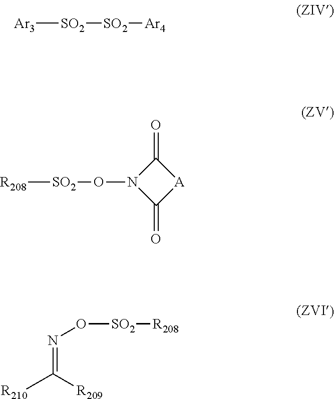

In General Formulae (ZIV′) to (ZV′),

each of Ar₃ and Ar₄ independently represents an aryl group.

Each of R₂₀₈, R₂₀₉, and R₂₁₀ independently represents an alkyl group, a cycloalkyl group, or an aryl group.

A represents an alkylene group, an alkenylene group, or an arylene group.

The specific examples of the aryl group of Ar₃, Ar₄, R₂₀₈, R₂₀₉, and R₂₁₀ include the same specific examples of the aryl group of R₂₀₁, R₂₀₂, and R₂₀₃ in General Formula (ZI′-1) above.

The specific examples of the alkyl group and the cycloalkyl group of R₂₀₈, R₂₀₉, and R₂₁₀ respectively include the same specific examples of the alkyl group and the cycloalkyl group of R₂₀₁, R₂₀₂, and R₂₀₃ in General Formula (ZI′-1) above.

Examples of the alkylene group of A include alkylene having 1 to 12 carbon atoms (for example, a methylene group, an ethylene group, a propylene group, an isopropylene group a butylene group, and an isobutylene group), examples of the alkenylene group of A include an alkenylene group having 2 to 12 carbon atoms (for example, an ethenylene group, a propenylene group, and a butenylene group), and examples of the arylene group of A include an arylene group having 6 to 10 carbon atoms (for example, a phenylene group, a tolylene group, and a naphthylene group).

Among the combined acid generator (A′) that can be combined with the compound (A) according to the invention, particularly preferable examples are provided below.

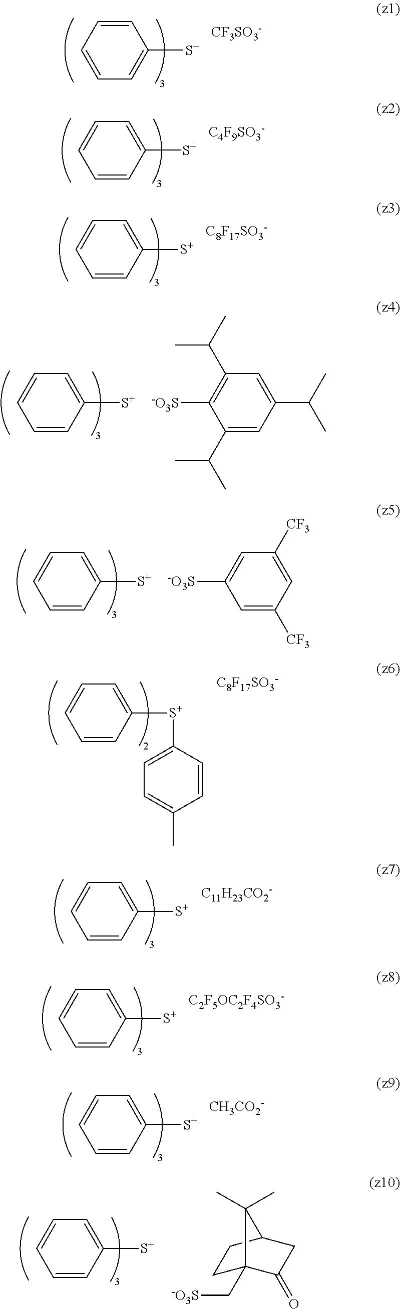

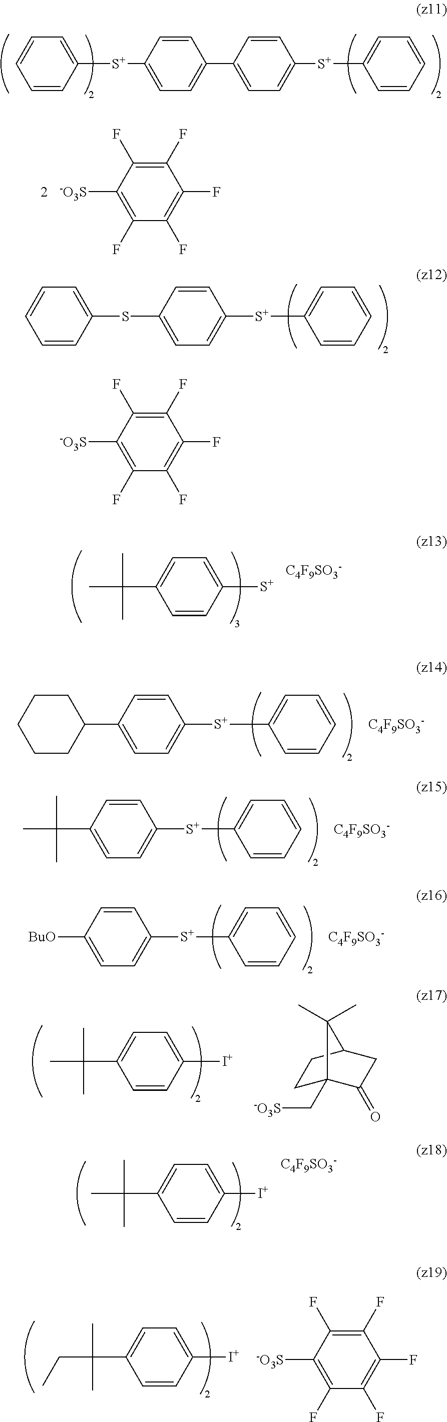

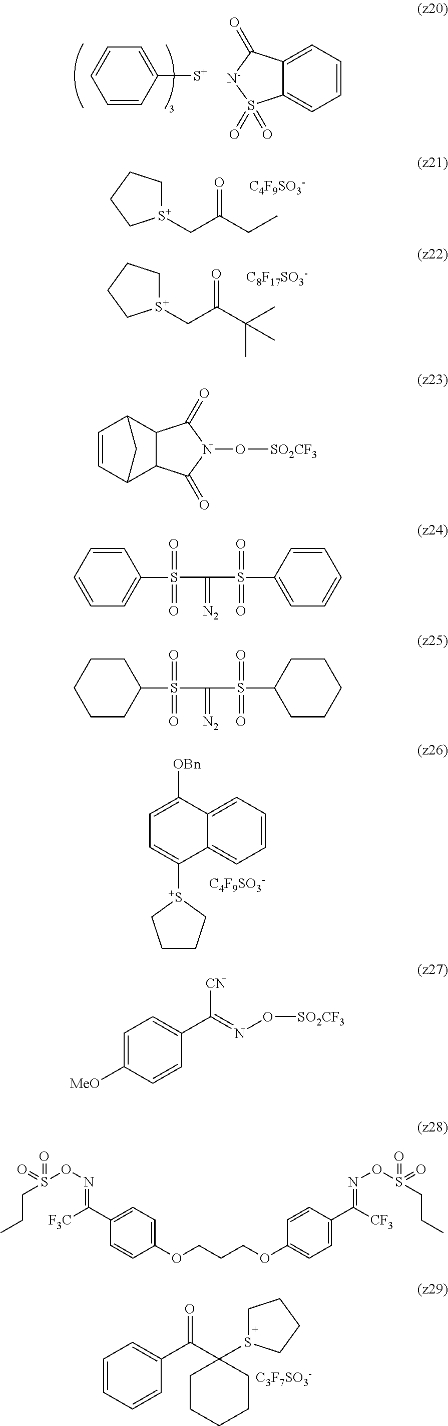

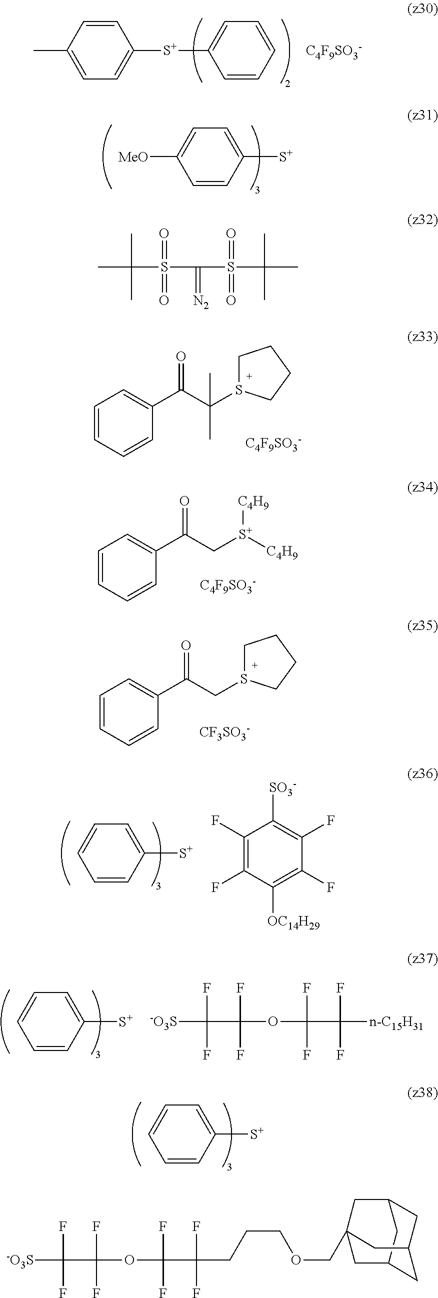

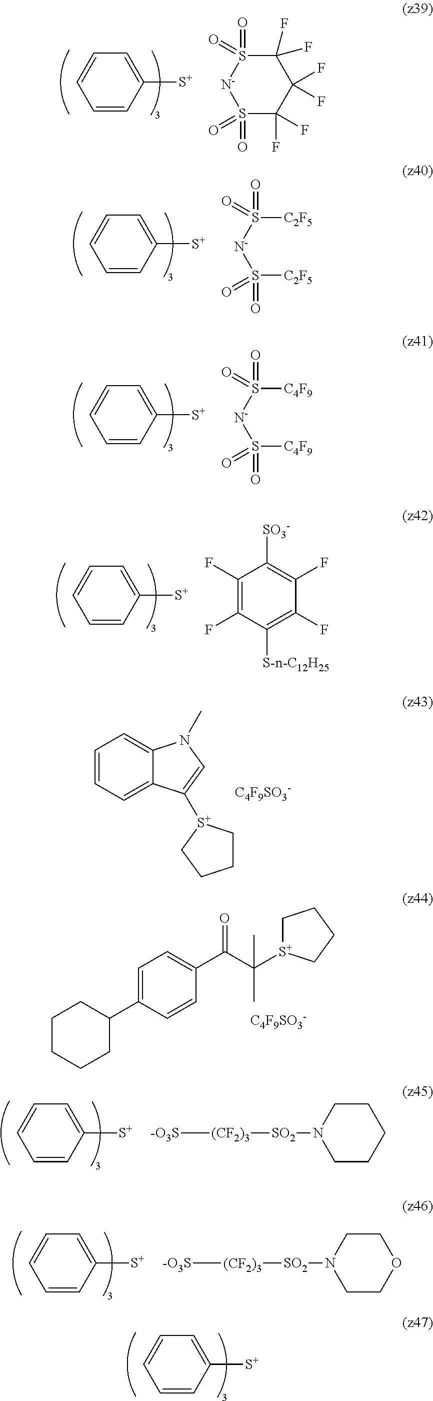

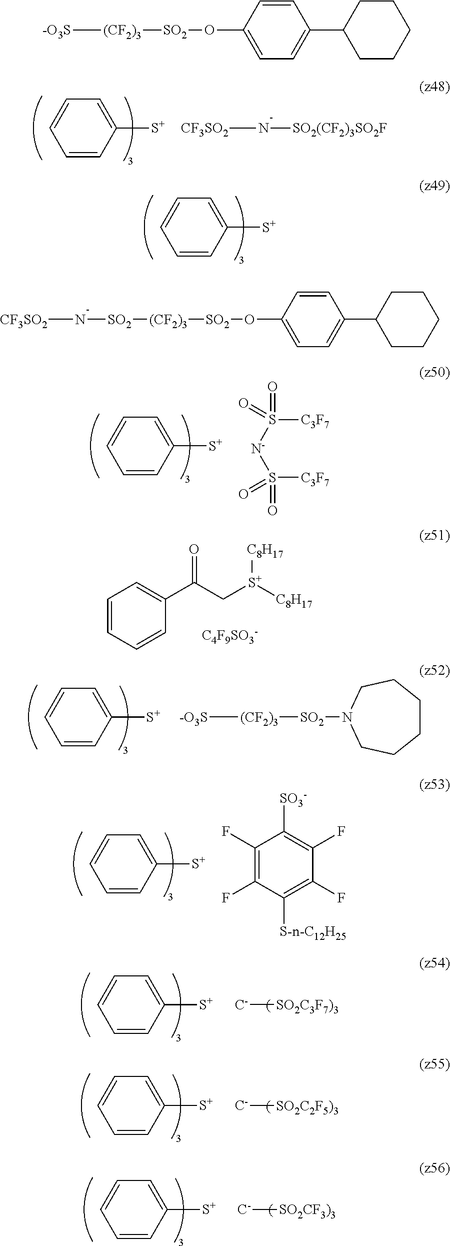

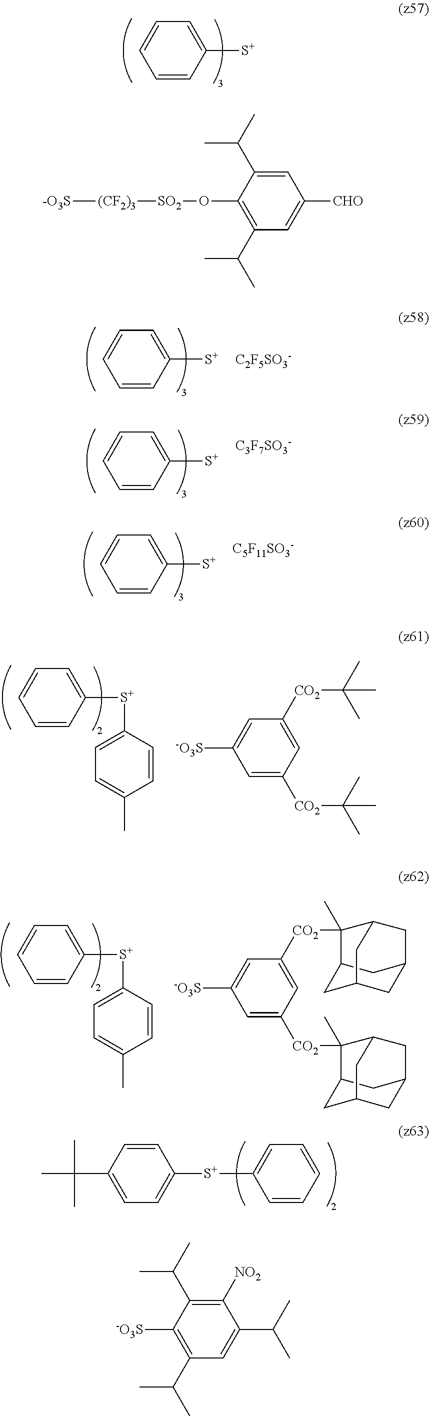

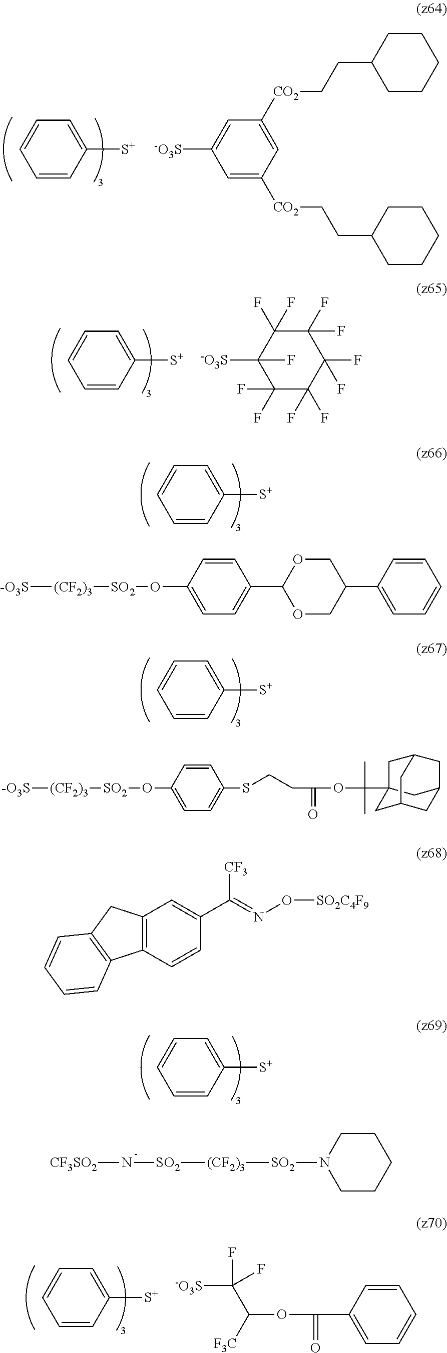

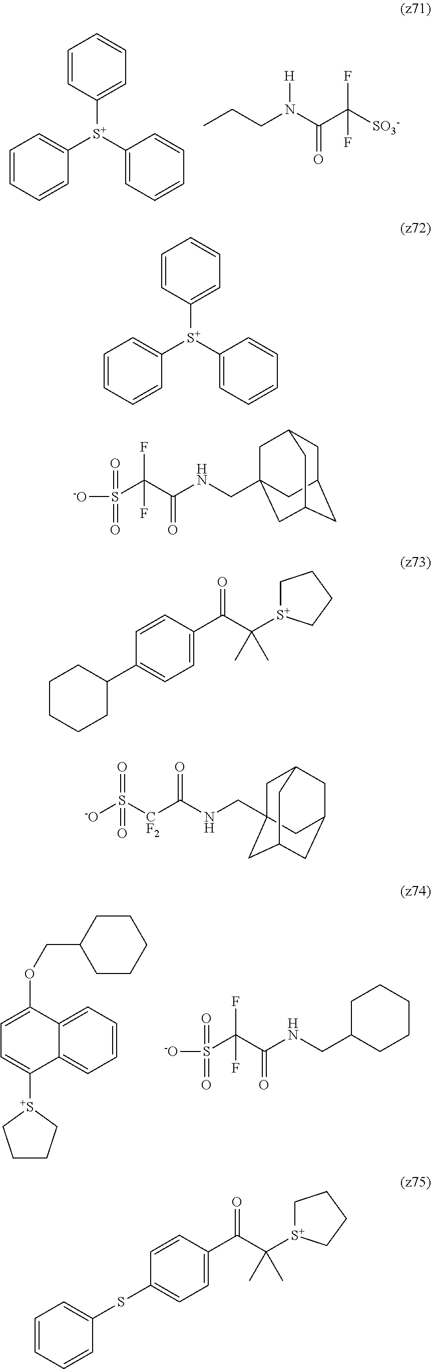

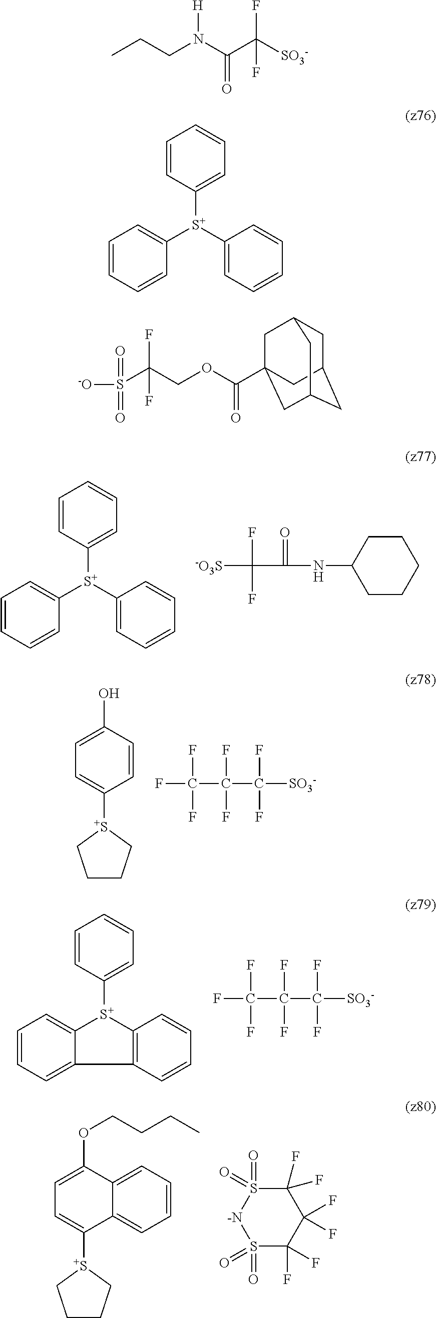

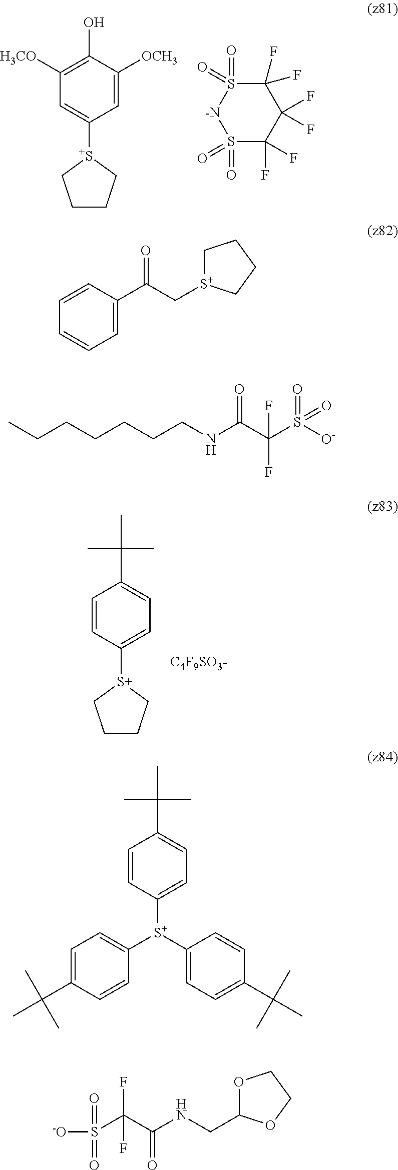

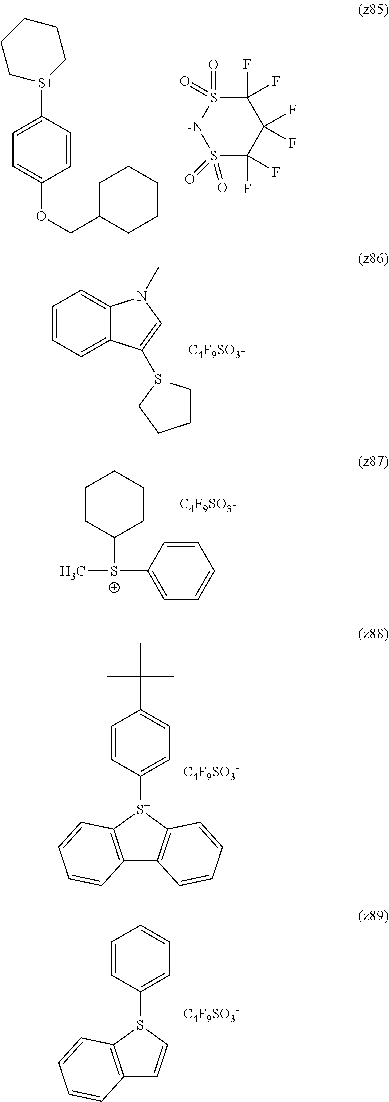

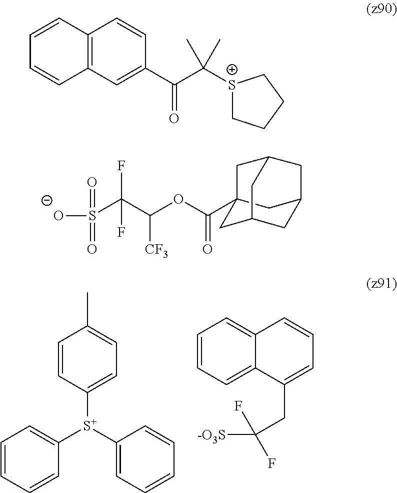

The combined acid generator (A′) can be synthesized by well-known methods. For example, the combined acid generator (A′) can be synthesized in conformity with methods described in JP2007-161707A.

The combined acid generator (A′) may be used singly, or 2 or more types thereof may be used in combination.

The resist composition for the semiconductor manufacturing process according to the invention may contain or may not contain the combined acid generator (A′). However, if the combined acid generator (A′) is contained, the content in the composition of the combined acid generator (A′) is preferably 0.05% by mass to 15% by mass, more pre preferably 0.1% by mass to 10% (by mass, and still more preferably 1% by mass to 6% by mass with respect to the total solid content of the resist composition for the semiconductor manufacturing process.

[2] (P) Compound Having Phenolic Hydroxy Group

It is preferable that the resist composition for the semiconductor manufacturing process according to the invention contains a compound (P) (hereinafter, referred to as a compound (P)) having a phenolic hydroxy group.

The phenolic hydroxy group according to this application refers to a group in which a hydrogen atom of an aromatic ring group is substituted with a hydroxy group. The aromatic ring of the aromatic ring group is a monocyclic or polycyclic aromatic ring, and examples thereof include a benzene ring or a naphthalene ring.

The compound (P) having the phenolic hydroxy group is not limited to a group having a phenolic hydroxy group, may be a relatively lower molecular compound such as a molecular resist or may be a resin. In addition, as the molecular resist, low molecular weight cyclic polyphenol compounds disclosed in JP2009-173623A and JP2009-173625A can be used.

In view of reactivity and sensitivity, the compound (P) having the phenolic hydroxy group is preferably a resin.

If the compound (P) having a phenolic hydroxy group according to the invention is a resin, the resin preferably contains a repeating unit having at least one type of phenolic hydroxy group. The repeating unit having the phenolic hydroxy group is not particularly limited, but it is preferable that the repeating unit having the phenolic hydroxy group is a repeating unit expressed by General Formula (1) below.

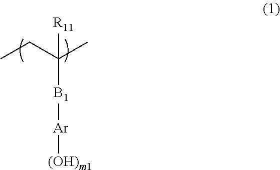

In General Formula (1), R₁₁ represents a hydrogen atom, a methyl group, or a halogen atom.

B₁ represents a single bond or a bivalent linking group.

Ar represents an aromatic ring.

m1 represents an integer of 1 or greater.

The methyl group in R₁₁ may have a substituent, and examples thereof include a trifluoromethyl group and a hydroxynmethyl group.

R₁₁ is preferably a hydrogen atom or a methyl group, and in view of developing properties, a hydrogen atom is preferable.

The bivalent linking group of Br is preferably a carbonyl group, an alkylene group (preferably having 1 to 10 carbon atoms and more preferably having 1 to 5 carbon atoms), a sulfonyl group (—S(═O)₂—), —O—, —NH—, or a bivalent linking group obtained by combining these.

B₁ preferably represents a single bond, an ester bond (—C(═O)—O—), or an amide bond (—C(═O)—NH—), more preferably represents a single bond or an ester bond (—C(═O)—O—), and particularly preferably a single bond, in view of dry etching resistance improvement.

The aromatic ring of Ar is a monocyclic or polycyclic aromatic ring, and examples thereof include an aromatic hydrocarbon ring that may have a substituent having 6 to 18 carbon atoms such as a benzene ring, a naphthalene ring, an anthracene ring, a fluorene ring, and a phenanthrene ring, or an aromatic heterocyclic ring including heterocyclic ring such as a thiophene ring, a furan ring, a pyrrole ring, a benzothiophene ring, a benzofuran ring, a benzopyrrole ring, a triazine ring, an imidazole ring, a benzimidazole ring, a triazole ring, a thiadiazole ring, and a thiazole ring. Among them, a benzene ring and a naphthalene ring are preferable in view of resolving power, and a benzene ring is most preferable in view of sensitivity.

m1 is preferably an integer of 1 to 5, and most preferably 1. When m1 is 1 and Ar is a benzene ring, a substitution position of —OH may be a para position, a meta position, or an ortho position with respect to a bonding position to a benzene ring of B₁ (polymer main chain, if B₁ is a single bond). However, in view of crosslinking reactivity, a para position and a meta position are preferable, and a para position is more preferable.

The aromatic ring of Ar may have a substituent other than the group represented by —OH above, and examples of the substituent include an alkyl group, a cycloalkyl group, a halogen atom, a hydroxy group, an alkoxy group, a carboxyl group, an alkoxycarbonyl group, an alkylcarbonyl group, an alkylcarbonyloxy group, an alkylsulfonyloxy group, and an arylcarbonyl group.

It is more preferable that the repeating unit having a phenolic hydroxy group is a repeating unit expressed by General Formula (2) below, in view of crosslinking reactivity, developing properties, and dry etching resistance.

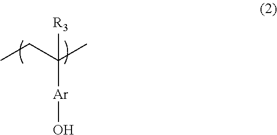

In General Formula (2), R₃ represents a hydrogen atom or a methyl group.

Ar represents an aromatic ring.

R₃ represents a hydrogen atom or a methyl group, and a hydrogen atom is preferable in view of developing properties,

Ar in General Formula (2) represents the same Ar in General Formula (1), and a preferable range is also the same. The repeating unit expressed by General Formula (2) is preferably a repeating unit derived from hydroxystyrene (that is, a repeating unit in which R₃ in General Formula (2) is a hydrogen atom and Ar is a benzene ring), in view of sensitivity:

The compound (P) as the resin may be configured with only a repeating unit having a phenolic hydroxy group as described above. The compound (P) as the resin may have a repeating unit described below, in addition to the repeating unit having the phenolic hydroxy group described above. In this case, the content of the repeating unit having the phenolic hydroxy group is preferably 10% by mol to 98% by mol, more preferably 30% by mol to 97% by mol, and still more preferably 40% by mol to 95% by mol with respect to the total repeating unit of the compound (P), as a resin. Accordingly, particularly, if a resist film is a thin film (for example, if the thickness of the resist film is 10 nm to 150 nm), it is possible to definitely decrease a dissolution rate of an exposed portion in the resist film formed by using the compound (P) according to the invention, to an alkaline developer (that is, it is possible to more surely control a dissolution rate of a resist film using the compound (P) to an optimum rate). As a result, it is possible to more definitely improve sensitivity.

Hereinafter, examples of the repeating unit having the phenolic hydroxy group are provided, but the invention is not limited thereto.

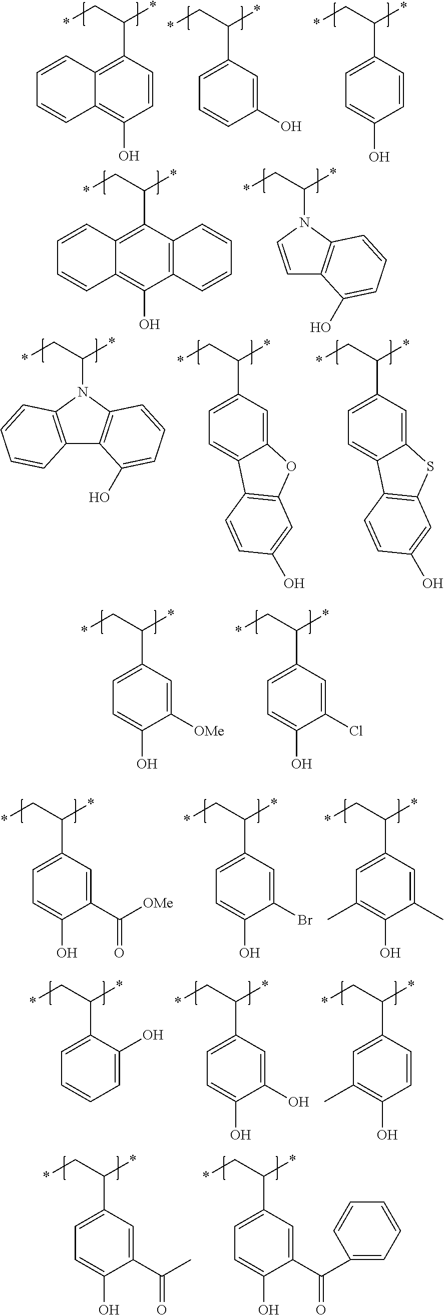

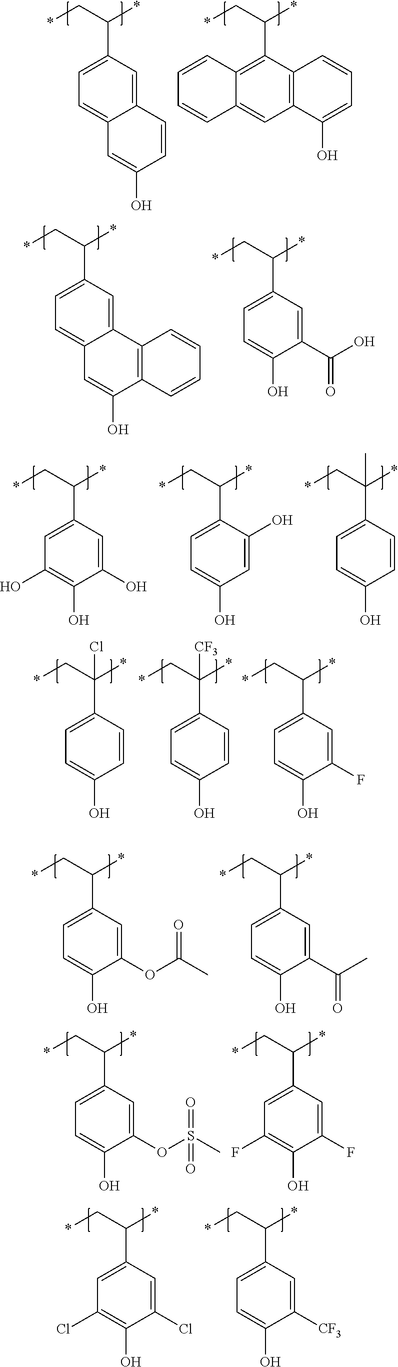

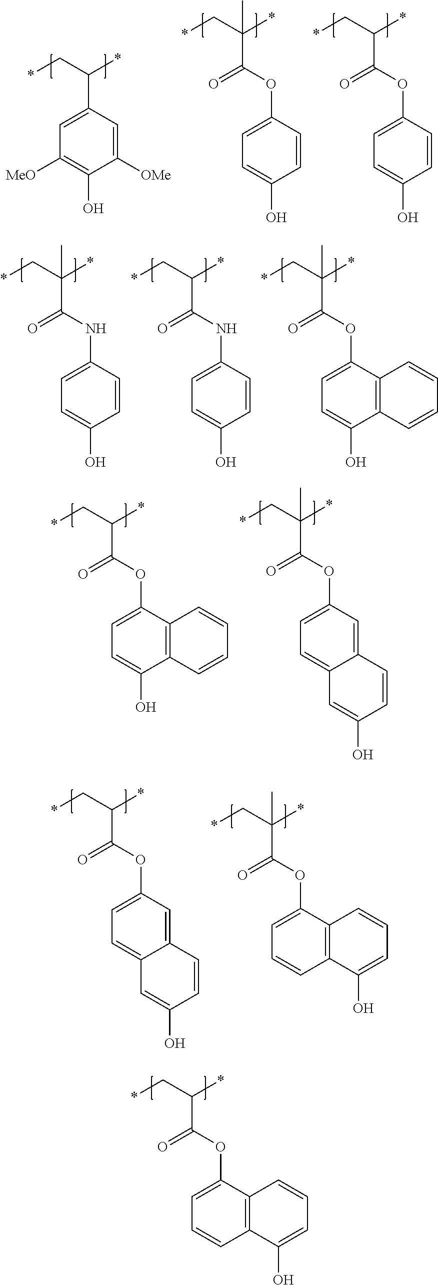

(2-1) Compound (P) Having Phenolic Hydroxy Group as Acid Decomposable Resin

(P) The compound having the phenolic hydroxy group according to the invention is a resin having the repeating unit having at least one type of phenolic hydr oxy group, and a resin further having a repeating unit as described below, as a repeating unit other than the repeating unit expressed by General Formula (1) above is preferable.

Specifically, (P) the compound having a phenolic hydroxy group is a resin having a repeating unit having at least one type of phenolic hydroxy group. Further, examples thereof include a compound having a repeating unit having a group that is decomposed due to the action of an acid and generates a polar group (hereinafter, referred to as an “acid decomposable group”), as a preferable embodiment according to the invention (hereinafter, the compound (P) in this case may be referred to as a “resin that is decomposed due to the action of an acid, and thus solubility thereof to a developer changes” or an “acid decomposable resin”).

If the resist composition according to the invention is applied to the alkaline development, it is preferable that the polar group functions as an alkaline soluble polymer.

The acid decomposable group is preferably a group obtained by substituting a hydrogen atom of a polar group (alkaline soluble polymer in the case of an alkaline development) such as a —COOH group and an —OH group with a group that is released due to the action of an acid. The group that is released due to the action of an acid is particularly preferably an acetal group or a tertiary ester group.

Examples of a matrix resin when this acid decomposable group is bonded as a side chain include an alkaline soluble resin having —OH or a —COOH group at a side chain.

Examples of this alkaline soluble resin include resins described below.

The alkali dissolution rate of this alkaline soluble resin is preferably 17 nm/sec or greater measured by 2.38% by mass of tetramethyl ammonium hydroxide (TMAH) (23° C.). This rate is particularly preferably 33 nm/sec or greater.

In this point of view, examples of particularly preferable alkaline soluble resin include a resin including a hydroxystyrene structure unit such as o-, m-, and p-poly(hydroxystyrene), and copolymers of these, partially O-alkylated products or O-acylated products of hydrogenated poly(hydroxystyrene), halogen- or alkyl-substituted poly(hydroxystyrene), and poly(hydroxystyrene), a styrene-hydroxystyrene copolymer, an α-methylstyrene-hydroxystyrene copolymer, and a hydrogenated novolac resin; and a resin including a repeating unit having a carboxyl group such as a (meth)acrylic acid and a norbornene carboxylic acid.

Examples of the preferable repeating unit having the acid decomposable group include t-butoxycarbonyloxystyrene, 1-alkoxyethoxystyrene, and a tertiary (meth)acrylate alkyl ester. As the repeating unit, 2-alkyl-2-adamantyl(meth)acrylate or dialkyl(1-adamantylmethyl(meth)acrylate is more preferable.

As disclosed in EP254853B, JP1990-25850A (JP-H2-25850A), JP1991-223860A (JP-H3-223860A), and JP1992-251259A (JP-44-251259A), the acid decomposable resin can be obtained, for example, by reacting a precursor of a group that is released due to the action of an acid with a resin, or copolymerizing an alkaline soluble resin monomer bonded to the group that is released due to the action of the acid with various monomers.

If the composition according to the invention is irradiated with KrF exciplex light, electron beams, X rays, or high energy rays having a wavelength of 50 nm or less (for example EUV), the acid decomposable resin, preferably has a hydroxystyrene repeating unit. It is still more preferable that the acid decomposable resin is a copolymer of hydroxystyrene protected by a group that is released due to the action of the acid and hydroxystyrene or a copolymer of hydroxystyrene and a tertiary (meth)acrylate alkyl ester

With respect to the acid decomposable resin, specifically, examples of the repeating unit having an acid decomposable group include a resin having a repeating unit expressed by General Formula (A) below. If the resin having the repeating unit is used, the dry etching resistance of the formed pattern can be improved.

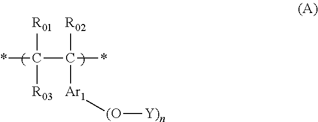

In the formula, each of R₀₁, R₀₂, and R₀₃ independently represents a hydrogen atom, an alkyl group, a cycloalkyl group, a halogen atom, a cyano group, or an alkoxycarbonyl group. Ar₁ represents an aromatic ring group. In addition, R₀₃ and Ar₁ are alkylene groups, and both may be bonded to each other to form a 5-membered or 6-membered ring together with a main chain of a repeating unit expressed by General Formula (A).

Each of n items of Y's independently represents a hydrogen atom or a group that is released due to the action of an acid. However, at least one of the Y's represents a group that is released due to the action of an acid.

n represents an integer of 1 to 4, 1 or 2 is preferable, and 1 is more preferable.

The alkyl groups as R₀₁ to R₀₃ are, for example, an alkyl group having 20 or less carbon atoms, and preferably a methyl group, an ethyl group, a propyl group, an isopropyl group, an n-butyl group, a sec-butyl group, a hexyl group, a 2-ethylhexyl group, an octyl group, or a dodecyl group. It is more preferable that the alkyl group is an alkyl group having 8 or less carbon atoms. In addition, the alkyl group may have a substituent.

As the alkyl group included in the alkoxycarbonyl group, the same alkyl groups as the alkyl groups in R₀₁ to R₀₃ are preferable.

The cycloalkyl group may be a monocyclic cycloalkyl group or may be a polycyclic cycloalkyl group. It is preferable that examples thereof include a monocyclic cycloalkyl group having 3 to 8 carbon atoms such as a cyclopropyl group, a cyclopentyl group, and a cyclohexyl group. In addition, these cycloalkyl groups may have substituents.

Examples of the halogen atom include a fluorine atom, a chlorine atom, a bromine atom, and an iodine atom, and a fluorine atom is more preferable.

If R₀₃ represents an alkylene group, the alkylene group is preferably a group having 1 to 8 carbon atoms, such as a methylene group, an ethylene group, a propylene group, a butylene group, a hexylene group, and an octylene group.

The aromatic ring group as Ar₁ is preferably an aromatic ring group having 6 to 14 carbon atoms, and examples thereof include a benzene ring, a toluene ring, and a naphthalene ring. In addition, these aromatic ring groups may have substituents.

Examples of the group Y that is released due to the action of an acid include groups represented by —C(R³⁶)(R³⁷)(R³⁸), —C(═O)—O—C(R³⁶)(R³⁷)(R³⁸), —C(R⁰¹)(R⁰²)(OR³⁹), —C(R⁰¹)(R⁰²)—C(═O)—O—C(R³⁶)(R³⁷)(R³⁸), and —CH(R³⁶)(Ar).

In the formula, each of R³⁶ to R³⁹ independently represents an alkyl group, a cycloalkyl group, an aryl group, an aralkyl group, or an alkenyl group. R³⁶ and R³⁷ are bonded to each other to form a ring structure.

Each of R⁰¹ and R⁰² independently represents a hydrogen atom, an alkyl group, a cycloalkyl group, an aryl group, an aralkyl group, or an alkenyl group.

Ar represents an aryl group.

An alkyl group as R³⁶ to R³⁹, R⁰¹, or R⁰² is preferably an alkyl group having 1 to 8 carbon atoms, and examples thereof include a methyl group, an ethyl group, a propyl group, an n-butyl group, a sec-butyl group, a hexyl group, and an octyl group.

The cycloalkyl group as R³⁶ to R³⁹, R⁰¹, or R⁰² may be a monocyclic cycloalkyl group or may be a polycyclic cycloalkyl group. As the monocyclic cycloalkyl group, a cycloalkyl group having 3 to 8 carbon atoms is preferable, and examples thereof include a cyclopropyl group, a cyclobutyl group, a cyclopentyl group, a cyclohexyl group, and a cyclooctyl group. As the polycyclic cycloalkyl group, a cycloalkyl group having 6 to 20 carbon atoms is preferable, and examples thereof include an adamantyl group, a norbornyl group, an isobornyl group, a camphanyl group, a dicyclopentyl group, an α-pinel group, a tricyclodecanyl group, a tetracyclododecyl group, and an androstanyl group. In addition, a portion of a carbon atom in a cycloalkyl group may be substituted with a hetero atom such as an oxygen atom.

The aryl group as R³⁶ to R³⁹, R⁰¹, R⁰², or Ar is preferably an aryl group having 6 to 10 carbon atoms, and examples thereof include a phenyl group, a naphthyl group, and an anthryl group.

The aralkyl group as R³⁶ to R³⁹, R⁰¹, or R⁰² is preferably an aralkyl group having 7 to 12 carbon atoms, and for example, a benzyl group, a phenethyl group, and a naphthylmethyl group are preferable.

The alkenyl group as R³⁶ to R³⁹, R⁰¹ or R⁰² is preferably an alkenyl group having 2 to 8 carbon atoms, and examples thereof include a vinyl group, an aryl group, a butenyl group, and a cyclohexenyl group.

A ring that can be formed by bonding R³⁶ and R³⁷ to each other may be a monocyclic type or may be a polycyclic type. As the monocyclic type, a cycloalkane structure having 3 to 8 carbon atoms is preferable, and examples thereof include a cyclopropane structure, a cyclobutane structure, a cyclopentane structure, a cyclohexane structure, a cycloheptane structure, and a cyclooctane structure. As the polycyclic type, a cycloalkane structure having 6 to 20 carbon atoms is preferable, and examples thereof include an adamantane structure, a norbornane structure, a dicyclopentane structure, a tricyclodecane structure, and a tetracyclododecane structure. In addition, a portion of the carbon atom in the ring structure may be substituted with a hetero atom such as an oxygen atom.

The respective groups may have substituents. Examples of the substituent include an alkyl group, a cycloalkyl group, an aryl group, an amino group, an amide group, a ureido group, a urethane group, a hydroxyl group, a carboxyl group, a halogen atom, an alkoxy group, a thioether group, an acyl group, an acyloxy group, an alkoxycarbonyl group, a cyano group, and a nitro group. The substituent preferably have 8 or less carbon atoms.

As the group Y that is released due to the action of an acid, a structure expressed by General Formula (B) below is more preferable.

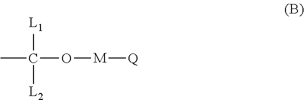

In the formula, each of L₁ and L₂ independently represents a hydrogen atom, an alkyl group, a cycloalkyl group, an aryl group, or an aralkyl group.

M represents a single bond or a bivalent linking group.

Q represents an alkyl group, a cycloalkyl group, an alicyclic group, an aromatic ring group, an amino group, an ammonium group, a mercapto group, a cyano group, or an aldehyde group. In addition, the alicyclic group and the aromatic ring group may have hetero atoms.

In addition, at least 2 of Q, M, and L₁ may be bonded to each other to form a 5-membered or 6-membered ring.

An example of the alkyl group as L₁ and L₂ is an alkyl group having 1 to 8 carbon atoms, and specific examples thereof include a methyl group, an ethyl group, a propyl group, an isopropyl group, an n-butyl group, a sec-butyl group, a t-butyl group, a hexyl group, and an octyl group.

The cycloalkyl group as L₁ and L₂ is, for example, a cycloalkyl group having 3 to 15 carbon atoms, and specific examples thereof include a cyclopentyl group, a cyclohexyl group, a norbornyl group, and an adamantyl group.

The aryl group as L₁ and L₂ is, for example, an aryl group having 6 to 15 carbon atoms, and specific examples thereof include a phenyl group, a tolyl group, a naphthyl group, and an anthryl group.

The aralkyl group as L₁ and L₂ is, for example, an aralkyl group having 6 to 20 carbon atoms, and specific examples thereof include a benzyl group and a phenethyl group.

The bivalent linking group as M is, for example, an alkylene group (for example, a methylene group, an ethylene group, a propylene group, a butylene group, a hexylene group, or an octylene group), a cycloalkylene group (for example, a cyclopentylene group or a cyclohexylene group), an alkenylene group (for example, an ethenylene group, a propenylene group, or a butenylene group), an arylene group (for example, a penylene group, a tolylene group, or a naphthylene group). —S—, —S—, —C—, —SO—, and —N(R₀)—, or a combination of 2 or more of these groups. Here, R₀ is a hydrogen atom or an alkyl group. The alkyl group as R₀ is, for example, an alkyl group having 1 to 8 carbon atoms, and specific examples thereof include a methyl group, an ethyl group, a propyl group, an n-butyl group, a sec-butyl group, a hexyl group, and an octyl group.

The alkyl group and the cycloalkyl group as Q are the same as the respective groups as L₁ and L₂ described above.

Examples of the alicyclic group or the aromatic ring group as Q include the cycloalkyl group and the aryl group as L₁ and L₂ described above. This cycloalkyl group and this aryl group are preferably groups having 3 to 15 carbon atoms.

Examples of the alicyclic group or the aromatic ring group including the hetero atom as Q include a group having a heterocyclic ring structure such as thiirane, cyclothiolane, thiophene, furan, pyrrole, benzothiophene, benzofuran, benzopyrrole, triazine, imidazole, benzimidazole, triazole, thiadiazole, thiazole, and pyrrolidone. However, the alicyclic group or the aromatic ring group is not limited thereto as long as a group is a ring formed with carbon and a hetero atom, or a ring formed only with hetero atoms.

Examples of the ring structure that can be formed by bonding at least 2 of Q, M, and L₁ include a 5-membered or 6-membered ring structure obtained by forming a propylene group or a butylene group with these. In addition, the 5-membered or 6-membered ring structure contains an oxygen atom.

The respective groups represented by L₁, L₂, M, and Q in General Formula (2) may have substituents. Examples of the substituent include an alkyl group, a cycloalkyl group, an aryl group, an amino group, an amino group, an amide group, a ureido group, a urethane group, a hydroxyl group, a carboxyl group, a halogen atom, an alkoxy group, a thioether group, an acyl group, an acyloxy group, an alkoxycarbonyl group, a cyano group, and a nitro group. These substituents preferably have 8 or less carbon atoms.

As the group represented by -(M-Q), the group having 1 to 30 carbon atoms is preferable, and a group having 5 to 20 carbon atoms is more preferable. Particularly, in view of outgassing suppression, a group having 6 or more carbon atoms is preferable.

The acid decomposable resin may be a resin having a repeating unit expressed by General Formula (X) below, as a repeating unit having an acid decomposable group.

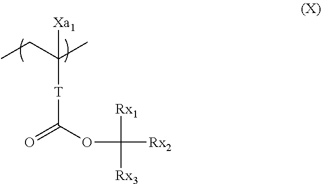

In General Formula (X),

Xa₁ represents a hydrogen atom, a methyl group, a trifluoromethyl group, or a hydroxymethyl group.

T represents a single bond or a bivalent linking group.

Each of Rx₁ to Rx₃ independently represents a straight chain or branched alkyl group or a monocyclic or polycyclic cycloalkyl group. In addition, 2 of Rx₁ to Rx₃ may be bonded to each other to form a monocyclic or polycyclic cycloalkyl group.

Examples of the bivalent linking group as T include an alkylene group, a —(COO-Rt)- group, and an —(O-Rt)- group. Here, Rt represents an alkylene group or a cycloalkylene group.

T is preferably a single bond or a —(COO-Rt)- group. Here, Rt is preferably an alkylene group having 1 to 5 carbon atoms, and a —CH₂— group, a —(CH₂)₂— group, or a —(CH₂)₃— group is more preferable.

The alkyl group as Rx₁ to Rx₃ is preferably an alkyl group having 1 to 4 carbon atoms such as a methyl group, an ethyl group, an n-propyl group, an isopropyl group, an n-butyl group, an isobutyl group, and a t-butyl group,

The cycloalkyl group as Rx₁ to Rx₃ is preferably a monocyclic cycloalkyl group such as a cyclopentyl group and a cyclohexyl group or a polycyclic cycloalkyl group such as a norbornyl group, a tetracyclodecanyl group, a tetracyclododecanyl group, and an adamantyl group.

As the cycloalkyl group that can be formed by bonding 2 of Rx₁ to Rx₃, a monocyclic cycloalkyl group such as a cyclopentyl group and a cyclohexyl group, or a polycyclic cycloalkyl group having a norbornyl group, a tetracyclodecanyl group, a tetracyclododecanyl group, and an adamantyl group is preferable.

Particularly, Rx₁ is a methyl group or an ethyl group, and an aspect in which Rx₂ and Rx₃ are bonded to each other and the cycloalkyl group described above is formed is preferable.

Specific examples of the repeating unit having acid decomposable properties are provided below, but the invention is not limited thereto.

(In the formula, H, CH₃, CF₃, CH₂OH, Rxa, and Rxb are respectively alkyl groups having 1 to 4 carbon atoms.)

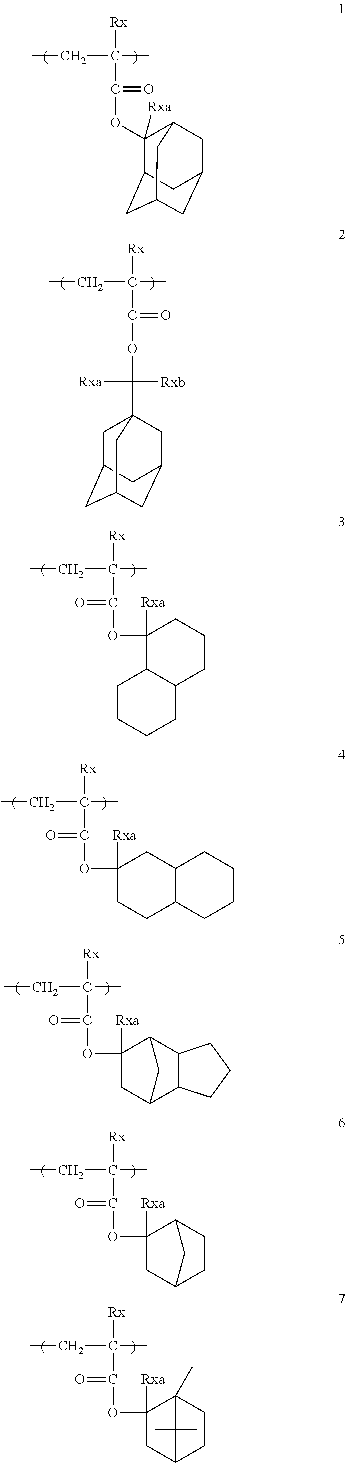

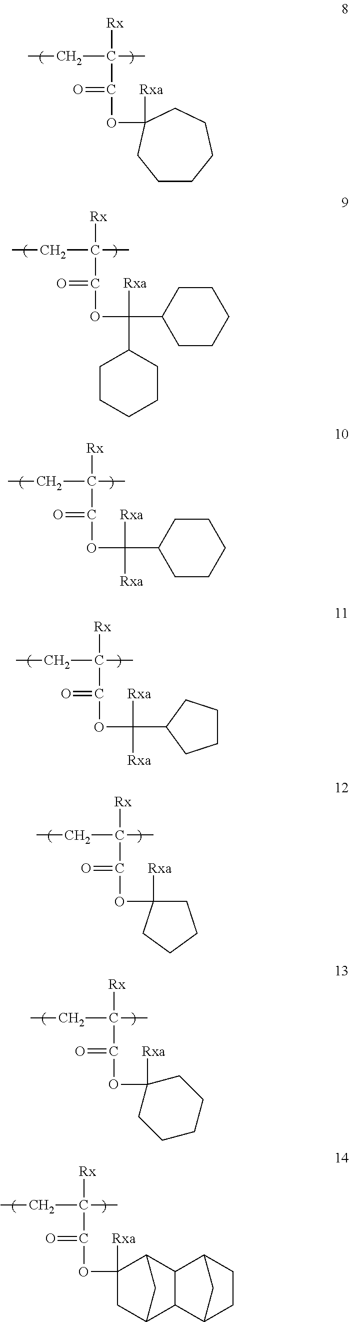

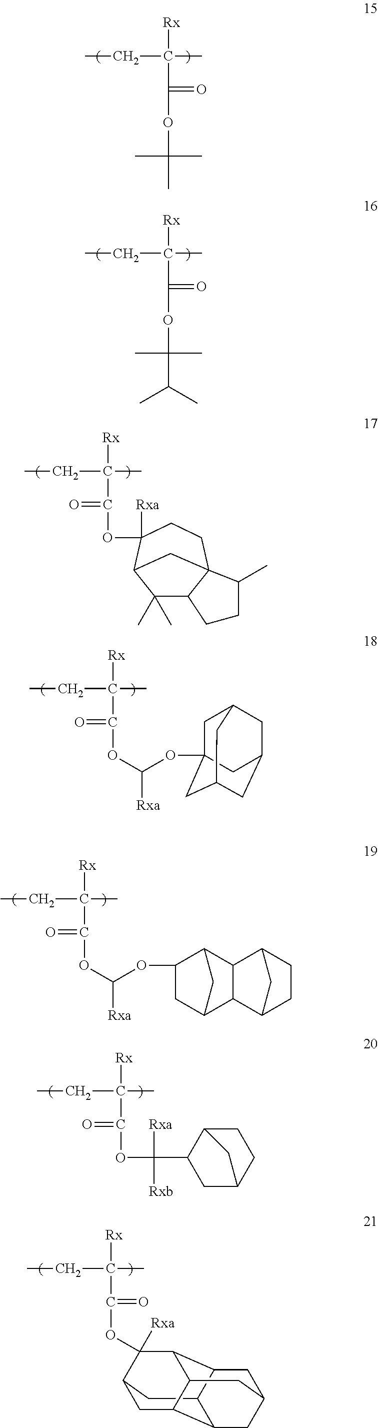

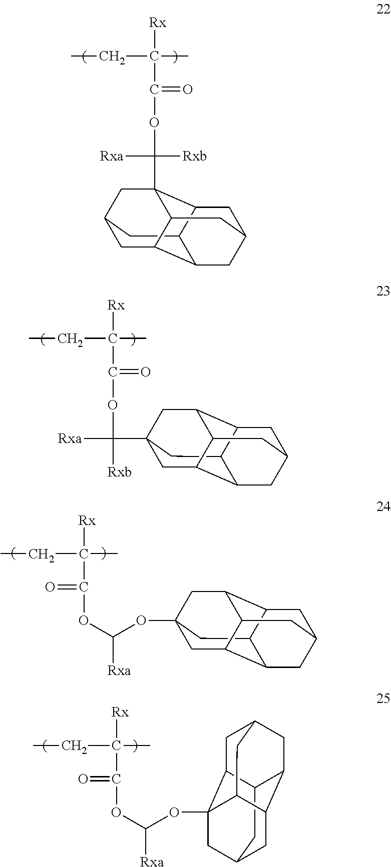

The content (the total when plural types are included) of the repeating unit having an acid decomposable group in the acid decomposable resin is preferably in the range of 3% by mol to 90% by mol, more preferably in the range of 5% by mol to 80% by mol, and particularly preferably in the range of 7% by mol to 70% by mol with respect to the total repeating unit of the acid decomposable resin.

The compound (P) as the acid decomposable resin may have a repeating unit including at least one type selected from a lactone group and a sultone group. Particularly, if the composition according to the invention is irradiated with ArF exciplex light, it is preferable to have a repeating unit having at least one type selected from a lactone group and a sultone group. The lactone group is preferably a group having a 5-membered to 7-membered ring lactone structure, and is particularly preferably a group in which another ring structure is condensed in a form of forming a bicyclo structure or a spire structure in a 5-membered to 7-membered ring lactone structure.

In addition, an optical isomer generally exists in a repeating unit having a lactone structure, and any optical isomer may be used. In addition, one type of optical isomer may be used singly, or plural optical isomers may be used in mixture. If one type of optical isomer is mainly used, an optical isomer having optical purity of 90% ee or greater is preferable, and an optical isomer having optical purity of 95% ee or greater is more preferable.

The compound (P) as the acid decomposable resin may contain or may not contain a repeating unit having a lactone structure. However, if the repeating unit having the lactone structure is contained, the content of the repeating unit in the compound (P) as the acid decomposable resin is preferably in the range of 1% by mol to 70% by mol, more preferably in the range of 3% by mol to 65% by mol, and still more preferably in the range of 5% by mol to 60% by mol with respect to the total repeating unit.

Examples of the particularly preferable repeating unit having the lactone group include repeating units described below. If an optimum lactone group is selected, a pattern profile and density dependency become satisfactory. In the formula, Rx and R represent H, CH₃, CH₂OH, or CF₃.

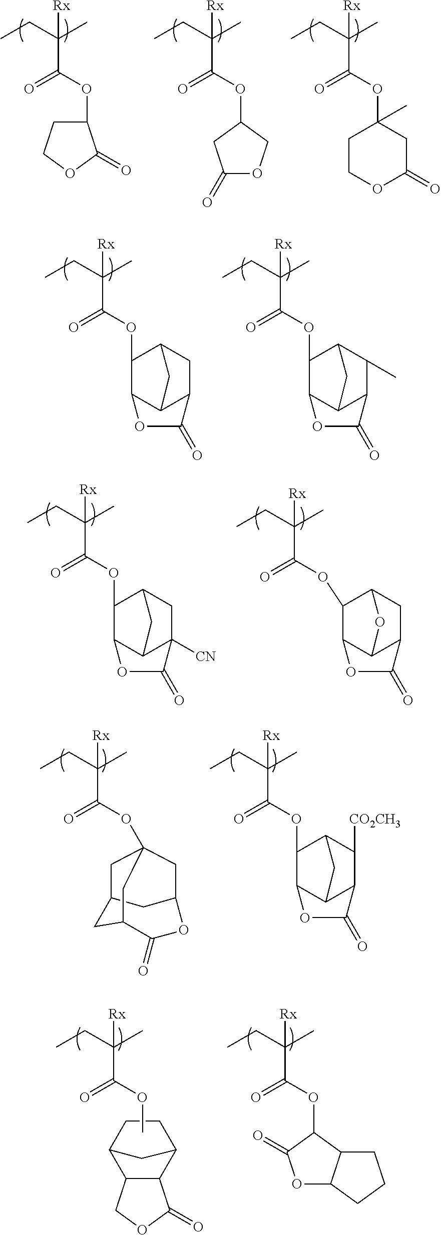

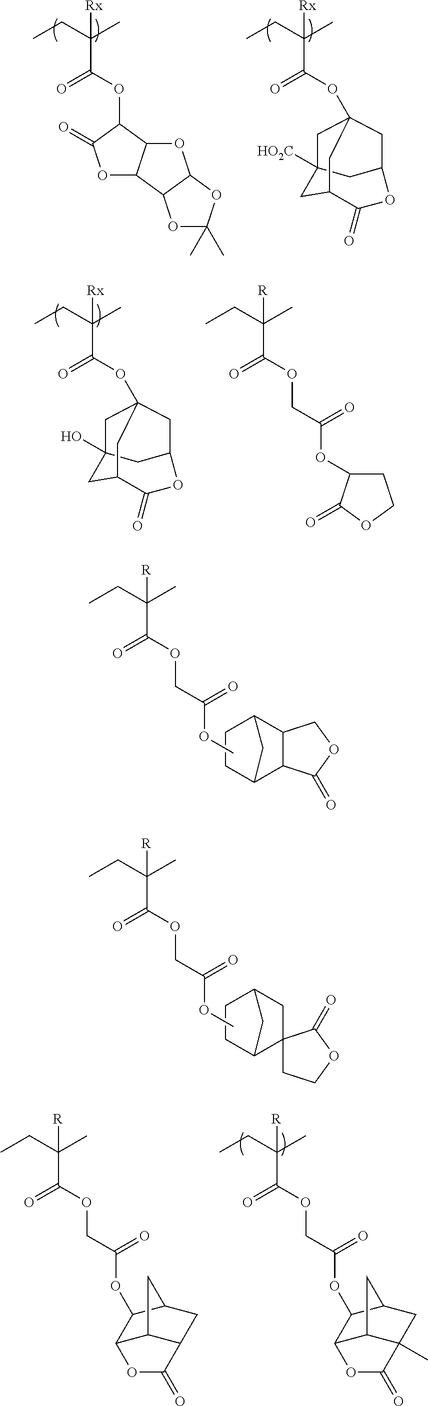

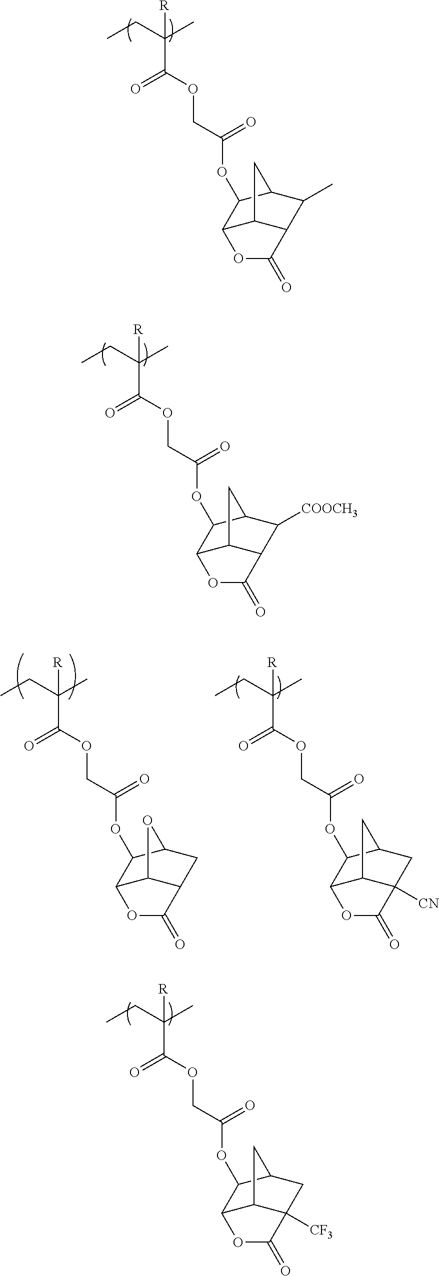

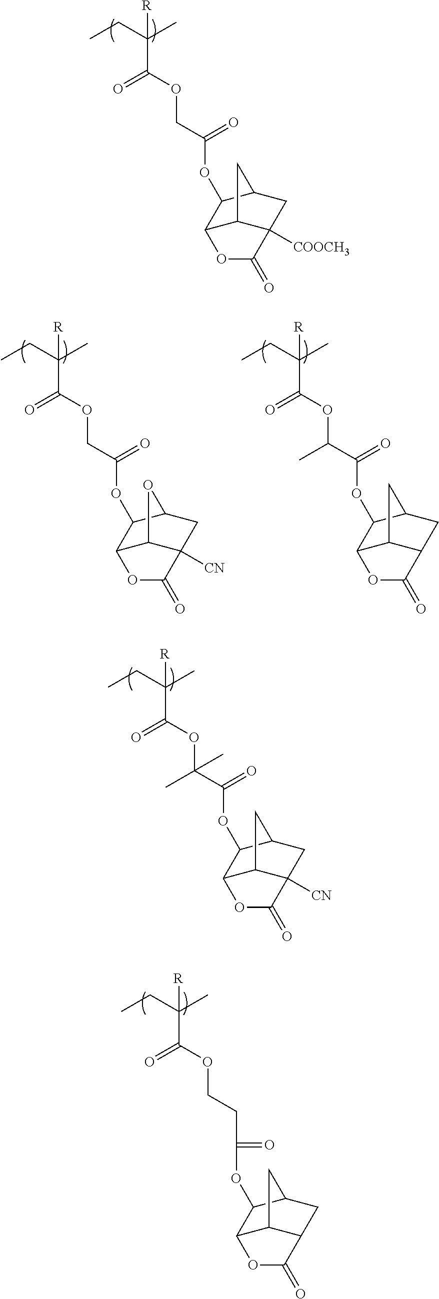

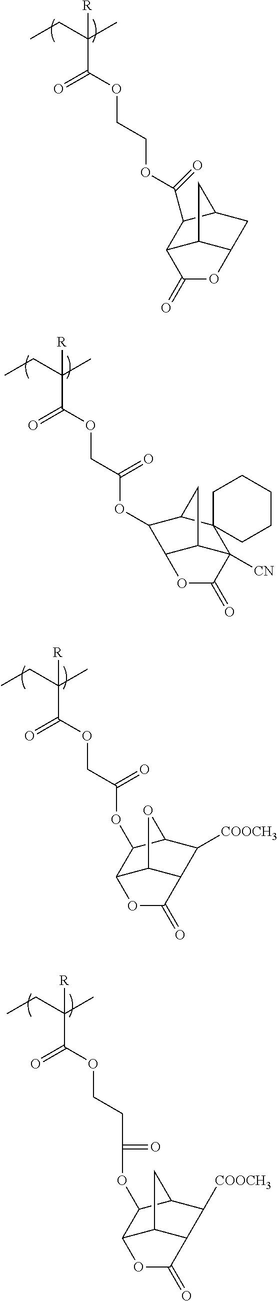

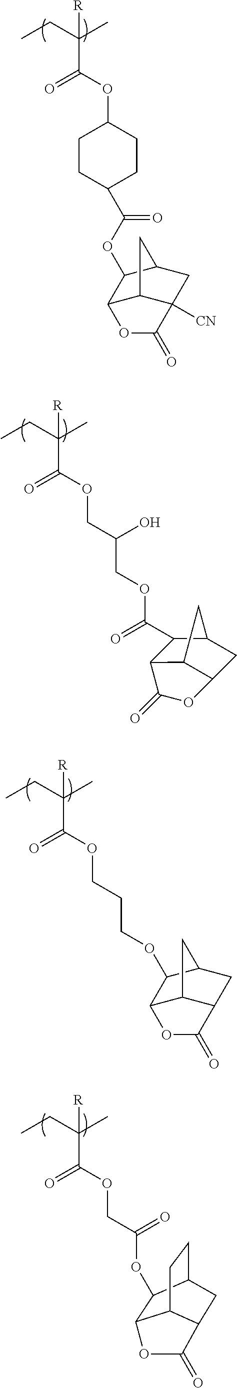

As the repeating unit having a compound (P) as an acid decomposable resin, examples of the repeating unit having the lactone group described above preferably include a repeating unit in which a lactone group is substituted with a sultone group.

The compound (P) as the acid decomposable resin may have a monocyclic or polycyclic alicylic hydrocarbon structure.

The compound (P) as the acid decomposable resin may have a repeating unit having a hydroxy group or a cyano group.

As the repeating unit having a hydroxy group or a cyano group, disclosures in paragraphs “0080” to “0089” of JP2013-113944A may be referred to, and the contents thereof is combined with this specification.

In addition, the compound (P) as the acid decomposable resin has an alicyclic hydrocarbon structure without a polar group and may have a repeating unit that does not exhibit acid decomposable properties.

As the repeating unit that has an alicyclic hydrocarbon structure without a polar group and does not exhibit acid decomposable properties, disclosures in paragraphs “0092 to 0098” of JP2013-113944A may be referred to, and the contents thereof is combined with this specification.

The compound (P) according to the invention may have a repeating unit having an ionic structure portion that is decomposed due to irradiation of the active rays or the radial ray s and generates an acid at a side chain of a resin. Examples of the repeating unit include a repeating unit expressed by General Formula (PS) below.

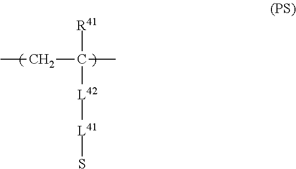

R⁴¹ represents a hydrogen atom or a methyl group. L⁴¹ represents a single bond or a bivalent linking group. L⁴² represents a bivalent linking group. S represents structure portion that is decomposed due to the irradiation of active rays or radial rays and generates an acid at a side chain.

The content of the repeating unit expressed by General Formula (PS) in the compound (P) as the acid decomposable resin is preferably in the range of 1% by mol to 40% by mol, more preferably in the range of 2% by mol to 30% by mol, and particularly preferably in the range of 5% by mol to 25% by mol with respect to the total repeating unit of the compound (P) as the acid decomposable resin.

Specific examples of the compound (P) having a phenolic hydroxy group as the acid decomposable resin described above are provided below, but the invention is not limited thereto.

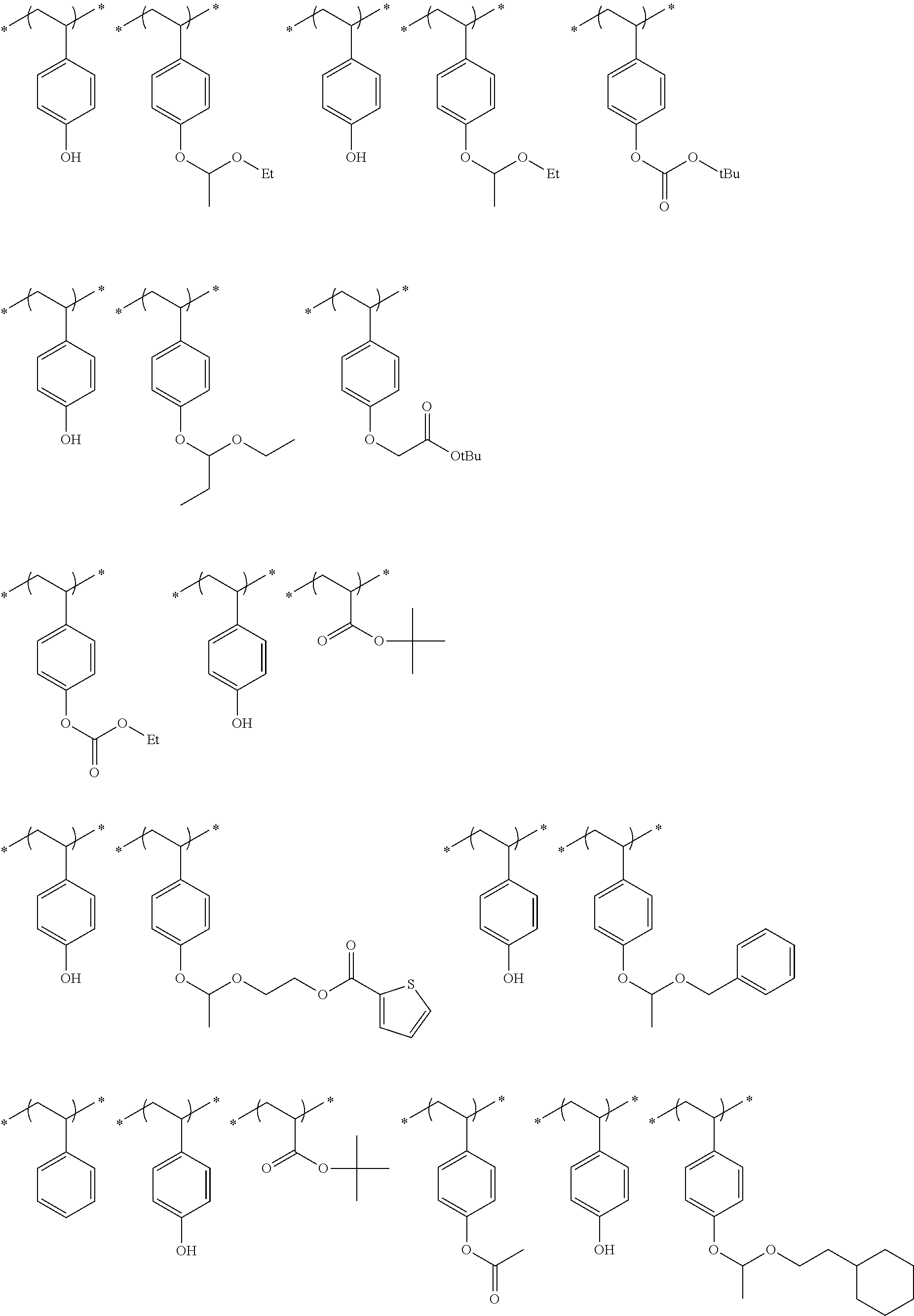

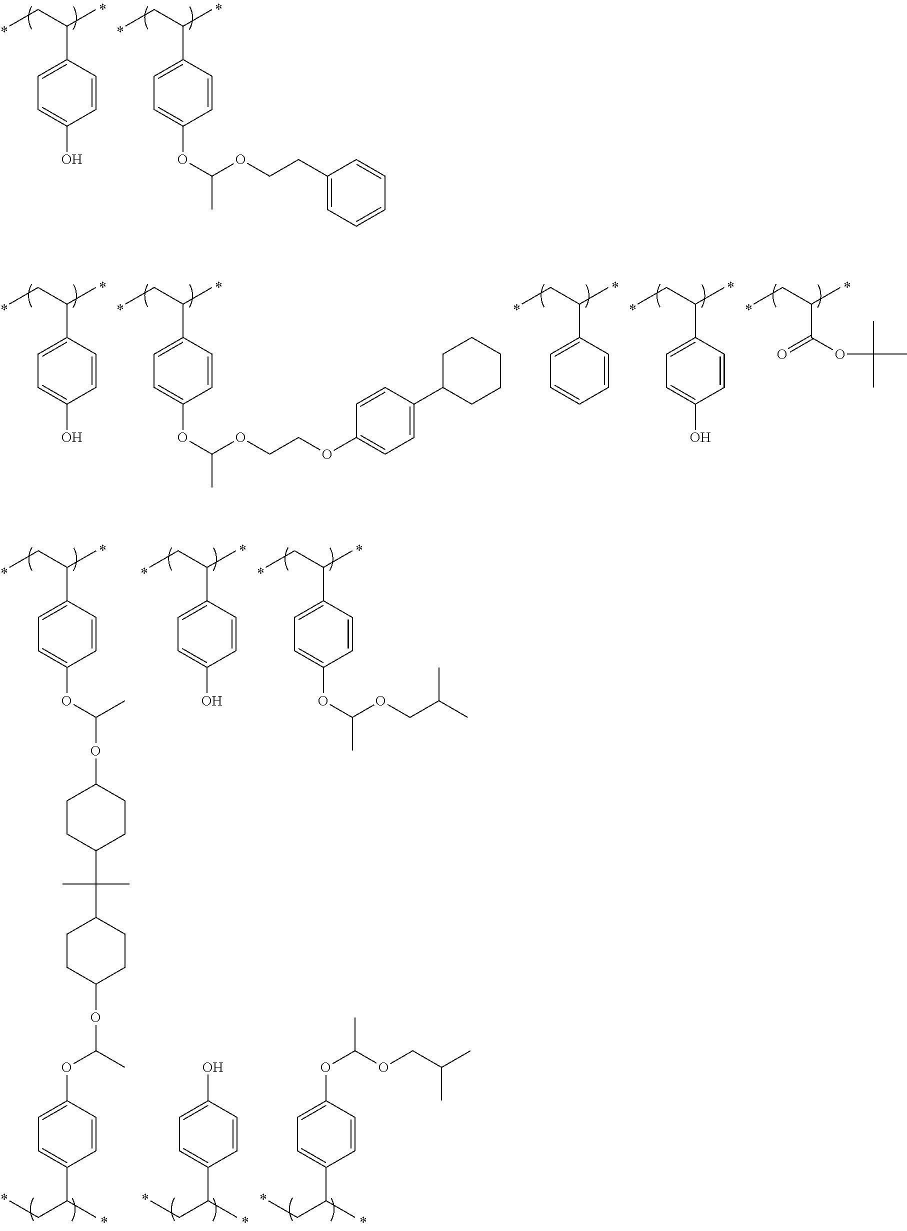

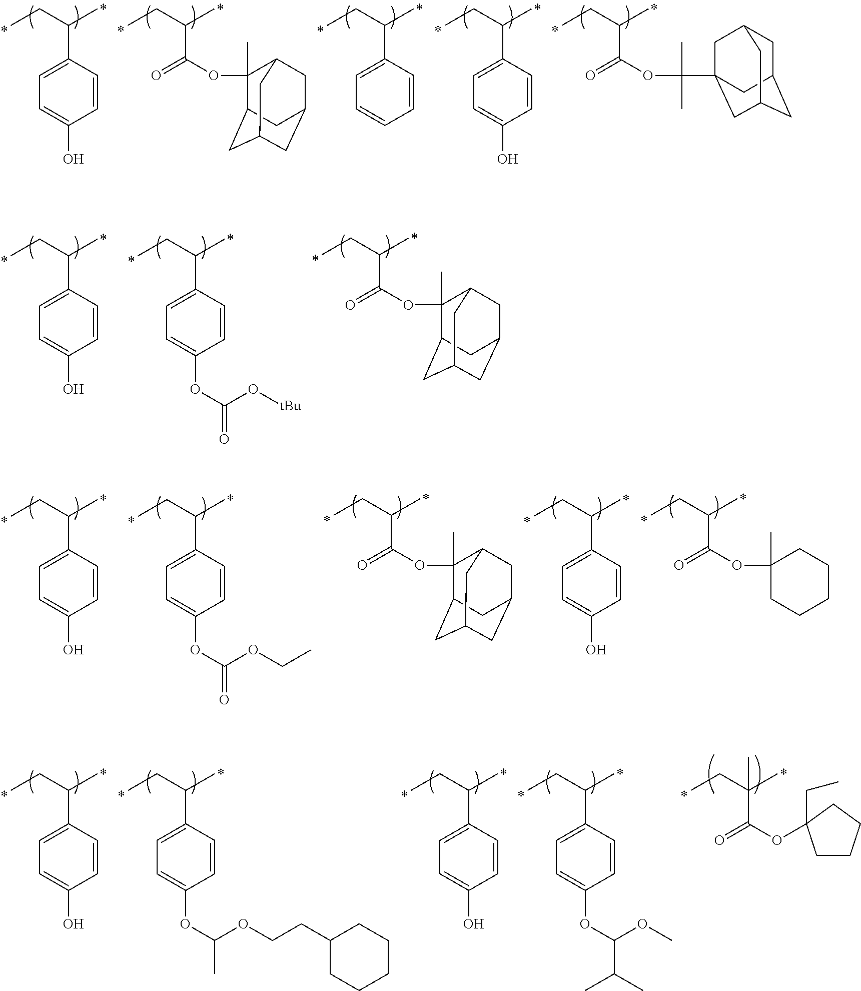

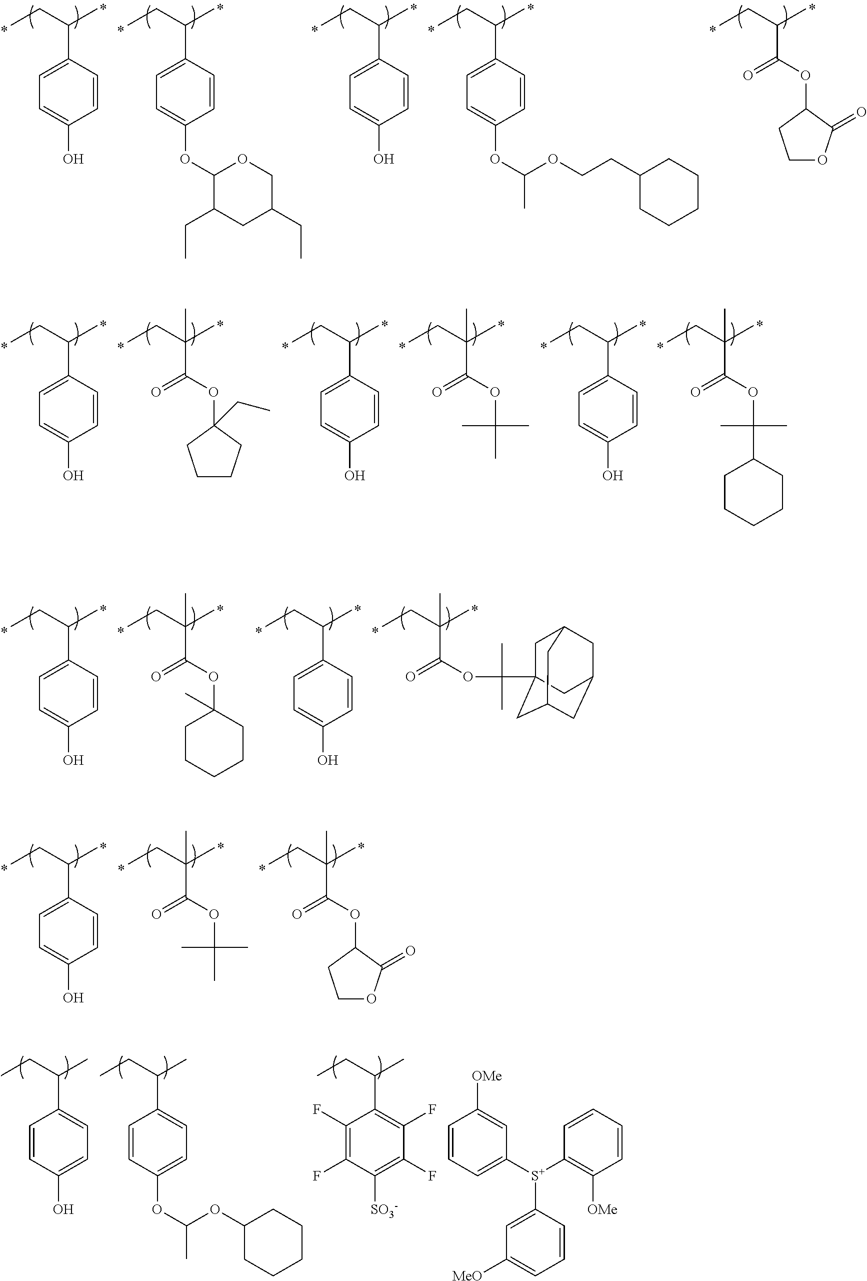

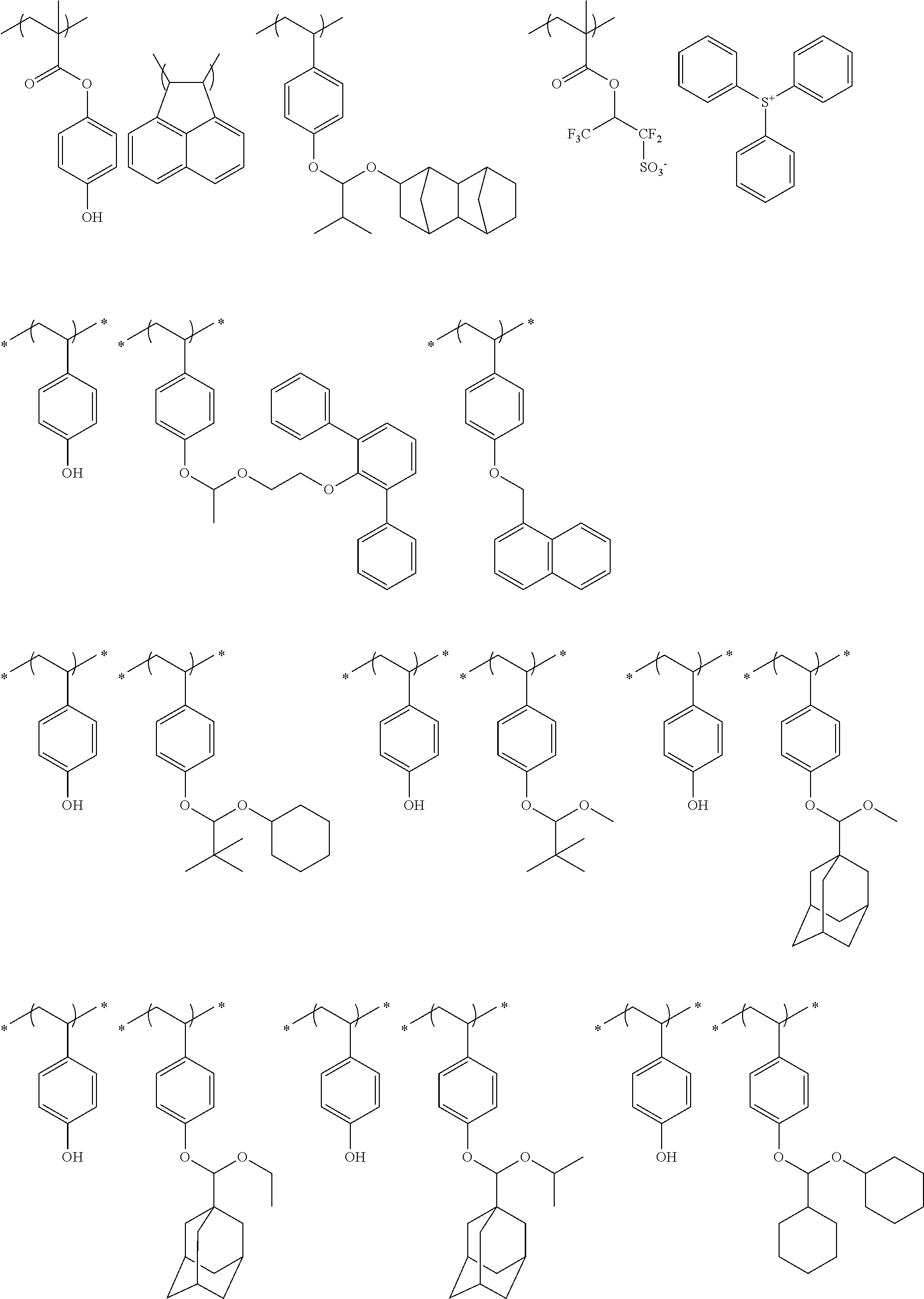

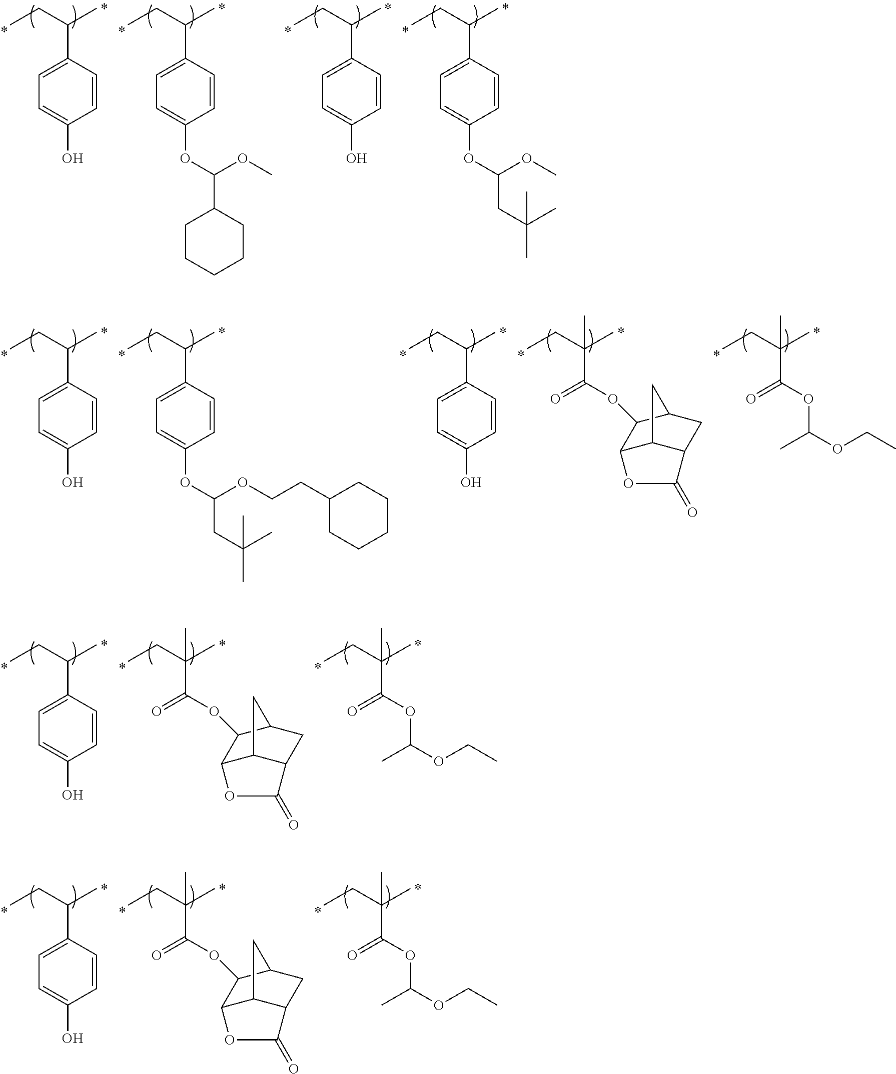

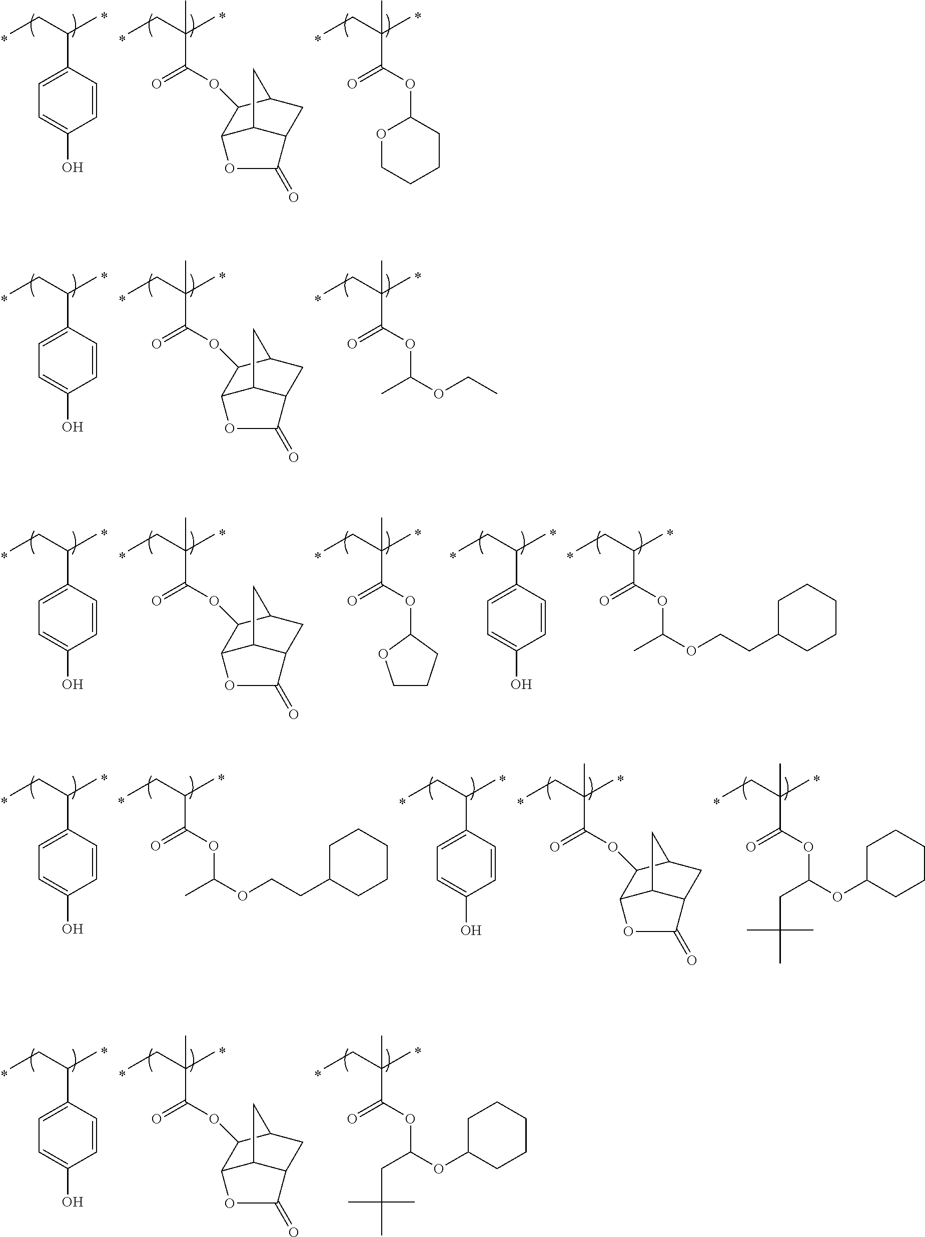

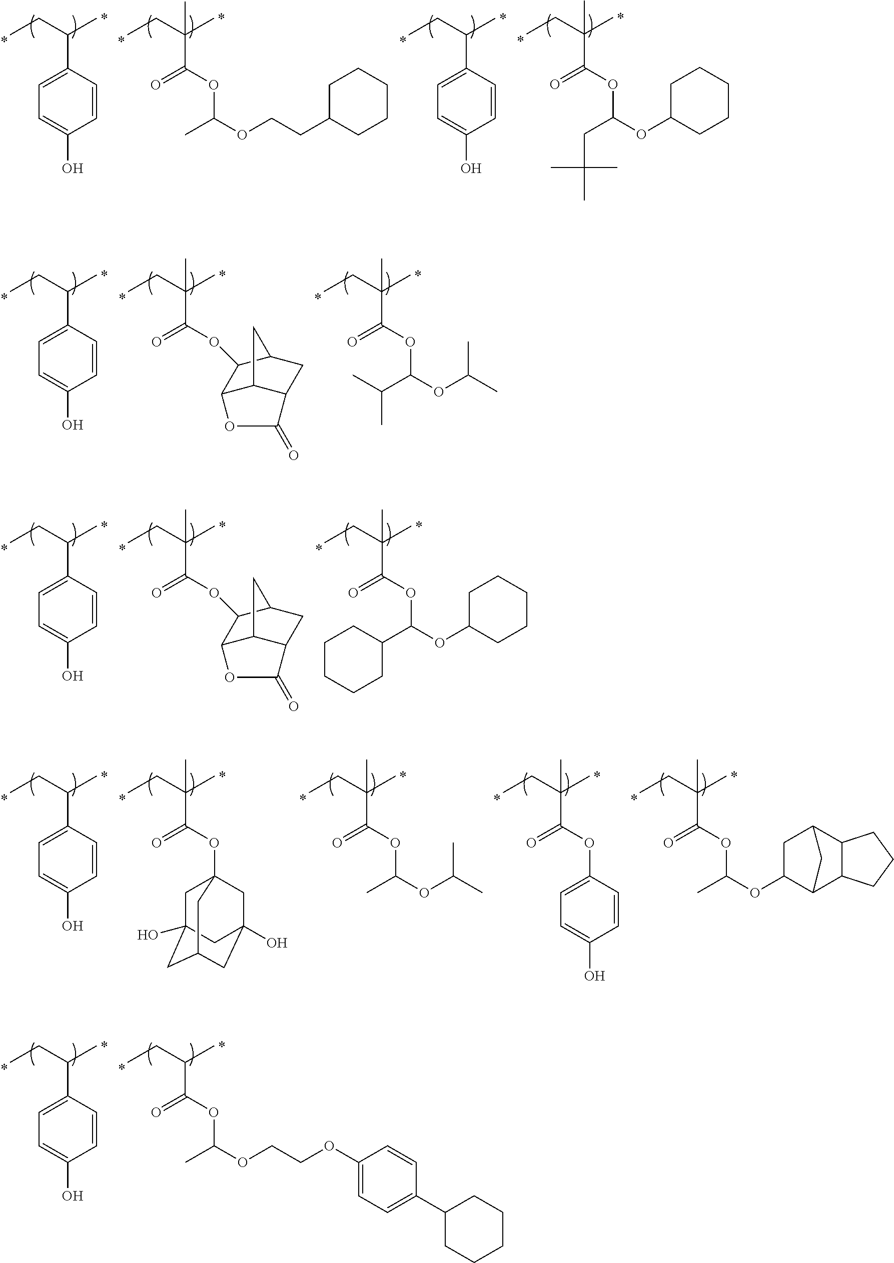

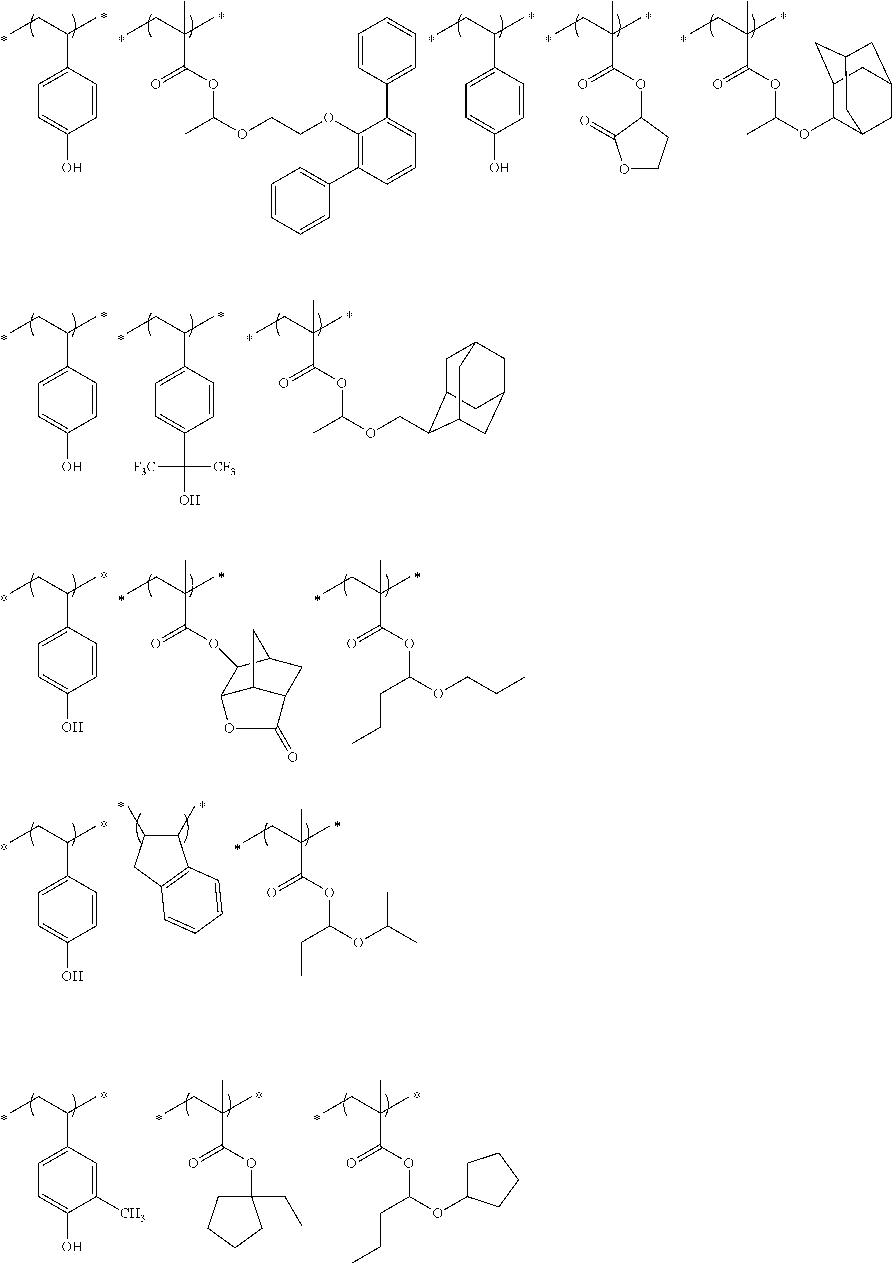

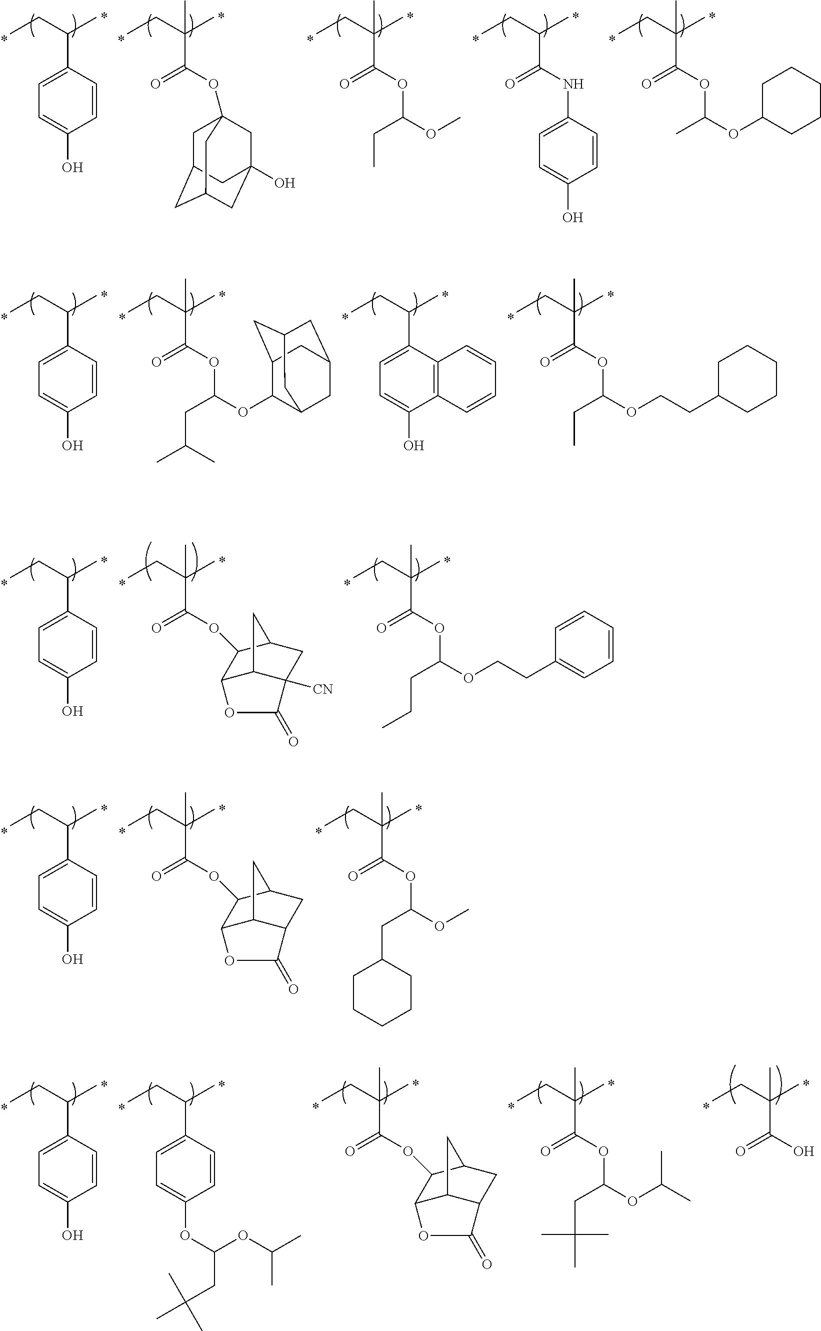

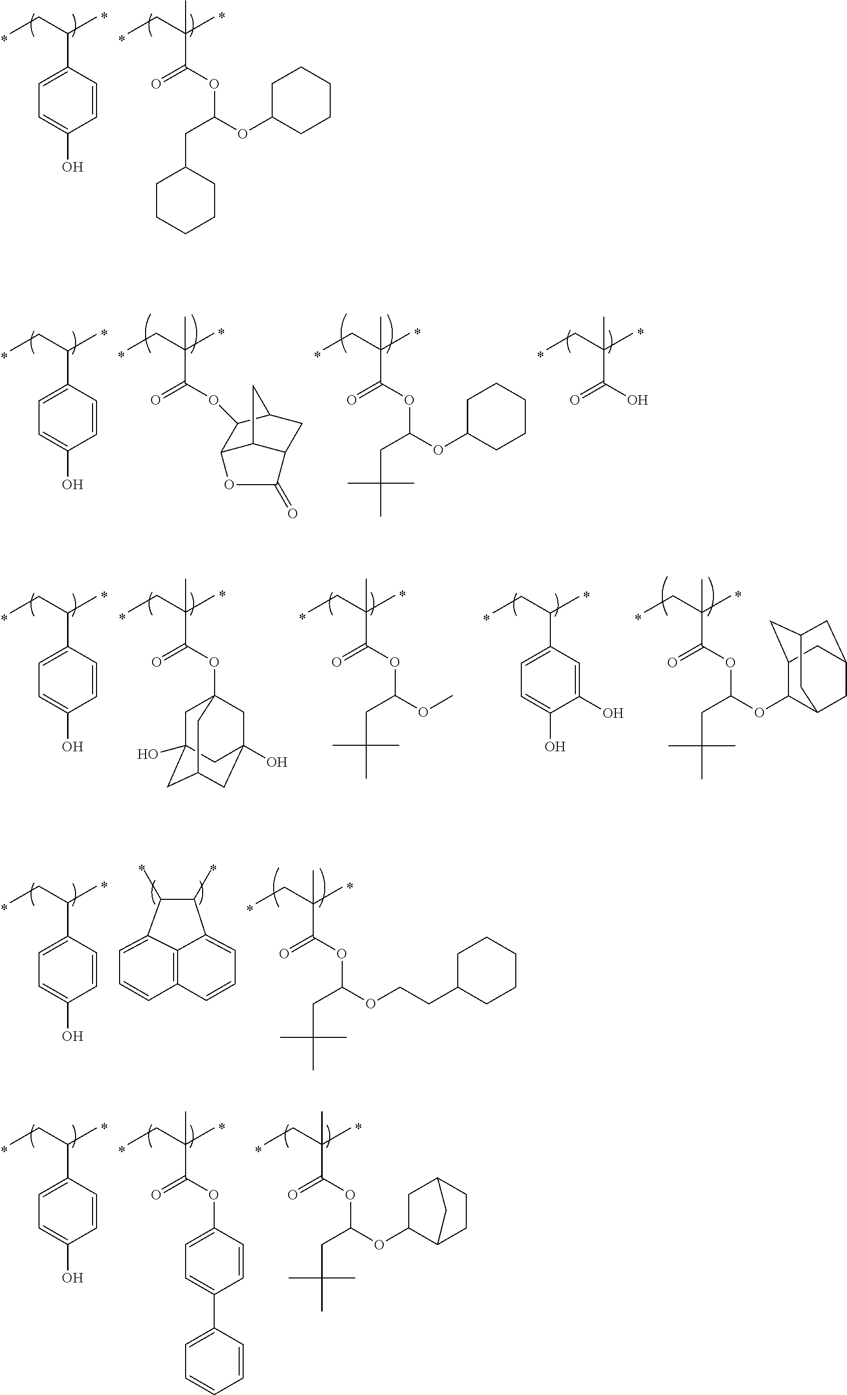

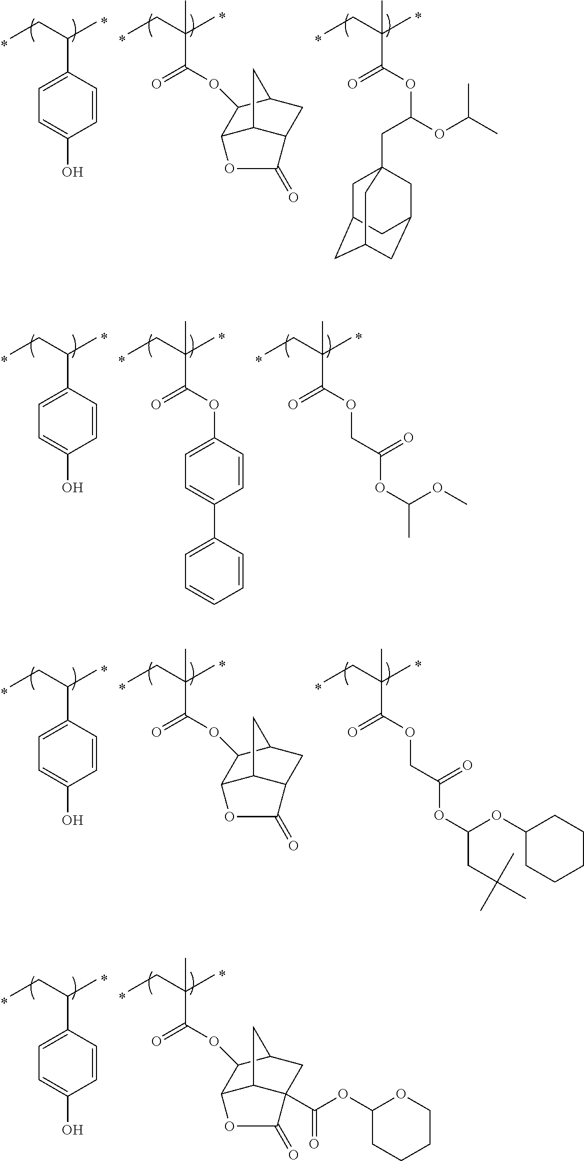

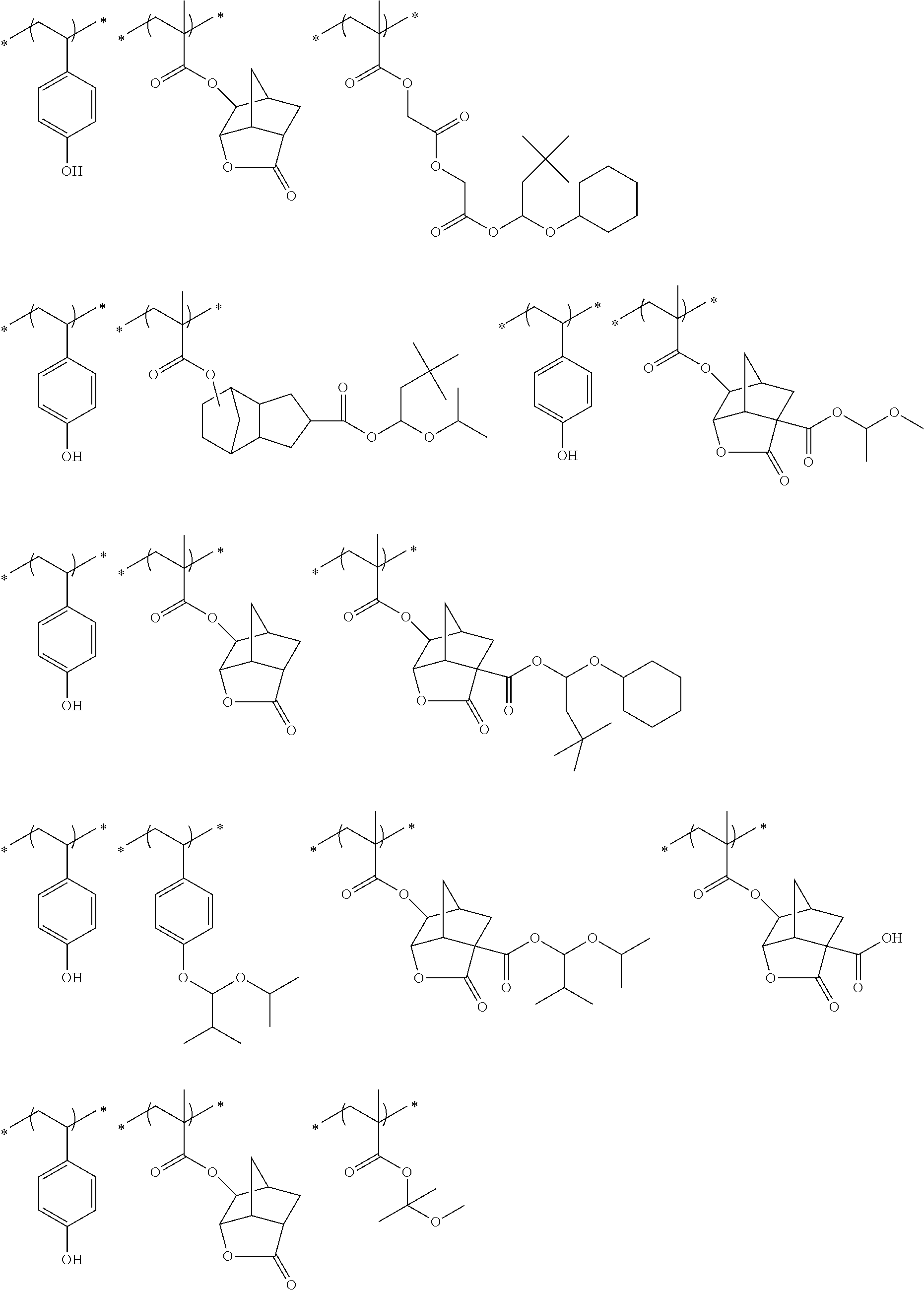

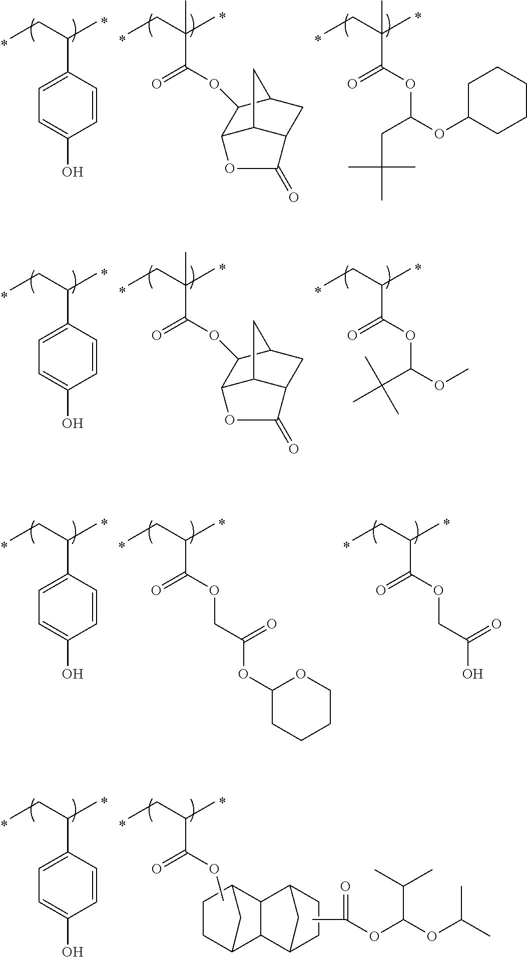

In the specific examples above, tBu represents a t-butyl group.

The content ratio of the group that can be decomposed by an acid is calculated by a formula B/(B+S) with the number (B) of groups that can be decomposed by an acid in a resin, and the number (S) of polar groups (alkaline soluble polymers at the time of alkaline development) that are not protected with groups that are released by an acid. The content ratio thereof is preferably 0.01 to 0.7, more preferably 0.05 to 0.50, and still more preferably 0.05 to 0.40.

(2-2) Compound (P) Having Phenolic Hydroxy Group Used in a Crosslinked Negative Chemical Amplification Type Resist Composition

An embodiment in which the resist composition for the semiconductor manufacturing process according to the invention contains (C) an acid crosslinking compound described below and the resist composition for the semiconductor manufacturing process according to the invention is used as a negative chemical amplification type resist composition is one of preferable embodiments. In this embodiment, the compound (P) having a phenolic hydroxy group is a group having a non-acid decomposable polycyclic alicyclic hydrocarbon structure, and it is preferable to further have a structure in which a hydrogen atom of a phenolic hydroxy group is substituted, since a high glass transition temperature (Tg) is obtained, and dry etching resistance becomes satisfactory.

If the compound (P) has the specific structure described above, the glass transition temperature (Tg) of the compound (P) becomes high, and thus a stronger resist film can be formed, such that diffusion properties of an acid are controlled and dry etching resistance can be improved. Accordingly, since diffusion properties of an acid in the exposed portion with active rays such as electron beams or extreme ultraviolet rays or radial rays are further suppressed, resolving power, pattern forms, and LER in a fine pattern become further excellent. In addition, it is considered that the compound (P) having a non-acid decomposable polycyclic alicyclic hydrocarbon structure contributes to further improvement of dry etching resistance.

Further, specifics are unclear, but it is assumed that donating properties of a hydrogen radical of the polycyclic alicyclic hydrocarbon structure are high and the hydrogen radical becomes a hydrogen source at the time of decomposition of a photo-acid generator, decomposition efficiency of a photo-acid generator is further improved, and acid generation efficiency becomes higher. Therefore, it is considered that this contributes to more excellent sensitivity.

In the specific structure described above that may be included in the compound (P) according to the invention, an aromatic ring such as a benzene ring and a group having a non-acid decomposable polycyclic alicyclic hydrocarbon structure are linked to each other via an oxygen atom derived from the phenolic hydroxy group. As described above, the structure contributes not only to high dry etching resistance but also to the increase in the glass transition temperature (Tg) of the compound (P). Therefore, it is assumed that higher resolving power is provided by these effects in combination.

According to the invention, non-acid decomposable properties refer to properties of not generating decomposition reaction by an acid due to an acid generator.

Specifically, the group having the non-acid decomposable polycyclic alicyclic hydrocarbon structure is preferably a group which remains stable in the presence of an acid and an alkali. The group stable to an acid and an alkali refers to a group which does not exhibit acid decomposable properties and alkali decomposable properties. Here, the acid decomposable properties refer to properties of causing decomposition reaction by the action of an acid generated by an acid generator, and examples of the group exhibiting the acid decomposable properties includes an acid decomposable group that is described in the “repeating unit having the acid decomposable group” described above.

In addition, the alkali decomposable properties refer to properties of causing decomposition reaction by an action of an alkaline developer, and examples of the group exhibiting alkali decomposable properties include a group that is included in a resin which is suitably used in the resist composition for the semiconductor manufacturing process (particularly, positive chemical amplification type resist composition) and which is decomposed by an action of an alkaline developer well-known in the related art such that a dissolution rate in an alkaline developer increases (for example, a group having a lactone structure).

The group having the polycyclic alicyclic hydrocarbon structure is not particularly limited as long as the group is a univalent group having a polycyclic alicyclic hydrocarbon structure, but the total number of carbon atoms is preferably 5 to 40 and more preferably 7 to 30. The polycyclic alicyclic hydrocarbon structure may have an unsaturated bond in the ring.

The polycyclic alicyclic hydrocarbon structure in the group having the polycyclic alicyclic hydrocarbon structure refers to a structure of having plural monocyclic alicyclic hydrocarbon groups or a polycyclic alicyclic hydrocarbon structure, and may be a bridged type. As the monocyclic alicyclic hydrocarbon group, a cycloalkyl group having 3 to 8 carbon atoms is preferable, and examples thereof include a cyclopropyl group, a cyclopentyl group, a cyclohexyl group, a cyclobutyl group, and a cyclooctyl group, and, the structure having plural monocyclic alicyclic hydrocarbon group has plural items of these groups. The structure having plural monocyclic alicyclic hydrocarbon groups preferably has 2 to 4 monocyclic alicyclic hydrocarbon groups and particularly preferably has 2 monocyclic alicyclic hydrocarbon groups.

Examples of the polycyclic alicyclic hydrocarbon structure include bicyclo, tricyclo, or tetracyclo structures having 5 or more carbon atoms, a polycyclic structure having 6 to 30 carbon atoms is preferable, and examples thereof include an adamantane structure, a decalin structure, a norbornane structure, a norbornene structure, a cedrol structure, an isobornane structure, a bornane structure, a dicyclopentane structure, an α-pinene structure, a tricyclodecane structure, a tetracyclododecane structure, or an androstane structure. In addition, a portion of carbon atoms in the monocyclic or polycyclic cycloalkyl group may be substituted with a hetero atom such as an oxygen atom.

Preferable examples of the polycyclic alicyclic hydrocarbon structure described above include an adamantane structure, a decalin structure, a norbornane structure, a norbornene structure, a cedrol structure, a structure having plural cyclohexyl groups, a structure of having plural cycloheptyl groups, a structure of having plural cyclooctyl groups, a structure of having plural cyclodecanyl groups, a structure of having plural cyclododecanyl groups, and a tricyclodecane structure. An adamantane structure is most preferable, in view of dry etching resistance (that is, a group of having the non-acid decomposable polycyclic alicyclic hydrocarbon structure is most preferably a group of having a non-acid decomposable adamantane structure).

Chemical formulae of these polycyclic alicyclic hydrocarbon structures (with respect to structures having plural monocyclic alicyclic hydrocarbon groups, monocyclic alicyclic hydrocarbon structures corresponding to the monocyclic alicyclic hydrocarbon groups (specifically, structures of Formulae (47) to (50) below)) are provided below.

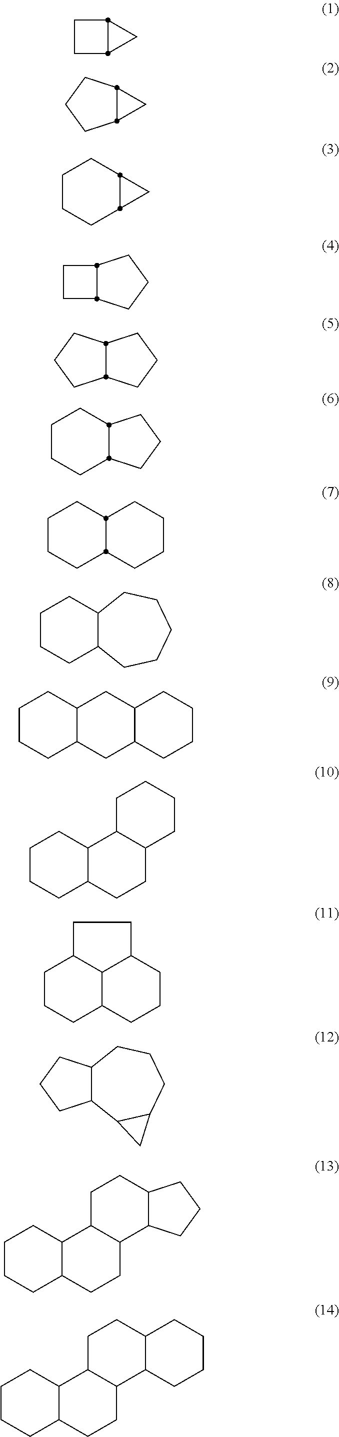

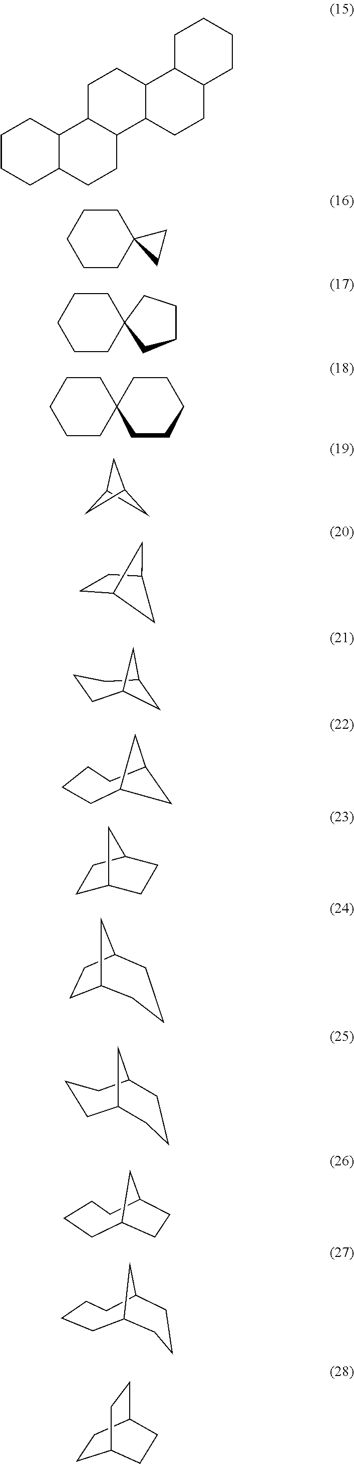

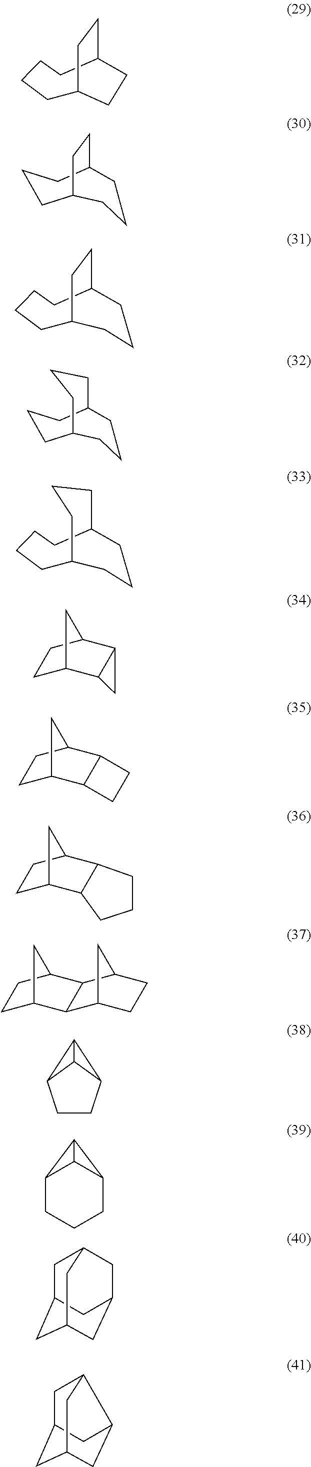

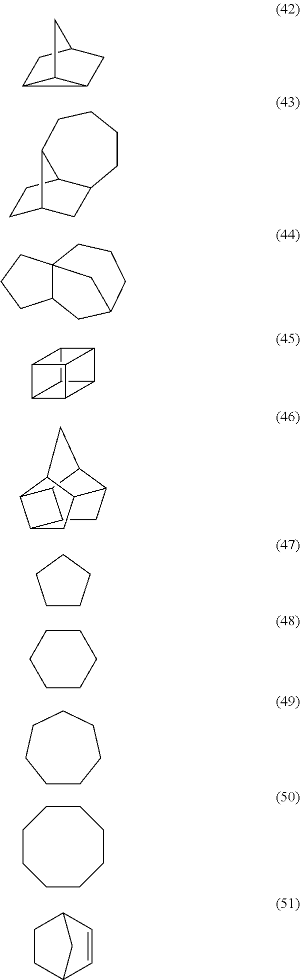

Further, the polycyclic alicyclic hydrocarbon structure may have a substituent, and examples of the substituent include an alkyl group (preferably having 1 to 6 carbon atoms), a cycloalkyl group (preferably having 3 to 10 carbon atoms), an aryl group (preferably having 6 to 15 carbon atoms), a halogen atom, a hydroxy group, an alkoxy group (preferably having 1 to 6 carbon atoms), a carboxyl group, a carbonyl group, a thiocarbonyl group, and an alkoxycarbonyl group (preferably having 2 to 7 carbon atoms), and groups obtained by combining these groups (the total number of carbon atoms is preferably 1 to 30, and the total number of carbon atoms is more preferably 1 to 15).

As the polycyclic alicyclic hydrocarbon structure, a structure expressed by any one of Formulae (7), (23), (40), (41), and (51) above and a structure of having 2 univalent groups using any one of hydrogen atom as a bonding hand in the structure of Formula (48) above are preferable, a structure expressed by any one of Formulae (23), (40), and (51) and a structure of having 2 univalent groups using any one of hydrogen atom as a bonding hand in the structure of Formula (48) above are more preferable, and a structure expressed by Formula (40) is most preferable.

As the group having the polycyclic alicyclic hydrocarbon structure, a univalent group using any one of hydrogen atom in the polycyclic alicyclic hydrocarbon structure above as a bonding hand is preferable.

A structure in which a hydrogen atom in a phenolic hydroxy group is substituted with a group having the non-acid decomposable polycyclic alicyclic hydrocarbon structure described above is preferably contained in the compound (P) as a resin, as a repeating unit having a structure in which a hydrogen atom in a phenolic hydroxy group is substituted with a group having the non-acid decomposable polycyclic alicyclic hydrocarbon structure described above and more preferably contained in the compound (P) as the repeating unit expressed by General Formula (3) below.

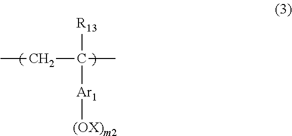

In General Formula (3), R₁₃ represents a hydrogen atom or a methyl group.

X represents a group having a non-acid decomposable polycyclic alicyclic hydrocarbon structure.

Ar₁ represents an aromatic ring.

m2 represents an integer of 1 or greater.

R₁₃ in General Formula (3) represents a hydrogen atom or a methyl group, and a hydrogen atom is particularly preferable.

Examples of the aromatic ring of Ar₁ of General Formula (3) include an aromatic hydrocarbon ring that may have a substituent having 6 to 18 carbon atoms such as a benzene ring, a naphthalene ring, an anthracene ring, a fluorene ring, and a phenanthrene ring or an aromatic heterocyclic ring including a heterocyclic ring such as a thiophene ring, a furan ring, a pyrrole ring, a benzothiophene ring, a benzofuran ring, a benzopyrrole ring, a triazine ring, an imidazole ring, a benzimidazole ring, a triazole ring, a thiadiazole ring, and a thiazole ring. Among these, a benzene ring and a naphthalene ring are preferable in view of resolution, and a benzene ring is most preferable.

The aromatic ring of Ar₁ may have a substituent in addition to a group expressed by —OX described above, and examples of the substituent include an alkyl group (preferably having 1 to 6 carbon atoms), a cycloalkyl group (preferably having 3 to 10 carbon atoms), an aryl group (prefer ably having 6 to 15 carbon atoms), a halogen atom, a hydroxy group, an alkoxy group (preferably having 1 to 6 carbon atoms), a carboxyl group, and an alkoxycarbonyl group (preferably having 2 to 7 carbon atoms), and an alkyl group, an alkoxy group, and an alkoxycarbonyl group are preferable, and an alkoxy group is more preferable.

X represents a group having a non-acid decomposable polycyclic alicyclic hydrocarbon structure. Specific examples and preferable ranges of the group having the non-acid decomposable polycyclic alicyclic hydrocarbon structure expressed by X are the same as those described above. X is more preferably a group represented by —Y—X₂ in General Formula (4) below.

m2 is preferably an integer of 1 to 5, and most preferably 1. When m2 is 1 and Ar₁ is a benzene ring, the substitution position of —OX may be a para position, may be a meta position, or may be an ortho position with respect to the bonding position to the polymer main chain of the benzene ring, a para position or a meta position is preferable, and a para position is more preferable.

According to the invention, the repeating unit expressed by General Formula (3) above is preferably a repeating unit expressed by General Formula (4) below.

If the a resin (P) having a repeating unit expressed by General Formula (4) is used, Tg of the resin (P) increases and forms a stronger resist film. Therefore, diffusion properties of an acid are controlled, and dry etching resistance can be more definitely improved.

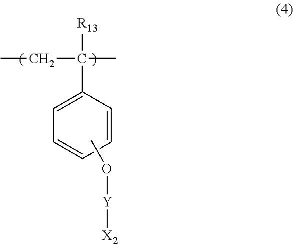

In General Formula (4), R₁₃ represents a hydrogen atom or a methyl group.

Y represents a single bond or a bivalent linking group.

X₂ represents a non-acid decomposable polycyclic alicyclic hydrocarbon group.

Preferable examples of the repeating unit expressed by General Formula (4) above to be used in the invention are described below.

R₁₃ in General Formula (4) represents a hydrogen atom or a methyl group, but a hydrogen atom is particularly preferable.

In General Formula (4), Y is preferably a bivalent linking group. The preferable group as a bivalent linking group of Y is a carbonyl group, a thiocarbonyl group, and an alkylene group (preferably having 1 to 10 carbon atoms, more preferably having 1 to 5 carbon atoms), a sulfonyl group, —COCH₂—, or —NH— or a bivalent linking group obtained by combining these (the total number of carbon atoms is preferably 1 to 20, and the total number of carbon atoms is more preferably 1 to 10), a carbonyl group, —COCH₂—, a sulfonyl group, —CONH—, and —CSNH— are more preferable, a carbonyl group and —COCH₂— are still more preferable, and a carbonyl group is particularly preferable.

X₂ represents a polycyclic alicyclic hydrocarbon group and has non-acid decomposable properties. The total number of carbon atoms in the polycyclic alicyclic hydrocarbon group is preferably 5 to 40 and more preferably 7 to 30. The polycyclic alicyclic hydrocarbon group may have an unsaturated bond in a ring.

A polycyclic alicyclic hydrocarbon group like this is a group having plural monocyclic alicyclic hydrocarbon groups or a polycyclic alicyclic hydrocarbon group, and may be a bridged type. As the monocyclic alicyclic hydrocarbon group, a cycloalkyl group having 3 to 8 carbon atoms is preferable. Examples thereof include a cyclopropyl group, a cyclopentyl group, a cyclohexyl group, a cyclobutyl group, and a cyclooctyl group, and plural items of these groups are included. The group having plural monocyclic alicyclic hydrocarbon groups preferably includes 2 to 4 monocyclic alicyclic hydrocarbon groups, and particularly preferably includes 2 monocyclic alicyclic hydrocarbon groups.

Examples of the polycyclic alicyclic hydrocarbon group include a group having a bicyclo, tricyclo, or tetracyclo structure having 5 or more carbon atoms, and a group having a polycyclic structure having 6 to 30 carbon atoms is preferable, and examples thereof include an adamantyl group, a norbornyl group, a norbornenyl group, an isobornyl group, a camphanyl group, a dicyclopentyl group, an α-pinel group, a tricyclodecanyl group, a tetracyclododecyl group, and an androstanyl group. In addition, a portion of carbon atoms in a monocyclic or polycyclic cycloalkyl group may be substituted with a hetero atom such as an oxygen atom.

The polycyclic alicyclic hydrocarbon group of X₂ above is preferably an adamantyl group, a decalin group, a norbornyl group, a norbornenyl group, a cedrol group, a group having plural cyclohexyl groups, a group having plural cycloheptyl groups, a group having plural cyclooctyl groups, a group having plural cyclodecanyl groups, a group having plural cyclododecanyl groups, and a tricyclodecanyl group, and an adamantyl group is most preferable, in view of dry etching resistance. Examples of the chemical formula of the polycyclic alicyclic hydrocarbon structure in the polycyclic alicyclic hydrocarbon group of X₂ include the same examples of the chemical formula of the polycyclic alicyclic hydrocarbon structure in the group having the polycyclic alicyclic hydrocarbon structure described above, and preferable ranges are also the same. The polycyclic alicyclic hydrocarbon group of X₂ includes a univalent group using any one of hydrogen atoms in the polycyclic alicyclic hydrocarbon structure described above as a bonding hand.

Further, the alicyclic hydrocarbon group may have a substituent, and examples of the substituent include the same examples described as the substituent that may be included in the polycyclic alicyclic hydrocarbon structure.

The substitution position of —O—Y—X₂ in General Formula (4) may be a para position, may be a meta position, or may be a ortho position with respect to the bonding position to the polymer main chain of the benzene ring, but a para position is preferable.

According to the invention, the repeating unit expressed by General Formula (3) above is most preferably a repeating unit expressed by General Formula (4′) below.

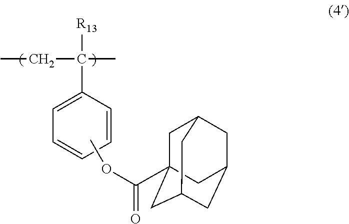

In General Formula (4′), R₁₃ represents a hydrogen atom or a methyl group.

R₁₃ in General Formula (4) represents a hydrogen atom or a methyl group, and a hydrogen atom is particularly preferable.

The substitution position of the an adamantyl ester group in General Formula (4′) may be a para position, may be a meta position, or may be an ortho position with respect to the bonding position to the polymer main chain of the benzene ring, but a para position is preferable.

The specific examples of the repeating unit expressed by General Formula (3) are as provided below.

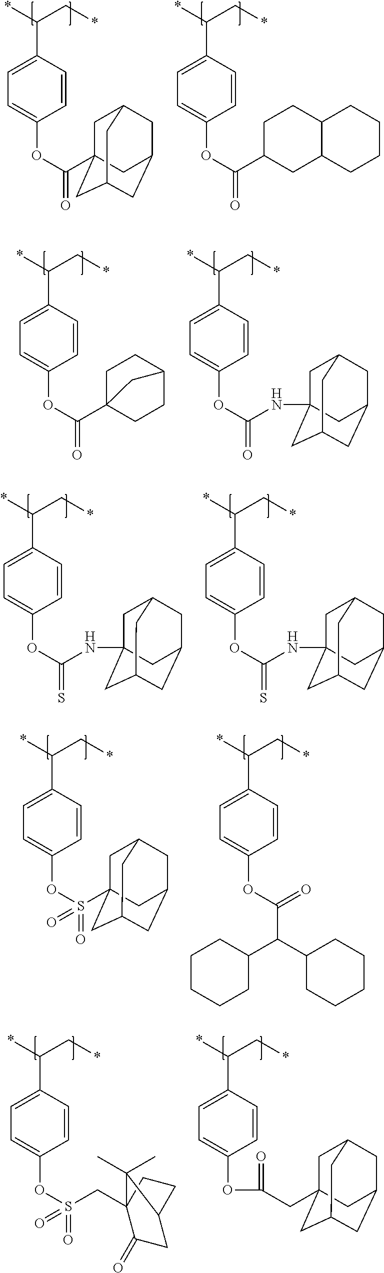

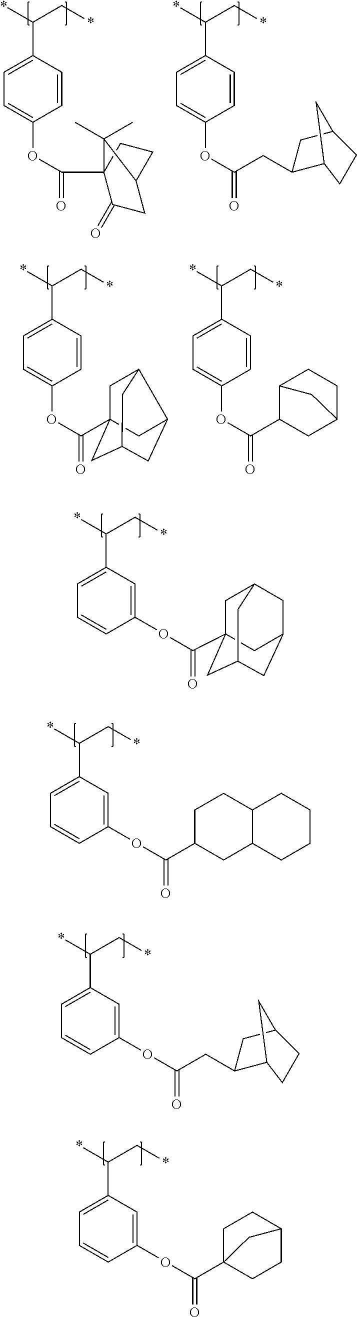

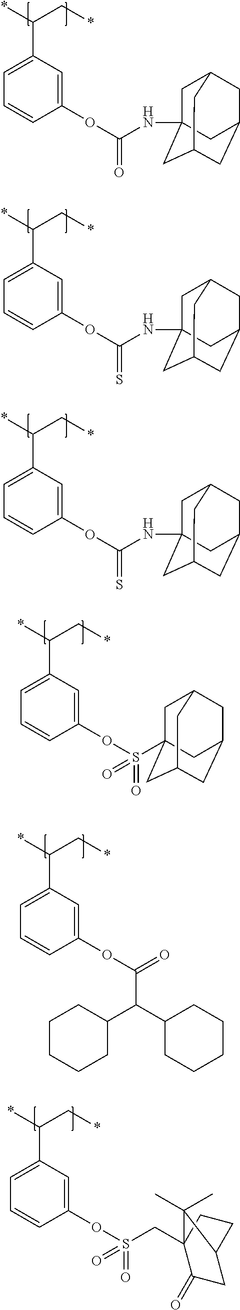

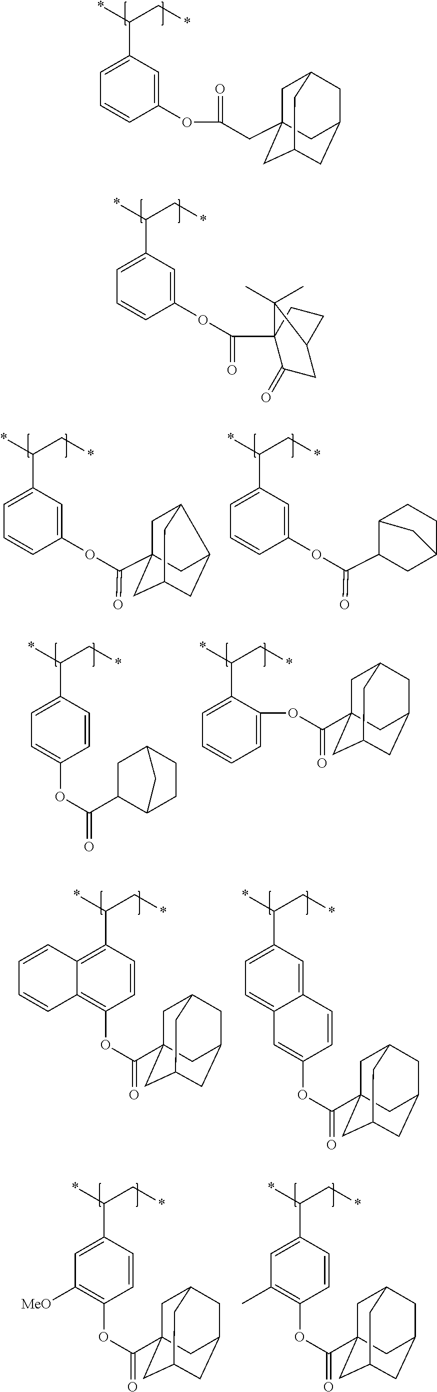

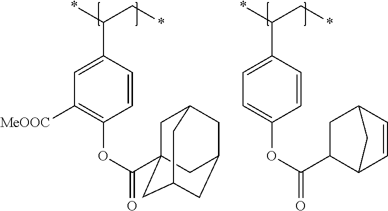

If the compound (P) is a resin and contains a repeating unit having a structure in which a hydrogen atom in a phenolic hydroxy group is substituted with a group having the non-acid decomposable polycyclic alicyclic hydrocarbon structure described above, the content of the repeating unit is preferably 1% by mol to 40% by mol and m-re preferably 2% by mol to 30% by tool with respect to the total repeating unit of the compound (P) as the resin.

It is preferable that the compound (P) as the resin used in the invention further has a repeating unit (hereinafter, referred to as “another repeating unit”) as described below, as a repeating unit in addition to the repeating unit.

Examples of the polymerizable monomer for forming another repeating unit include styrene, alkyl-substituted styrene, alkoxy-substituted styrene, halogen-substituted styrene, O-alkylated styrene, O-acylated styrene, hydrogenated hydroxystyrene, a maleic anhydride, an acrylic acid derivative (an acrylic acid and an acrylic acid ester), a methacrylic acid derivative (a methacrylic acid, a methacrylic acid ester, and the like), an N-substituted maleimide, acrylonitrile, methacrylonitrile, vinyl naphthalene, vinyl anthracene, and indene that may have a substituent.

The compound (P) as the resin may or may not contain another repeating unit, but if another repeating unit is contained, the content in the compound (P) as the resin of another repeating unit is generally 1% by tool to 30% by mol, preferably 1% by mol to 20% by mol, and more preferably 2% by mol to 10% by mol with respect to the total repeating unit that configures the compound (P) as the resin.

The compound (P) as the resin can be synthesized by a well-known radical polymerization method, a well-known anion polymerization method, or a well-known living radical polymerization method (an iniferter method and the like). For example, in the anion polymerization method, a polymer can be obtained by dissolving a vinyl monomer in an appropriate organic solvent, using a metal compound (butyl lithium and the like) as an initiator, and performing a reaction generally in a cooling condition.

For the compound (P) as the resin, a polyphenol compound produced by condensation reaction of a compound containing aromatic ketone or aromatic aldehyde, and 1 to 3 phenolic hydroxy groups (for example, JP2008-145539A), a calixarene derivative (for example, JP2004-18421A), a Noria derivative (for example, JP2009-222920A), and a polyphenol derivative (for example, JP2008-94782A) can be applied, and the compound (P) may be synthesized by performing modification with a polymer reaction.

Specific examples of the compound (P) having a phenolic hydroxy group in the case of being used for the crosslinked negative chemical amplification type resist composition are provided below, but the invention is not limited thereto.

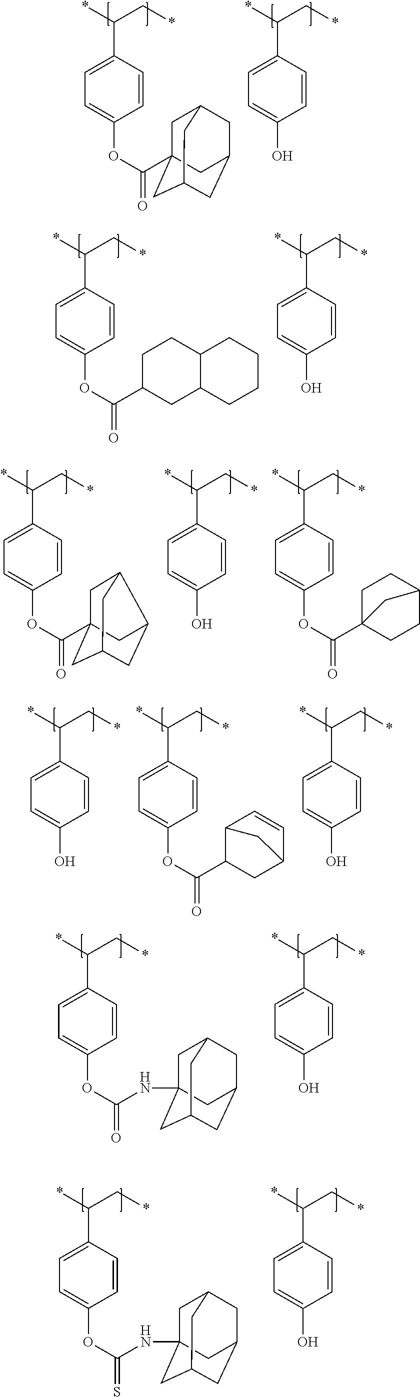

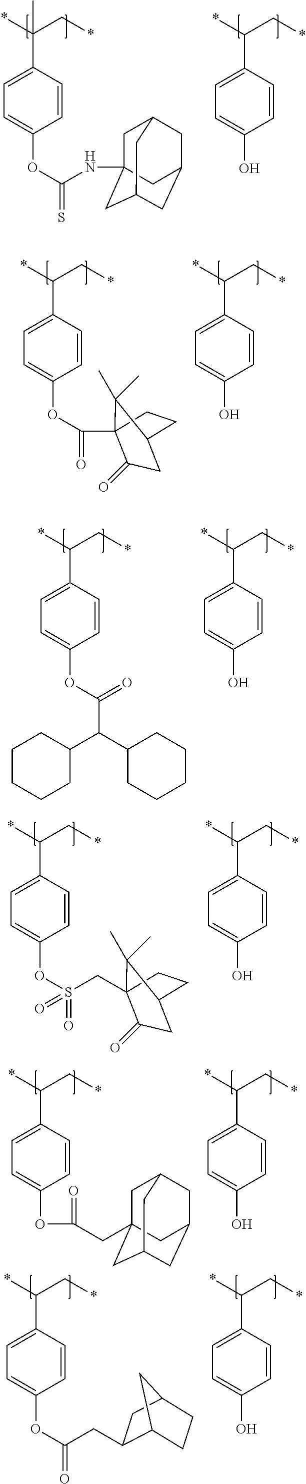

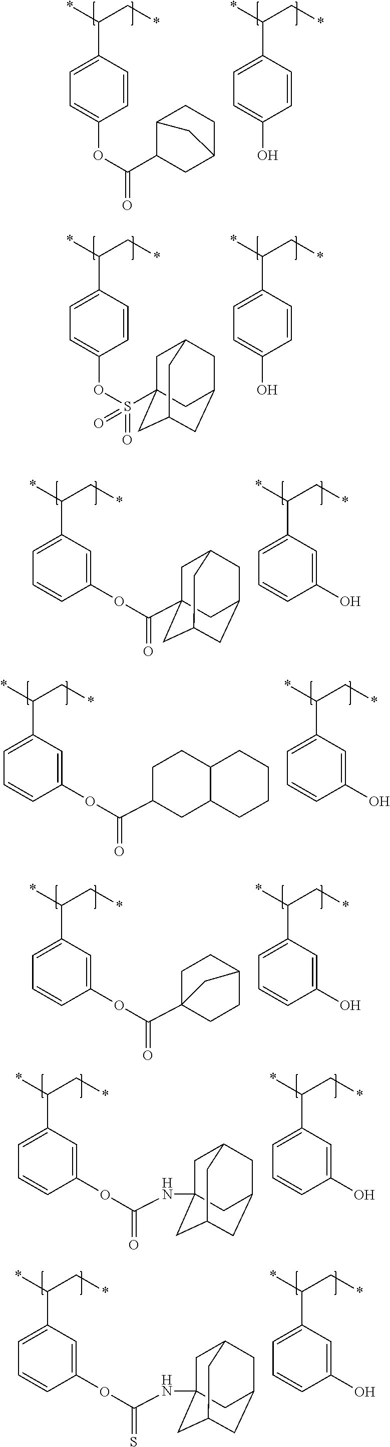

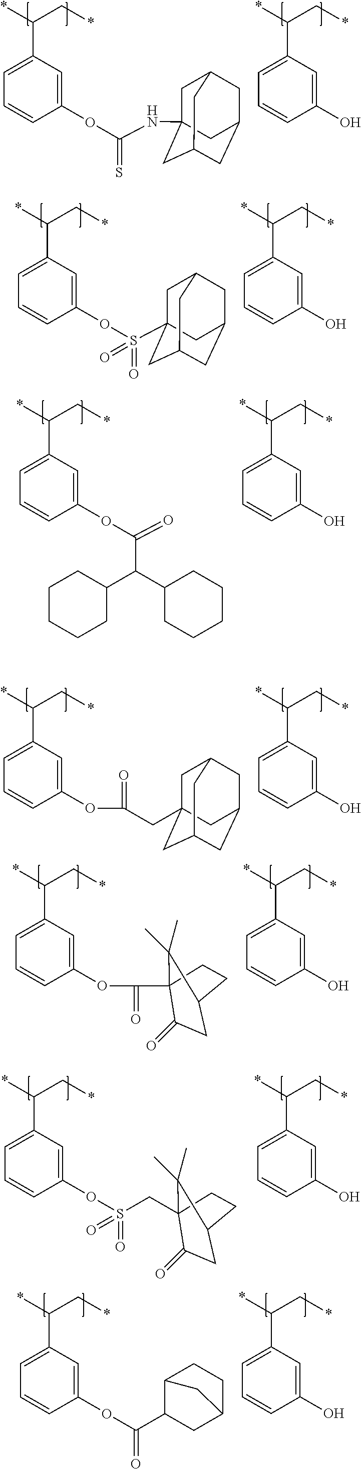

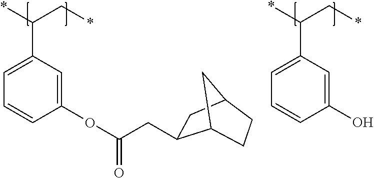

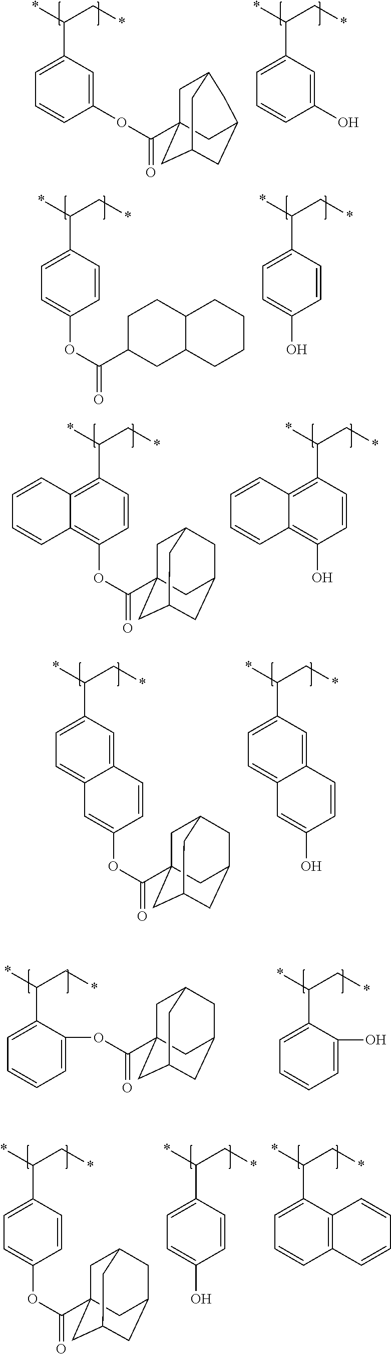

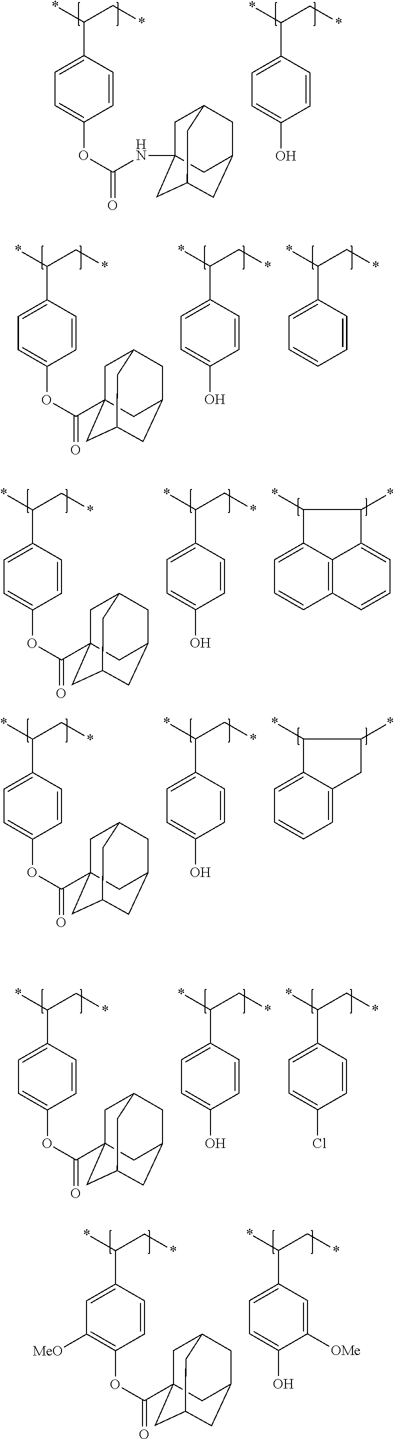

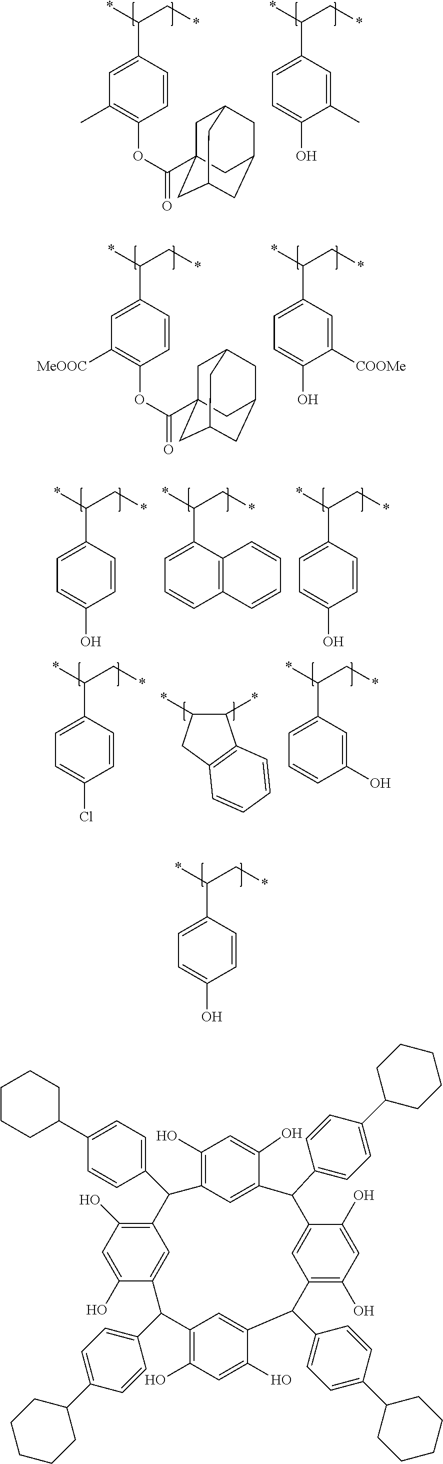

A weight average molecular weight of the compound (P) as the resin is preferably in the range of 2,000 to 200,000, calculated as polystyrene according to a GPC method. If the weight average molecular weight is caused to be 2,000 or greater, heat resistance and dry etching resistance can be particularly improved. If the weight average molecular weight is caused to be 200,000 or less, developing properties are particularly improved, and also film forming properties can be improved, due to a decrease in the viscosity of the composition.

The weight average molecular weight is still more preferably in the range of 2,000 to 50,000 and particularly preferably in the range of 2,000 to 20,000. In addition, in the formation of fine patterns using electron beams, X rays, high energy rays having a wavelength of 50 nm or less (for example, EUV), the weight average molecular weight is most preferably in the range of 3,000 to 15,000. It is possible to achieve the improvement of the heat resistance and the resolving power of the composition, the decrease of development defects, and the like, by adjusting a molecular weight.

The molecular weight of the compound (P) as a low molecular compound that can be used in a molecular resist for forming a resist film by a low molecular compound and the like is preferably 3,000 or less, more preferably 300 to 2,000, and still more preferably 500 to 1,500.

The dispersity (Mw/Mn) of the compound (P) as the resin is preferably 1.0 to 3.0, more preferably 1.0 to 2.5, and still more preferably 1.0 to 1.7. If the dispersity is adjusted, it is possible to improve, for example, line edge roughness performances.

The content of the compound (P) in the composition according to the invention is preferably 30% by mass to 99.9% by mass, more preferably 50% by mass to 99% by mass, and still more preferably 60% by mass to 99% by mass with respect to the total solid content.

The resist composition for the semiconductor manufacturing process according to the invention may contain a resin different from the compound (P) having the phenolic hydroxy group. Particularly, when the resist composition for the semiconductor manufacturing process according to the invention is exposed with ArF exciplex laser, the resist composition for the semiconductor manufacturing process according to the invention preferably contains a resin that does not include an aromatic ring.

A preferable range of a weight average molecular weight, dispersity (Mw/Mn), and a content in the composition with respect to the resin different from the compound (P) is the same as the preferable range of the weight average molecular weight, the dispersity (Mw/Mn), and the content in the composition with respect to the compound (P) as the resin.

(C) Acid Crosslinking Compound

The resist composition for the semiconductor manufacturing process according to the invention may contain (C) the acid crosslinking compound. Particularly, if the resist composition for the semiconductor manufacturing process according to the invention is used as a negative chemical amplification type resist composition, (C) the acid crosslinking compound is preferably contained. As (C) the acid crosslinking compound, a compound (hereinafter, appropriately referred to as an acid crosslinking agent or simply a crosslinking agent) having 2 or more hydroxymethyl groups or alkoxymethyl groups in a molecule is preferably contained.

Examples of a preferable crosslinking agent include a hydroxymethylated or alkoxymethylated phenol compound, an alkoxymethylated melamine-based compound, alkoxymethylglycoluril-based compounds, and an alkoxymethylated urea-based compound. Among them, a hydroxymethylated or alkoxymethylated phenol compound is more preferable, since a satisfactory pattern form can be obtained. Examples of the compound (C) as a particularly preferable crosslinking agent include a phenol derivative having 3 to 5 benzene rings in a molecule, having 2 or more items of hydroxymethyl groups or alkoxymethyl groups in total, and having a molecular weight of 1,200 or less, and a melamine-formaldehyde derivative or an alkoxymethylglycoluril derivative having at least 2 free N-alkoxymethyl groups.

In view of a pattern form, the resist composition for the semiconductor manufacturing process according to the invention more preferably contains at least 2 or more types of compounds having 2 or more alkoxymethyl groups in a molecule, as the acid crosslinking compound (C), still more preferably contains at least 2 or more types of phenol compounds having 2 or more alkoxymethyl groups in a molecule, and the resist composition for the semiconductor manufacturing, process according to the invention is particularly preferably a phenol derivative in which at least one type of at least 2 types of phenol compounds includes 3 to 5 benzene rings in a molecule, 2 or more alkoxymethyl groups are included in total, and a molecular weight is 1,200 or less.

As the alkoxymethyl group, a methoxymethyl group and an ethoxymethyl group are preferable.

Among the crosslinking agents, the phenol derivative having the hydroxymethyl group can be obtained by reacting a phenol compound not having a corresponding hydroxymethyl group and formaldehyde under a base catalyst. In addition, the phenol derivative having an alkoxymethyl group can be obtained by reacting a phenol derivative having a corresponding hydroxymethyl group and alcohol under an acid catalyst.

Among the phenol derivatives synthesized in this manner, a phenol derivative having an alkoxymethyl group is particularly preferable in view of the sensitivity and the preservation stability.

Examples of another preferable crosslinking agent further include a compound having an N-hydroxymethyl group or an N-alkoxymethyl group such as an alkoxymethylated melamine-based compound, alkoxymethylglycoluril-based compounds, and an alkoxymethylated urea-based compound.

Examples of these compounds include hexamethoxymethylmelamine, hexaethoxymethylmelamine, tetramethoxymethylglycoluril, 1,3-bismethoxymethyl-4,5-bismethoxyethyleneurea, and bismethoxymethylurea, and are disclosed in EP0133216A, DE3634671B, DE3711264B, and EP0212482A,

Among these crosslinking agents, particularly preferable crosslinking agents are provided below.

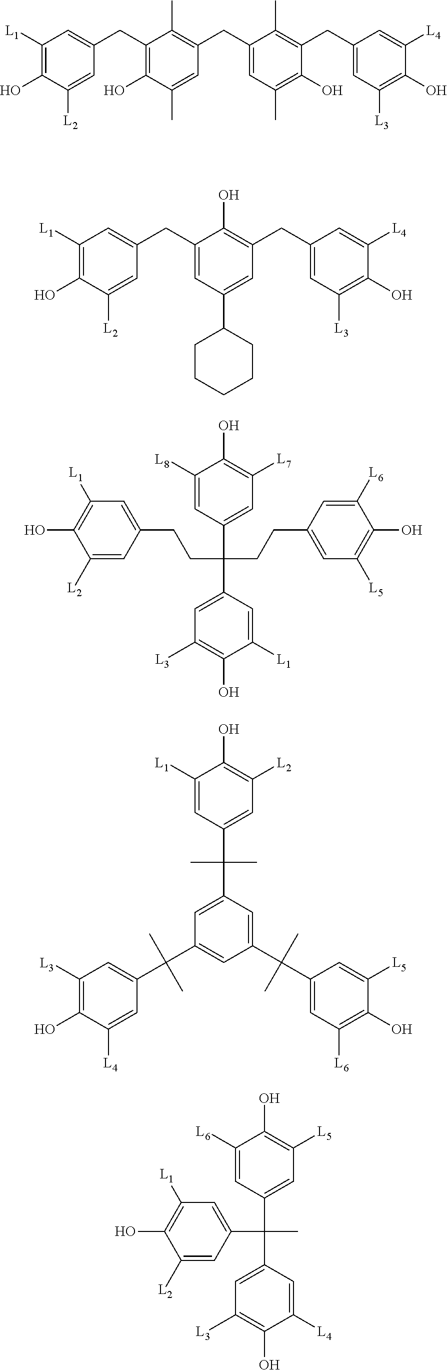

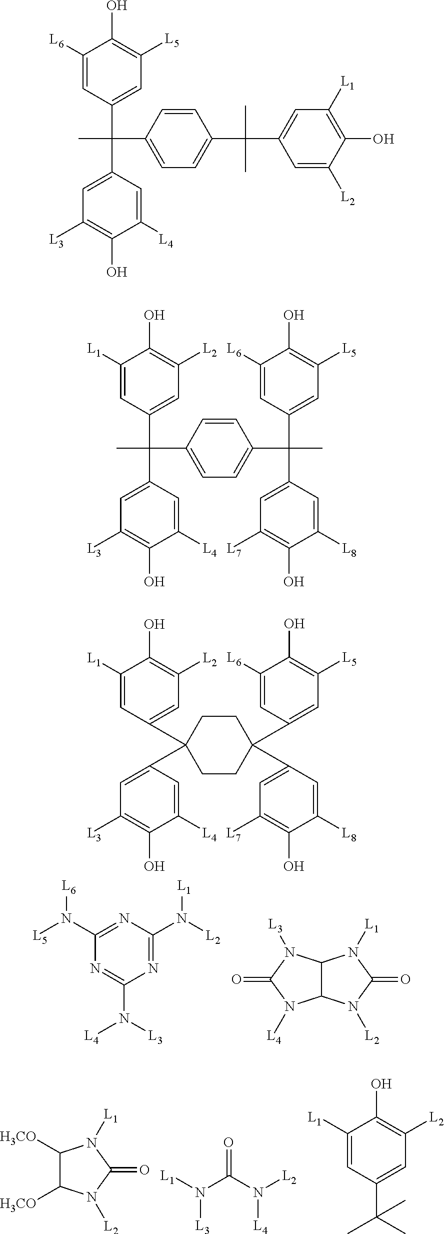

In the formula, each of L₁ to L₅ independently represents a hydrogen atom, a hydroxymethyl group, a methoxymethyl group, an ethoxymethyl group, or an alkyl group having 1 to 6 carbon atoms.

An addition amount of the crosslinking agent according to the invention is preferably 3% by mass to 65% by mass, more preferably 5% by mass to 50% by mass with respect to the solid content of the resist composition for the semiconductor manufacturing process. If the addition amount of the crosslinking agent is caused to be 3% by mass to 65% by mass, stability at the time of preserving a resist liquid can be satisfactorily maintained together with preventing a residual film ratio and resolving power from decreasing.

According to the invention, the crosslinking agent may be used singly, or 2 or more types thereof may be used in combination, and it is preferable to use 2 or more types in combination, in view of pattern forms.

For example, in addition to the phenol derivatives, if other crosslinking agents, for example, the compound having an N-alkoxymethyl group described above, are used in combination, the ratio of the phenol derivative and another crosslinking agent is 100/0 to 20/80 by a molar ratio, preferably 90/10 to 40/60, and still more preferably 80/20 to 50/50.

The acid crosslinking compound (C) may be a resin having a repeating unit having an acid crosslinking group (hereinafter, also referred to as a resin (C″)). It is preferable that the compound (P) described above is a resin (C″) further having a repeating unit having an acid crosslinking group. If the acid crosslinking compound (C) is the resin (C″), the repeating unit in the resin (C″) has an acid crosslinking group, and thus crosslinking reactivity is high and a strong film can be formed, compared with a resist composition for the semiconductor manufacturing process that contains a resin not having a repeating unit having an acid crosslinking group. As a result, it is considered that dry etching resistance is improved. In addition, since diffusion of an acid in an exposed portion with active rays or radial rays is suppressed, as a result, it is considered that resolving power when a fine pattern is formed is improved, a pattern form becomes better, and further line edge roughness (LER) decreases. In addition, as in a repeating unit expressed by General Formula (C1) below, if a reaction point of the resin and a reaction point of a crosslinking group are close to each other, it is considered that the sensitivity of the resist composition for the semiconductor manufacturing process is improved.

Examples of the resin (C″) include a resin having a repeating unit expressed by General Formula (C1) below. The repeating unit expressed by General Formula (C1) has a structure including at least one methylol group that may have a substituent.

Here, the “methylol group” is a group expressed by General Formula (M) below, and according to an embodiment of the invention, the methylol group is preferably a hydroxymethyl group or an alkoxymethyl group.

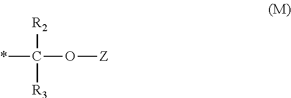

R₂ and R₃ represent hydrogen atoms, alkyl groups, or cycloalkyl groups.

Z represents a hydrogen, atom or a substituent.

Hereinafter, General Formula (C1) is described.

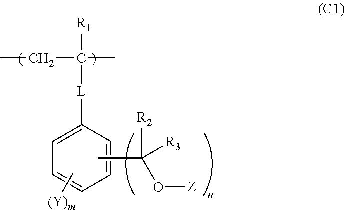

In General Formula (C1),

R₂, R₃, and Z are as defined in General Formula (M) above.

R₁ represents a hydrogen atom, a methyl group, or a halogen atom.

L represents a bivalent linking group or a single bond.

Y represents a substituent except for a methylol group.

m represents an integer of 0 to 4.

n represents an integer of 1 to 5.

A value of m+n is 5 or less.

If in is 2 or greater, plural Y's may be identical to or different from each other,

If n is 2 or greater, plural R₂'s, R₃'s, and Z's may be identical to or different from each other.

In addition, 2 or more of Y's, R₂'s, R₃'s, and Z's may be bonded to each other, to form a ring structure.

Each of R₁, R₂, R₃, L, and Y may have a substituent.

The content of the repeating unit having the acid crosslinking group in the resin (C″) is preferably 3% by mol to 40% by mol and more preferably 5% by mol to 30% by mol with respect to the total repeating unit of the resin (C″).

The content of the resin (C″) is preferably 5% by mass to 50% by mass and more preferably 10% by mass to 40% by mass with respect to the total solid content of the negative resist composition.

In addition, the content of the resin (C″) when the compound (P) described above is the resin (C″) further having a repeating unit having an acid crosslinking group is the same as the preferable range of the content of the compound (P).

The resin (C″) may have 2 or more types of repeating units having acid crosslinking groups, or 2 or more types of resins (C″) may be used in combination. In addition, the compound (C) and the resin (C″) may be used in combination.

Specific examples of the repeating unit having the acid crosslinking group included in the resin (C′″) include the structures provided below.

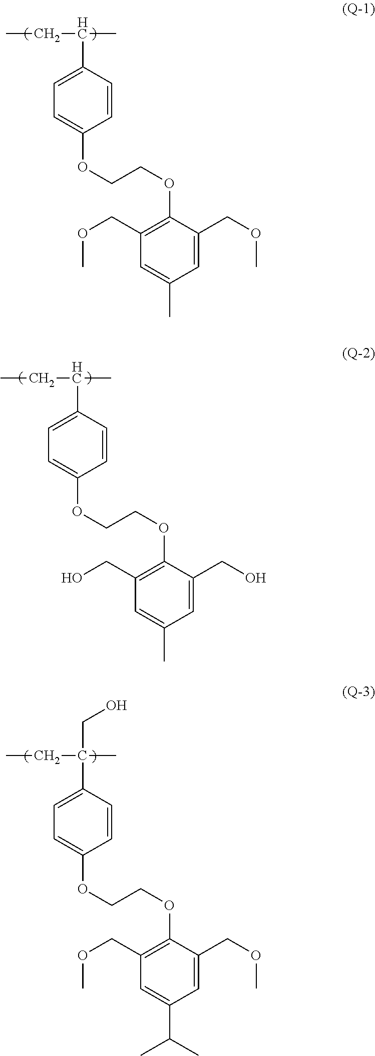

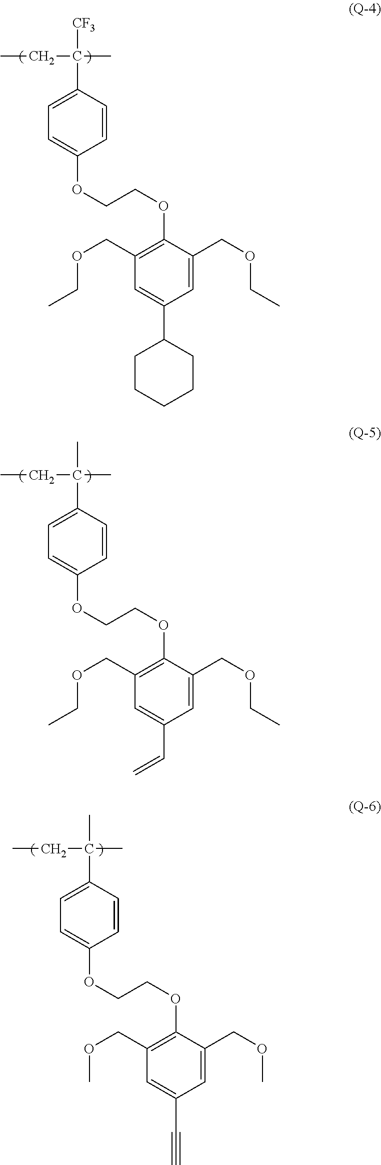

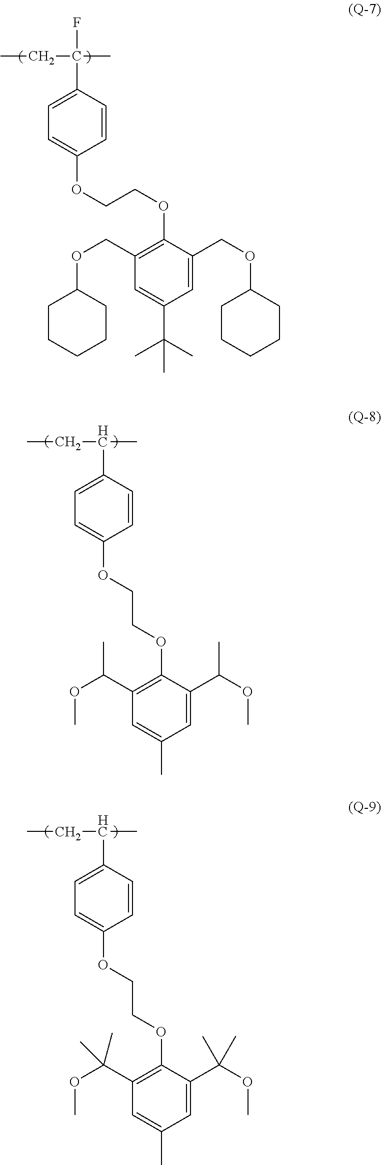

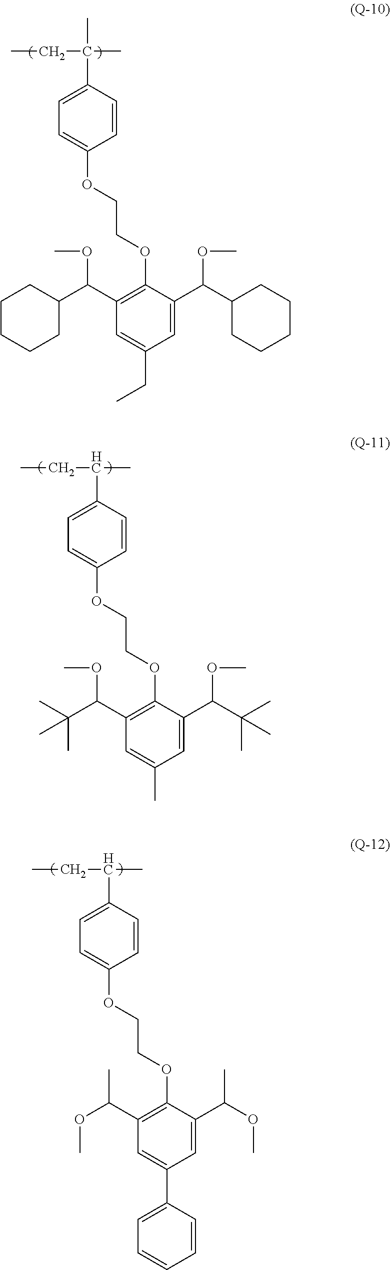

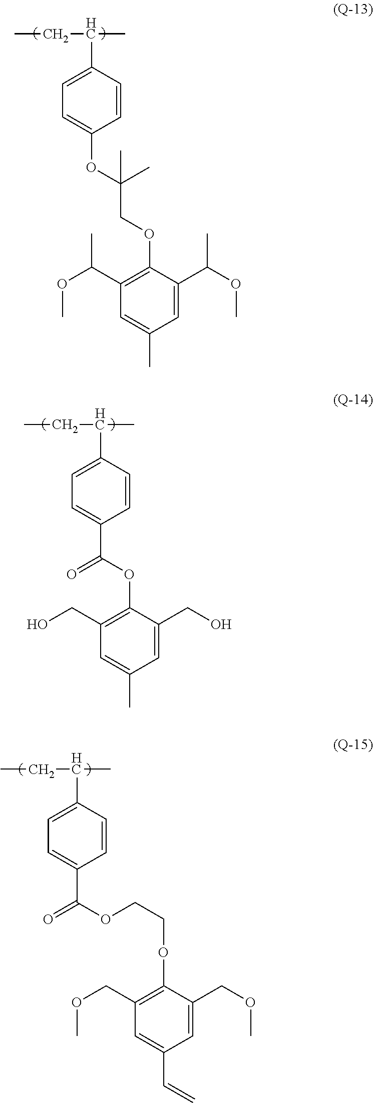

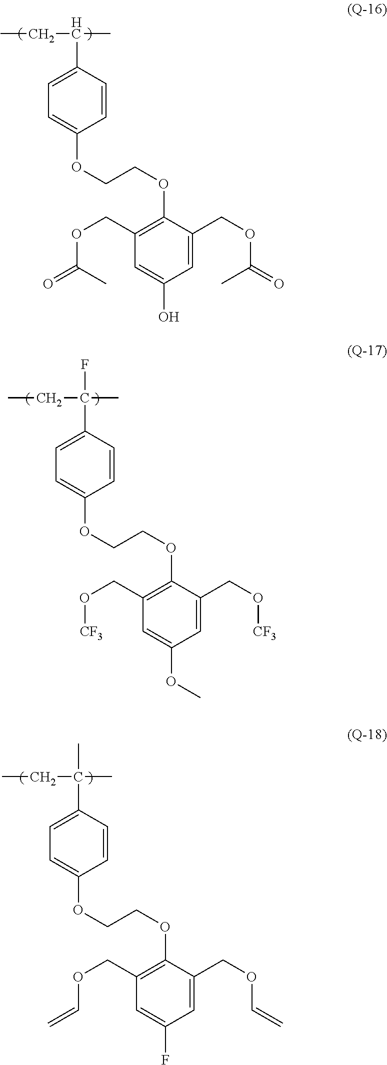

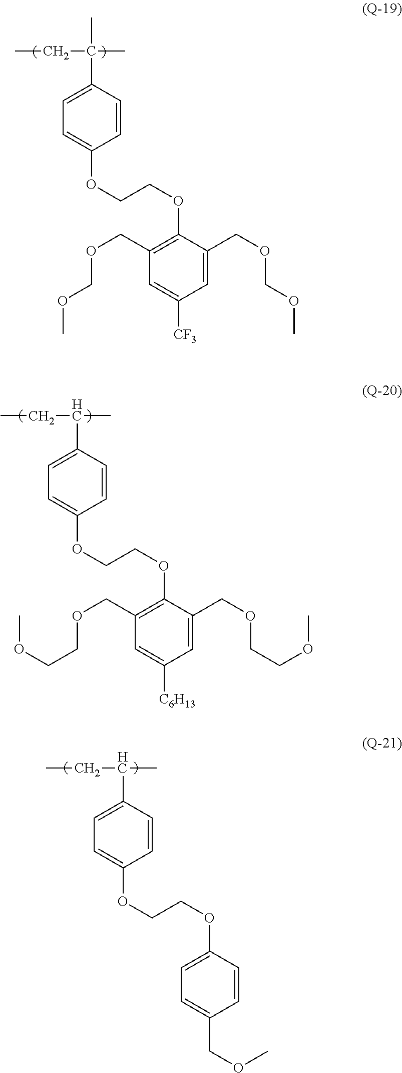

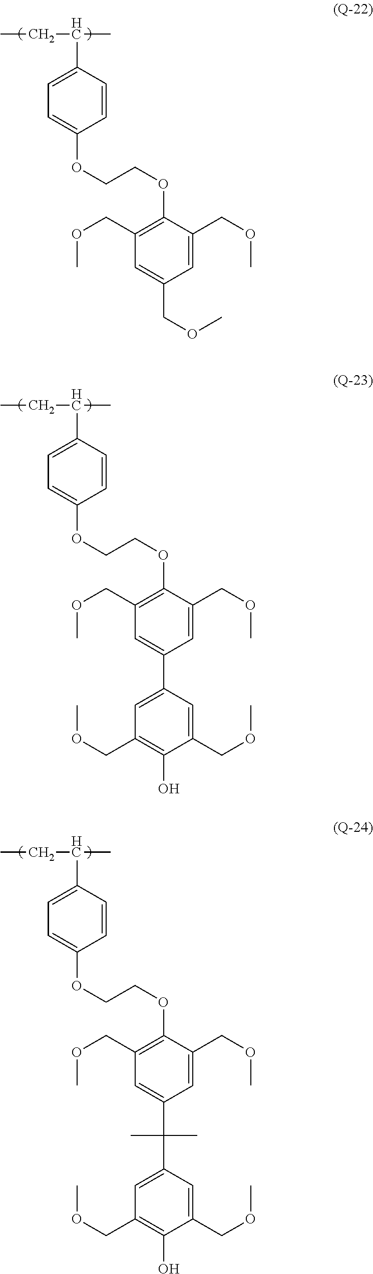

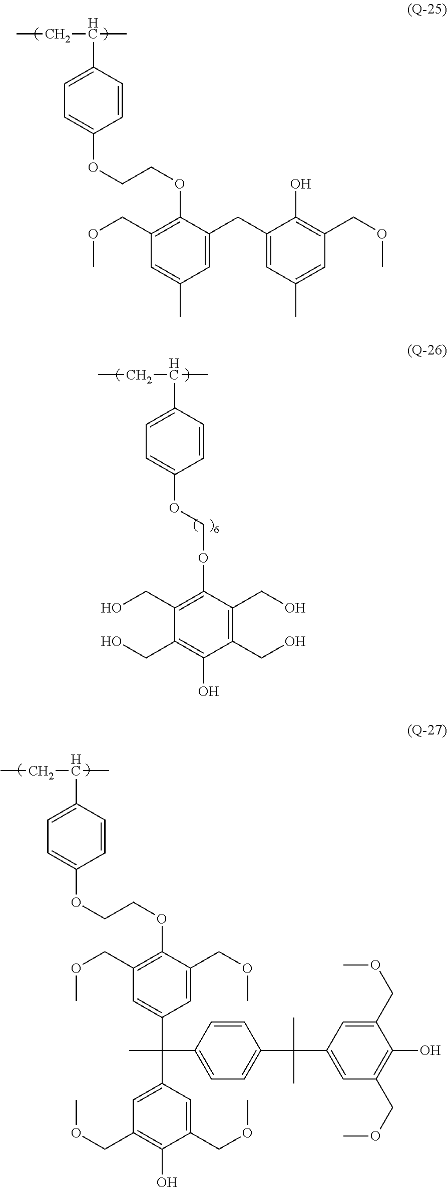

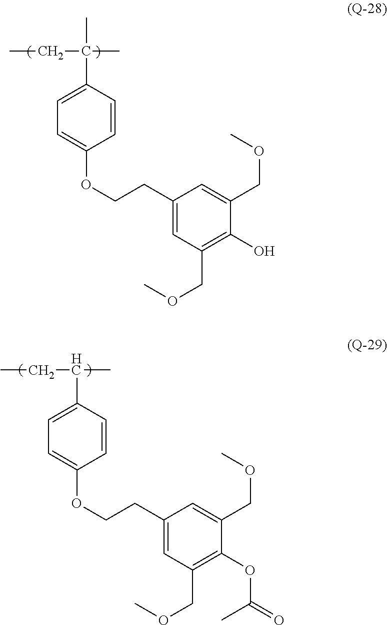

Basic Compound

The resist composition for the semiconductor manufacturing process according to the invention preferably contains a basic compound as an acid scavenger, in addition to the components above. If the basic compound is used, it is possible to reduce a change in performances over time due to exposure to the post baking. As the basic compound like this, an organic basic compound is preferable. Specifically, examples thereof include aliphatic amines, aromatic amines, heterocyclic amines, a nitrogen-containing compound having a carboxyl group, a nitrogen-containing compound having a sulfonyl group, a nitrogen-containing compound having a hydroxy group, a nitrogen-containing compound having a hydroxyphenyl group, an alcoholic nitrogen-containing compound, an amide derivative, and an imide derivative. An amine oxide compound (a compound having a methyleneoxy unit and/or an ethyleneoxy unit is preferable, and examples thereof include compounds disclosed in JP2008-102383A) and an ammonium salt (preferably hydroxide or carboxylate, and, specifically, tetraalkylammonium hydroxide represented by tetrabutylammonium hydroxide is preferable in view of LER) are also appropriately used.

Further, a compound in which basicity increases due to the action of an acid is also used as one type of a basic compound.

Specific examples of the amines include tri-n-butylamine, tri-n-pentylamine, tri-n-octylamine, tri-n-decylamine, triisodecylamine dicyclohexylmethylamine, tetradecylamine, pentadecylamine, hexadecylamine, octadecylamine, didecylamine methyloctadecylamine, dimethylundecyl amine, N,N-dimethyldodecylamine, methyldioctadecylamine, N,N-dibutylaniline, N,N-dihexylaniline, 2,6-diisopropylaniline, 2,4,6-tri(t-butyl)aniline, triethanolamine, N,N-dihydroxyethylaniline, tris(methoxyethoxyethyl)amine, compounds disclosed in Column 3 on line 60 and subsequent lines in U.S. Pat. No. 6,040,112A, 2-[2-{2-((2,2-dimethoxy-phenoxyethoxy)ethyl}-bis-(2-methoxyethyl)]-amine, and compounds (C1-1) to (C3-3) exemplified in paragraph “0066” in US2007/0224539A1. Examples of the compounds having the nitrogen-containing heterocyclic ring structure include 2-phenylbenzimidazole, 2,4,5-triphenylimidazole, N-hydroxyethylpiperidine, bis(1,2,2,6,6-pentamethyl-4-piperidyl)sebacate, 4-dimethylaminopyridine, antipyrine, hydroxyantipyrine, 1,5-diazabicyclo[4.3.0]non-5-ene, 1,8-diazabicyclo[5.4.0])-undec-7-ene, and tetarabutylammonium hydroxide.

In addition, a photodecomposable basic compound (a compound in which a basic nitrogen atom originally functions as a base to show basicity, but the basic nitrogen atom is decomposed by irradiation with active rays or radial rays, amphoteric ion compounds having basic nitrogen atoms and organic acid portions are generated, these perform neutralization in a molecule, and thus basicity decreases or disappears. For example, onium salts disclosed in JP3577743B, JP2001-215689A, J2001-166476A and JP2008-102383A) and a photobase generating gent (for example compounds disclosed in JP2010-243773A) are also appropriately used.

Among these basic compounds, since satisfactory LER can be obtained, an ammonium salt or a photodecomposable basic compound is preferable.

According to the invention, the basic compound may be used singly, or two or more types thereof may be used in combination.

The content of the basic compound used in the invention is preferably 0.01% by mass to 10% by mass, more preferably 0.03% by mass to 5% by mass, and particularly preferably 0.05% by mass to 3% by mass with respect to the total solid content of the resist composition for the semiconductor manufacturing process.

[5] Surfactant

The resist composition for the semiconductor manufacturing process according to the invention may further contain a surfactant in order to improve coating properties. Examples of the surfactant are not particularly limited, but include nonionic surfactants such as polyoxyethylene alkyl ethers, polyoxyethylene alkylaryl ethers, polyoxyethylene polyoxypropylene block copolymers, sorbitan fatty acid esters, polyoxyethylene sorbitan fatty acid esters, fluorine-containing surfactants such as MEGAFACE F171 and F176 (manufactured by DIC Corporation) and FLUORAD FC430 (manufactured by 3M Japan Limited) and SURFYNOL E1004 (produced by Asahi. Glass Co., Ltd.), and PF656 and PF6320 manufactured by OMNOVA Solutions Inc., and an organosiloxane polymer such as a polysiloxane polymer KP-341 (manufactured by Shin-Etsu Chemical Co., Ltd.).

If the resist composition for the semiconductor manufacturing process contains a surfactant, the usage amount of the surfactant is preferably 0.0001% by mass to 2% by mass, more preferably 0.0005% by mass to 1% by mass with respect to the total amount (except for a solvent) of the resist composition for the semiconductor manufacturing process.

[6] Organic Carboxylic Acid

The resist composition for the semiconductor manufacturing process according to the invention preferably contains an organic carboxylic acid in addition to the components described above, in view of scum characteristics. Examples of the organic carboxylic acid compound include an aliphatic carboxylic acid, an alicyclic carboxylic acid, an unsaturated aliphatic carboxylic acid, an oxycarboxylic acid, an alkoxycarboxylic acid, a ketocarboxylic acid, a benzoic acid, a benzoic acid derivative, a phthalic acid, a terephthalic acid, an isophthalic acid, a 2-naphthoic acid, a 1-hydroxy-2-naphthoic acid, and a 2-hydroxy-3-naphthoic acid. However, when electron beam exposure is performed in a vacuum, there is a concern that the organic carboxylic acid is volatilized from a surface of a resist film and contaminates the inside of a drawing chamber. Therefore, an example of a preferable compound is an aromatic organic carboxylic acid, and among these, for example, a benzoic acid, a 1-hydroxy-2-naphthoic acid, and a 2-hydroxy-3-naphthoic acid are suitable.

The blending amount of an organic carboxylic acid is preferably in the range of 0.01 parts by mass to 10 parts by mass, more preferably in the range of 0.01 parts by mass to 5 parts by mass, and further more preferably in the range of 0.01 parts by mass to 3 parts by mass with respect to 100 parts by mass of the compound (P) having the phenolic hydroxy group.

The resist composition for the semiconductor manufacturing process according to the invention may further contain a dye, a plasticizer, and an acid proliferating agent (disclosed in WO95/29968A, WO98/24000A, JP1996-305262A (JP-H8-305262A), JP1997-34106A (JP-H9-34106A), JP1996-248561A (JP-H8-248561A), JP1996-503082A (JP-H8-503082A), U.S. Pat. No. 5,445,917A, JP1996-50308 IA (JP-H8-503081A), U.S. Pat. No. 5,534,393A, U.S. Pat. No. 5,395,736A, U.S. Pat. No. 5,741,630A, U.S. Pat. No. 5,334,489A, U.S. Pat. No. 5,582,956A, U.S. Pat. No. 5,578,424A, U.S. Pat. No. 5,453,345A, U.S. Pat. No. 5,445,917A, EP66596013B, EP757628B, EP665961B, U.S. Pat. No. 5,667,943A, JP1998-1508A (JP-H10-1508A), JP1998-282642A (JP-H10-282642A), JP1997-512498A (JP-H9-512498A), JP2000-62337A, JP2005-17730A, and JP2008-209889A), if necessary. With respect to these compounds, respective compounds disclosed in JP2008-268935A can be included.

### [Carboxylic Acid Onium Salt]

The resist composition for the semiconductor manufacturing process according to the invention may contain a carboxylic acid onium salt. Examples of the carboxylic acid onium salt include a carboxylic acid sulfonium salt, a carboxylic acid iodonium salt, and a carboxylic acid ammonium salt. Particularly, as the carboxylic acid onium salt, a carboxylic acid iodonium salt and a carboxylic acid sulfonium salt are preferable. Further, according to the invention, it is preferable that a carboxylate residue of the carboxylic acid onium salt does not contain an aromatic group and a carbon-carbon double bond. As a particularly preferable anion portion, a straight chain, branched, monocyclic or polycyclic cyclic alkylcarboxylate anion having 1 to 30 carbon atoms is preferable. An anion of a carboxylic acid in which a portion or all of alkyl groups are substituted with fluorine is more preferable. In addition, an oxygen atom may be included in an alkyl chain. Accordingly, transparency with respect to light of 220 nm or less is secured, and thus sensitivity and resolving power are improved, such that density dependency and exposure margins are improved.

Compound that is Decomposed Due to Action of Acid and Generates Acid

The resist composition for the semiconductor manufacturing process according to the invention may include one or more types of compounds that is decomposed due to the action of an acid and generates an acid. The acid that is generated by the compound that is decomposed due to the action of an acid and generates an acid is preferably a sulfonic acid, a methide acid, or an imide acid.

Hereinafter, examples of the compounds that can be used in the invention are provided, but the invention is not limited thereto.

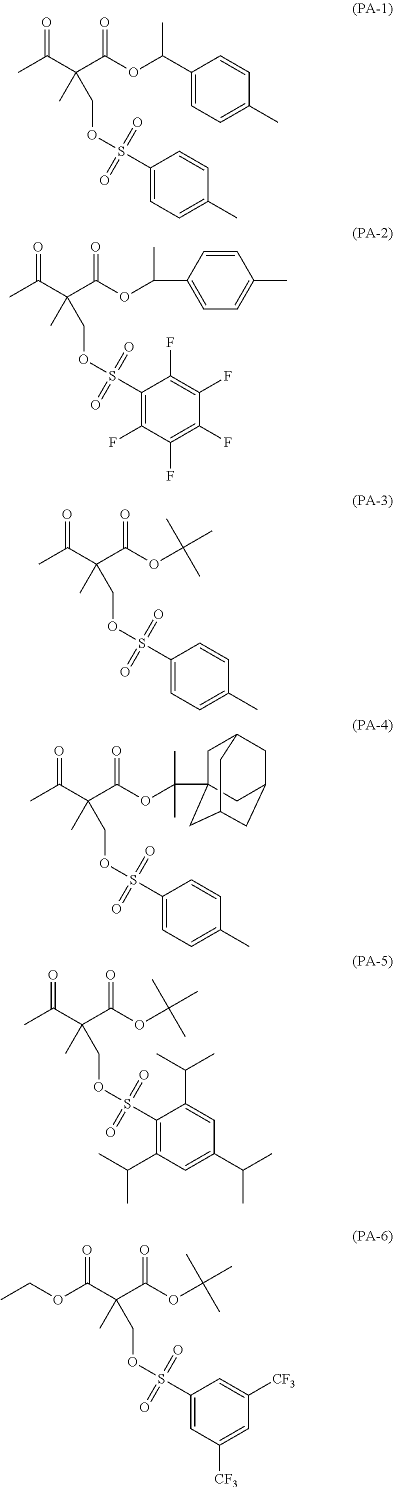

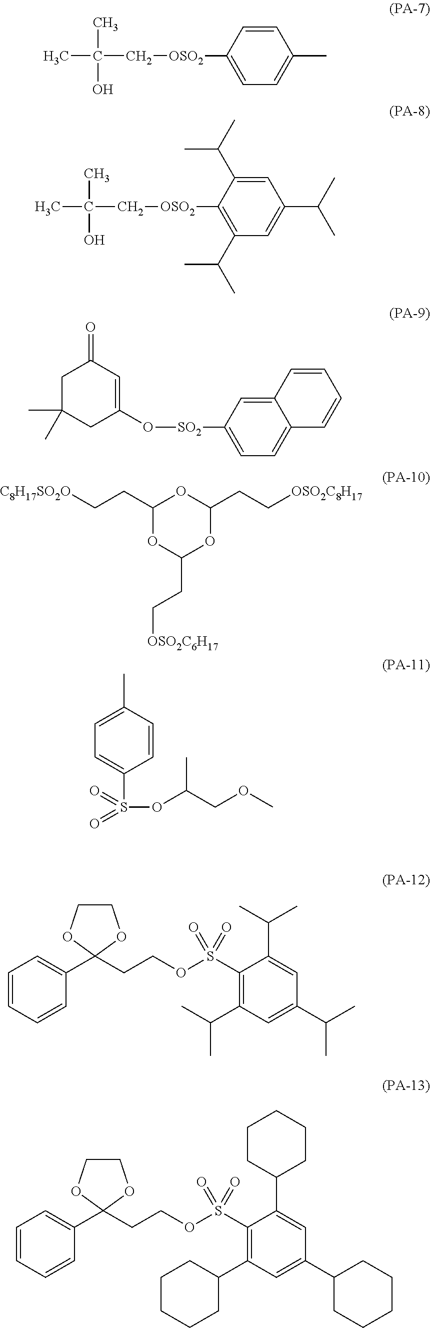

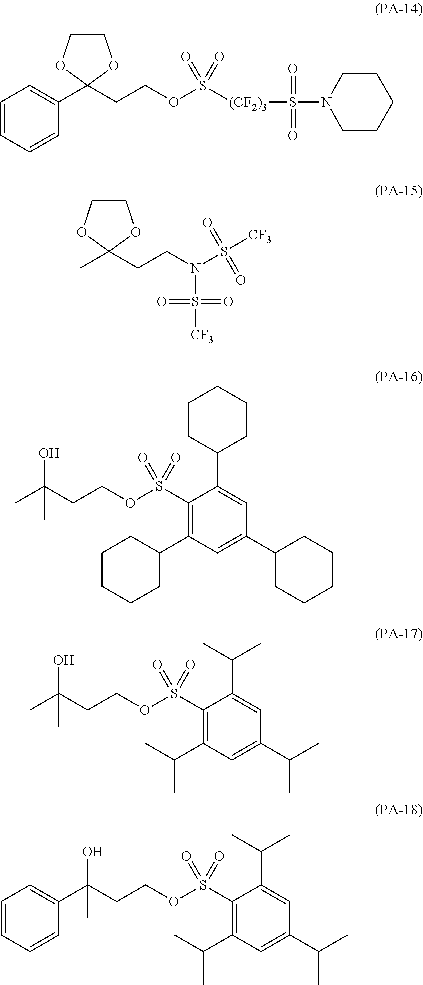

[8] Hydrophobic Resin (HR)

The resist composition for the semiconductor manufacturing process according to the invention may have a hydrophobic resin (HR) in addition to the compound (P) having the phenolic hydroxy group. If this resin is added, an effect of causing a pattern to be close to a rectangle form or an effect of suppressing outgassing can be expected. In addition, the hydrophobic resin (HR) is preferably used, in the case where exposure is performed by filling a portion between a photosensitive film (resist film) and a lens with a liquid (pure water and the like) having a refractive index higher than the air, that is, in the case where liquid immersion exposure is performed.

In order to cause the hydrophobic resin (HR) to be unevenly distributed on a surface of a film, a group having a fluorine atom, a group having a silicon atom, or a hydrocarbon group having 5 or more carbon atoms is preferably contained. These groups may be included in or may be substituted to a side chain of a resin.

Specific examples of the hydrophobic resin (HR) include resins disclosed in paragraphs “0240” to “0247” of JP2010-175858A and resins disclosed in paragraphs “0349” to “354” of JP2013-80006A.

Examples of the solvent used in the resist composition for the semiconductor manufacturing process according to the invention preferably include ethyleneglycolmonoethylether acetate, cyclohexanone, 2-heptanone, propylene glycol monomethyl ether (PGME, also referred to as 1-methoxy-2-propanol), propylene glycol monomethyl ether acetate (PGMEA, also referred to as 1-methoxy-2-acetoxypropane), propylene glycol monomethyl ether propionate, propyleneglycolmonoethylether acetate, methyl 3-methoxypropionate, ethyl 3-ethoxypropionate, methyl β-methoxyisobutyrate, ethyl butyrate, propyl butyrate, methylisobutylketone, ethyl acetate, isoamyl acetate, ethyl lactate, toluene, xylene, cyclohexyl acetate, diacetone alcohol, N-methyl pyrrolidone, N,N-dimethyl formamide, γ-butyrolactone, N,N-dimethylacetamide, propylene carbonate, and ethylene carbonate. These solvents may be used singly or in combination.

The solid content of the resist composition for the semiconductor manufacturing process is preferably 1% by mass to 40% by mass, more preferably 1% by mass to 30% by mass, and still more preferably 3% by mass to 20% by mass, as a solid content concentration.

The invention also relates to a resist film that is formed with the resist composition for the semiconductor manufacturing process according to the invention, and this resist film is formed, for example, by coating a support such as a substrate with the resist composition for the semiconductor manufacturing process. The thickness of the resist film is preferably 0.02 am to 0.1 μm. As a method of coating the substrate, an appropriate coating method such as spin coating, roll coating, flow coating, dip coating, spray coating, and doctor coating is performed to coat the substrate, but spin coating is preferable, and the number of revolutions thereof is preferably 1,000 rpm to 3,000 rpm. As the coating film, a thin film is formed by performing prebaking at 60° C. to 150° C. for 1 minute to 20 minutes, and preferably at 80° C. to 120° C. for 1 minute to 10 minutes.

As a material for configuring a substrate to be processed and the outermost layer thereof, for example, a silicon wafer can be used, in the case of a semiconductor wafer, and examples of a material that becomes an outermost layer include Si, SiO₂, SiN, SiON, TiN, WSi, BPSG, SOG, and an organic antireflective film.

In addition, the invention also relates to a resist-coated mask blank on which the resist film obtained as described above is coated. In order to obtain this resist-coated mask blank, if a resist pattern is formed on a photomask blank for manufacturing a photomask, examples of a used transparent substrate include a transparent substrate such as quartz and calcium fluoride. Generally, a necessary functional film such as a light shielding film, an antireflective film, and further a phase shift film, and additionally, an etching stopper film and an etching mask film are stacked on the substrate. As a material of the functional film, a film containing transition metal such as silicon, chromium, molybdenum, zirconium, tantalum, tungsten, titanium, and niobium is stacked. In addition, as a material used in the outermost layer, a silicon compound material having a material having silicon or a material containing oxygen and/or nitrogen in silicon, as a main constituent material or a material further containing transition metal in this material, as a main constituent material, and a transition metal compound material having a material including one or more types selected from transition metal, particularly, chromium, molybdenum, zirconium, tantalum, tungsten, titanium, and niobium, or a material having 1 or more element selected from oxygen, nitrogen, and carbon, further to this material, as a main constituent material are exemplified.

The light shielding film may be a single layer, but a multilayer structure in which plural materials are coated in an overlapped manner is more preferable. In the case of the multilayer structure, a thickness of the film per one layer is not particularly limited, but is preferably 5 nm to 100 nm and more preferably 10 nm to 80 nm. The total thickness of the light shielding film is not particularly limited, but is preferably 5 am to 200 nm and more preferably 10 nm to 150 nm.

Among these materials, if a pattern is formed by using the resist composition for the semiconductor manufacturing process on a photomask blank having a material containing oxygen or nitrogen generally in chromium on an outermost layer, a so-called undercut form in which a constricted shape is formed near the substrate is easily caused, but if the invention is used, an problem of the undercut form can be solved compared with a resist composition in the related art.

Subsequently, the resist film is irradiated with active rays or radial rays (electron beams, EUV rays, and the like), baking (generally at 80° C. to 150° C., more preferably at 90° C. to 130° C., and generally for 1 minute to 20 minutes, preferably for 1 minute to 10 minutes) is preferably performed, and then development is performed. Accordingly, a satisfactory pattern can be obtained. In addition, this pattern is used as a mask, and an etching process and ion injection are appropriately performed, a semiconductor fine circuit, an imprint mold structure body, or a photomask is created.

In addition, processes in the case of creating an imprint mold using the composition according to the invention are disclosed, for example, in JP4109085B, JP2008-162101A, and “Science and New Technology in Nanoimprint—Substrate technology of nanoimprint and latest technology development—edited by HIRAI, Yosihiko (Frontier Publishing)”.

A usage form of the resist composition for the semiconductor manufacturing process according to the invention and a resist patterning method are described below.

The invention also relates to a resist patterning method including a step of exposing the resist film or a resist-coated mask blank and a step of developing the exposed resist film or the exposed resist-coated mask blank. According to the invention, it is preferable that the exposure is performed using ArF light, KrF light, electron beams, or extreme ultraviolet rays.

As the exposure (patterning step) of the resist film in the manufacturing of a precisely integrated circuit element and the like, first, it is preferable to perform irradiation of the resist film according to the invention with electron beams or extreme ultraviolet rays (EUV) in a pattern shape. Exposure is performed such that the exposure amount is about 0.1 μC/cm² to 20 μC/cm² and preferably about 3 μC/cm² to 15 μC/cm² in the case of the electron beams, is about 0.1 mJ/cm² to 20 mJ/cm² and preferably about 3 mJ/cm² to 15 mJ/cm², in the case of extreme ultraviolet rays. Subsequently, post exposure baking is performed on a hot plate, at 60° C. to 150° C. for 1 minute to 20 minutes and preferably at 80° C. to 120° C. for 1 minute to 10 minutes, and subsequently, a resist pattern is formed by performing developing, rinsing, and drying. For example, in the case of the alkaline development, the developer is an alkaline aqueous solution of preferably 0.1% by mass to 5% by mass and more preferably 2% by mass to 3% by mass, such as tetramethylammonium hydroxide (TMAH) and tetrabutylammonium hydroxide (TBAH), and is developed by a well-known method such as a dipping method, a puddling method, and a spraying method, preferably for 0.1 minutes to 3 minutes and more preferably for 0.5 minutes to 2 minutes. Alcohols and/or a surfactant may be added to an alkaline developer, in an appropriate amount, pH of the alkaline developer is generally 10.0 to 15.0. Particularly, an aqueous solution of tetramethylammonium hydroxide of 2.38% by mass is desirable.

In the development step, generally, an alkaline developer or a developer containing an organic solvent (hereinafter, also referred to as an organic-based developer) can be used. Examples of the alkaline developer include alkaline aqueous solutions of inorganic alkalis such as sodium hydroxide, potassium hydroxide, sodium carbonate, sodium silicate, sodium metasilicate, and ammonia water, primary amines such as ethylamine and n-propylamine, secondary amines such as diethylamine and di-n-butylamine, tertiary amines such as triethylamine and methyldiethylamine, alcohol amines such as dimethylethanolamine and triethanolamine, tetraalkylammonium hydroxide such as tetramethylammonium hydroxide, tetraethylammonium hydroxide, tetrapropylammonium hydroxide, tetrabutylammonium hydroxide, tetrapentylammonium hydroxide, tetrahexylammonium hydroxide, tetraoctylammonium hydroxide, ethyltrimethylammonium hydroxide, butyltrimethylammonium hydroxide, methyltriamylammonium hydroxide, and dibutyldipentylammonium hydroxide, a quaternary ammonium salt such as trimethylphenylammonium hydroxide, trimethylbenzylammonium hydroxide, and triethylbenzylammonium hydroxide, and cyclic amines such as pyrrole and piperidine.

An appropriate amount of alcohols and/or a surfactant may be added to an alkaline developer.

The content of the alkaline developer is generally 0.1% by mass to 20% by mass, pH of the alkaline developer is generally 10.0 to 15.0. An alkali concentration and pH of the alkaline developer can be appropriately prepared to be used. The alkaline developer may be used by adding a surfactant or an organic solvent.

If the developer is an alkaline developer, pure water is used as a rinse liquid, and an appropriate amount of a surfactant may be added to be used.

The organic-based developer is particularly preferably used when a negative pattern is obtained by using a composition including a resin (in other words, a resin having a group of which polarity increases due to the action of an acid) in which solubility with respect to the alkaline developer due to the action of an acid increases. As the organic-based developer, a polar solvent such as an ester-based solvent (butyl acetate, propylene glycol monomethyl ether and the like), a ketone-based solvent (2-heptanone, cyclohexanone, and the like), an alcohol-based solvent, an amide-based solvent, and an ether-based solvent, and a hydrocarbon-based solvent can be used. The water content with respect to the total organic-based developer is preferably less than 10% by mass and it is more preferable for it not to substantially contain moisture.

That is, the usage amount of the organic solvent with respect to the organic-based developer is preferably 90% by mass to 100% by mass and preferably 95% by mass to 100% by mass with respect to the total amount of the developer.

Appropriate amounts of alcohols and/or a surfactant can be added to the developer, if necessary.

The surfactant is not particularly limited, but an ionic or nonionic fluorine-based and/or silicon-based surfactant can be used. Examples of the fluorine and/or the silicon-based surfactant include surfactants disclosed in JP1987-36663A (JP-S62-36663A), JP1986-226746A (JP-S61-226746A), JP1986-226745A (JP-S61-226745A), JP1987-170950A (JP-S62-170950A), JP1988-34540A (JP-S63-34540A), JP1995-230165A (JP-H7-230165A), JP1996-62834A (JP-H8-62834A), JP1997-54432A (JP-H9-54432A), JP1997-5988A (JP-H9-5988A). U.S. Pat. No. 5,405,720A, U.S. Pat. No. 5,360,692A, U.S. Pat. No. 5,529,881A, U.S. Pat. No. 5,296,330A, U.S. Pat. No. 5,436,098A, U.S. Pat. No. 5,576,143A, U.S. Pat. No. 5,294,511A, and U.S. Pat. No. 5,824,451A, and a nonionic surfactant is preferable. The nonionic surfactant is not particularly limited, but a fluorine-based surfactant or a silicon-based surfactant is still more preferably used.

The usage amount of the surfactant is generally 0.001% by mass to 5% by mass, preferably 0.005% by mass to 2% by mass, and still more preferably 0.01% by mass to 0.5% by mass with respect to the total amount of the developer.

The developer used in the invention may include a basic compound. Specific examples and preferable examples of the basic compound that can be included in the developer used in the invention include compounds exemplified as the basic compound that can be included in the resist composition for the semiconductor manufacturing process described above.

As the developing method, a method of dipping a substrate in a tank filled with a developer for a certain period of time (dipping method), a method of performing developing by piling a developer using the surface tension on a substrate surface and stopping development for a certain period of time (paddling method), a method of spraying a developer on a surface of a substrate (spraying method), and a method of developer continuously discharging a developer while scanning a developer discharging nozzle at a regular speed on a substrate that rotates at a regular speed (dynamic dispensing method) can be applied.

If the various developing methods above include a step of discharging a developer from a developing nozzle of a developing apparatus to a resist film, the discharge pressure (flow velocity near a unit area of the discharged developer) of the discharged developer is preferably 2 mL/sec/mm² or less, more preferably 1.5 mL/sec/mm² or less, and still more preferably 1 mL/sec/mm² or less. The lower limit of the flow velocity is not particularly limited, but 0.2 mL/sec/mm² or greater is preferable, when considering throughput.

If the discharge pressure of the discharged developer is caused to be in the range described above, it is possible to significantly decrease defects of the pattern derived from a resist residue after development.

Details of this mechanism are not clear, but it may be considered that, if the discharge pressure is caused to be in the range described above, the pressure applied by the developer to the resist film decreases such that the resist film or the resist pattern is suppressed from being carelessly cut or destroyed.

In addition, the discharge pressure (mL/sec/mm²) of the developer is a value at a developing nozzle outlet in a developing apparatus.

Examples of the method of adjusting the discharge pressure of the developer include a method of adjusting discharge pressure with a pump or the like or a method of changing discharge pressure by adjusting the pressure by a supply from a pressure tank.

In addition, after a step of performing developing by using the developer, a step of stopping development while substituting the developer with another solvent may be performed.

As the rinse liquid in a rinse process performed after the alkaline development, pure water is used, and an appropriate amount of surfactant may be added to be used.

If the developer is an organic-based developer, as the rinse liquid, it is preferable to use a rinse liquid containing at least one type of organic solvent selected from the group consisting of a ketone-based solvent, an ester-based solvent, an alcohol-based solvent, and an amide-based solvent.

In the resist patterning method according to the invention, a step (organic solvent development step) of performing development by using a developer including an organic solvent and a step (alkaline development step) of performing development by using an alkaline aqueous solution and forming a resist pattern can be performed in combination. Accordingly a finer pattern can be formed.

According to the invention, a portion having weak exposure strength is removed by an organic solvent development step, and a portion having strong exposure strength is removed by further performing an alkaline development step. Since it is possible to form a pattern without dissolving only an area having intermediate exposure strength using a multiple development process in which development is performed plural times, it is possible to form a finer pattern than as usual (the same mechanism as disclosed in paragraph “0077” in JP2008-292975A).

In the patterning method according to the invention, the sequence of the alkaline development step and the organic solvent development step is not particularly limited, but it is more preferable that the alkaline development is performed before the organic solvent development step.

In this manner, with respect to the resist film formed from the resist composition for the semiconductor manufacturing process according to the invention, for example, in the case of the negative crosslinking type, a resist film of an unexposed portion is dissolved in a developer and an exposed portion is hardly dissolved in a developer since the exposed portion is crosslinked with a compound having a phenolic hydroxy group. Therefore, a desired pattern is formed on a substrate.

In addition, the invention also relates to a photomask obtained by exposing and developing a resist-coated mask blank. As the exposure and the development, the steps described above are applied. The photomask is suitably used for manufacturing a semiconductor.

The photomask according to the invention may be a light transmission-type mask used in ArF exciplex laser and the like, or may be a light reflection-type mask used in a reflection system lithography having EUV light as a light source.

In addition, the invention also relates to an electronic-device manufacturing method including the resist patterning method according to the invention described above and an electronic device manufactured by the manufacturing method.

The electronic device according to the invention is suitably mounted on an electric and electronic apparatus (home electric appliances. OA media related-apparatuses, optical apparatuses, communication apparatuses, and the like).

### EXAMPLES

Hereinafter, the invention is described in detail with reference to examples, but the invention is not limited thereto.

### Synthesization of Compound (A)

### Synthesization of Compound (A9)

5.0 g of o-aminothiophenol (manufactured by Wako Pure Chemical industries. Ltd.) and 5.0 g of pivaloylacetontitrile (manufactured by Tokyo Chemical Industry Co., Ltd.) were mixed and stirred at 120° C. for 2 hours. After being cooled, a crude product was refined by silica gel column chromatography, so as to obtain 5.7 g of an intermediate A9-A.

3 mL of tetrahydrofuran (THF) and the intermediate A9-A (5.6 g) were mixed, and 24 mL of a 2M hydrochloric acid/THF solution and subsequently isopentyl nitrite (manufactured by Wako Pure Chemical industries, Ltd.) (3.4 g) were dripped under ice cooling, and were heated to room temperature (25° C.) and stirred for 2 hours. Water and ethyl acetate were added to the obtained reaction mixture, liquid separation was performed, an organic phase was washed with water, and the resultant was dried with magnesium sulfate, filtrated, and concentrated, so as to obtain a crude intermediate A9-B.

The crude intermediate A9-B was mixed with acetone (20 mL), triethylamine (manufactured by Wako Pure Chemical industries, Ltd.) (4.9 g) and p-toluenesulfonylchloride (manufactured by Tokyo Chemical industry Co., Ltd.) (5.9 g) were added under ice cooling, heated to room temperature, and stirred for 1 hour. Water and ethyl acetate were added to the obtained reaction mixture, liquid separation was performed, and an organic phase was dried with magnesium sulfate, filtrated, and concentrated, so as to obtain a crude compound (A9). After the crude compound (A9) was re-slurried with methanol, filtrated, and dried so as to obtain a compound (A9) (6.0 g),

In addition, a ¹H-NMR spectrum (300 MHz, CDCl₃) of the compound (A9) was δ=8.1-8.0 (m, 1H), 7.9 (d, 2H), 7.9-7.8 (m, 1H), 7.6-7.5 (m, 2H), 7.4 (d, 2H), 2.4 (s, 3H), and 1.4 (s, 9H).

In the same manner, the compounds (A1) to (A8) and (A10) to (A14) were synthesized.

| | | Volume of |
|---|---|---|
| | | generated |
| | | acid |
| Compound | Chemical Formula | (Å³) |
| Compound (A1) | 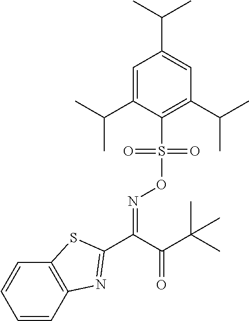 [SMILES: CC(C)c1cc(C(C)C)c(S(=O)(=O)O/N=C(\C(=O)C(C)(C)C)c2nc3ccccc3s2)c(C(C)C)c1] | 303 |
| Compound (A2) | 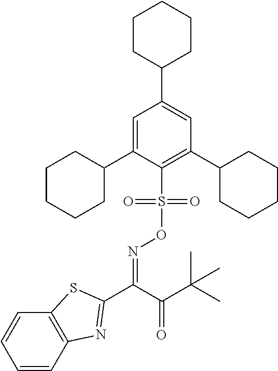 [SMILES: CC(C)(C)C(=O)/C(=N\OS(=O)(=O)c1c(C2CCCCC2)cc(C2CCCCC2)cc1C1CCCCC1)c1nc2ccccc2s1] | 437 |
| Compound (A3) | 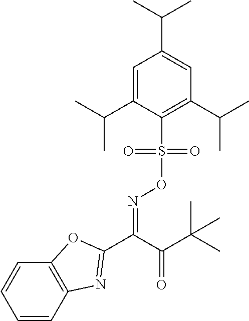 [SMILES: CC(C)c1cc(C(C)C)c(S(=O)(=O)O/N=C(\C(=O)C(C)(C)C)c2nc3ccccc3o2)c(C(C)C)c1] | 303 |
| Compound (A4) | 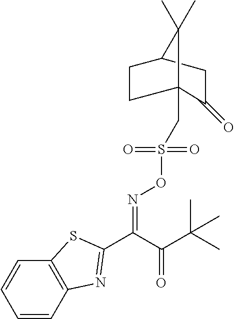 [SMILES: CC(C)(C)C(=O)/C(=N\OS(=O)(=O)CC12CCC(CC1=O)C2(C)C)c1nc2ccccc2s1] | 216 |
| Compound (A5) | 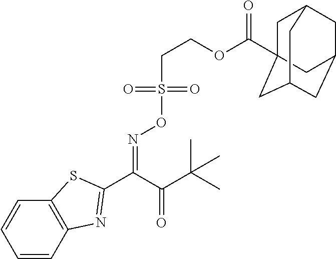 [SMILES: CC(C)(C)C(=O)/C(=N\OS(=O)(=O)CCOC(=O)C12CC3CC(CC(C3)C1)C2)c1nc2ccccc2s1] | 269 |
| Compound (A6) | 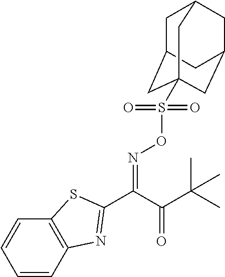 [SMILES: CC(C)(C)C(=O)/C(=N\OS(=O)(=O)C12CC3CC(CC(C3)C1)C2)c1nc2ccccc2s1] | 207 |
| Compound (A7) | 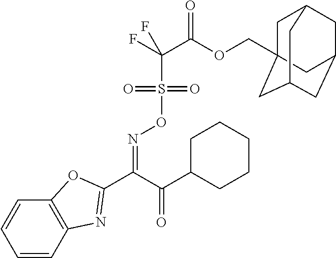 [SMILES: O=C(/C(=N\OS(=O)(=O)C(F)(F)C(=O)OCC12CC3CC(CC(C3)C1)C2)c1nc2ccccc2o1)C1CCCCC1] | 271 |
| Compound (A8) | 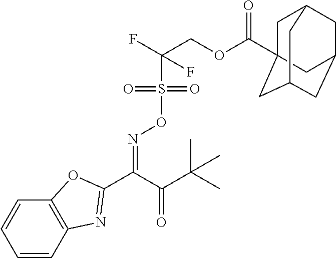 [SMILES: CC(C)(C)C(=O)/C(=N\OS(=O)(=O)C(F)(F)COC(=O)C12CC3CC(CC(C3)C1)C2)c1nc2ccccc2o1] | 270 |
| Compound (A9) | 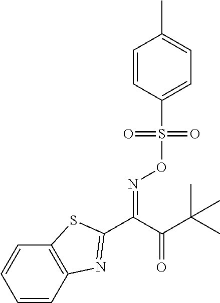 [SMILES: Cc1ccc(S(=O)(=O)O/N=C(\C(=O)C(C)(C)C)c2nc3ccccc3s2)cc1] | 186 |
| Compound (A10) | 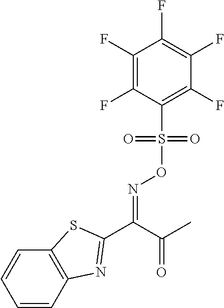 [SMILES: CC(=O)/C(=N\OS(=O)(=O)c1c(F)c(F)c(F)c(F)c1F)c1nc2ccccc2s1] | 127 |
| Compound (A11) | 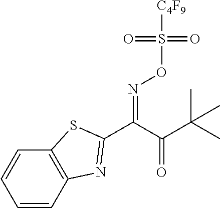 | 113 |
| Compound (A12) | 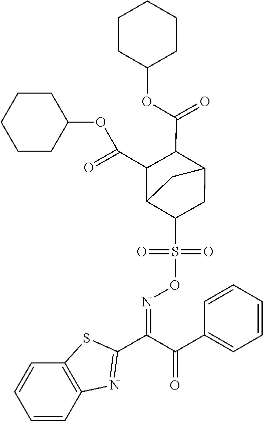 [SMILES: O=C(/C(=N\OS(=O)(=O)C1CC2CC1C(C(=O)OC1CCCCC1)C2C(=O)OC1CCCCC1)c1nc2ccccc2s1)c1ccccc1] | 435 |
| Compound (A13) | 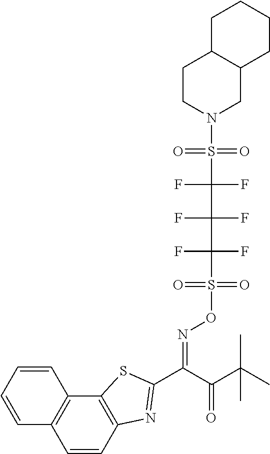 [SMILES: CC(C)(C)C(=O)/C(=N\OS(=O)(=O)C(F)(F)C(F)(F)C(F)(F)S(=O)(=O)N1CCC2CCCCC2C1)c1nc2ccc3ccccc3c2s1] | 311 |
| Compound (A14) | 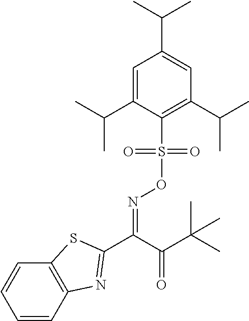 [SMILES: CC(C)c1cc(C(C)C)c(S(=O)(=O)O/N=C(\C(=O)C(C)(C)C)c2nc3ccccc3s2)c(C(C)C)c1] | 303 |
| Comparative Compound 1 | 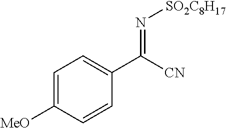 | 211 |
| Comparative Compound 2 | 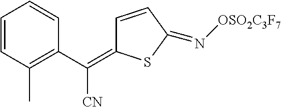 | 113 |
| Comparative Compound 3 | 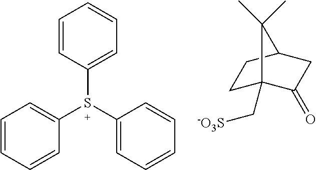 | 216 |

### Example 1P

### Electron Beam Explosure; Positive Type

(1) Preparation of Support

A 6-inch wafer (generally, a product subjected to a shielding film process used in a photomask blank) on which Cr oxide vapor deposition was performed was prepared.

(2) Preparation of resist coating liquid (coating liquid composition of positive resist composition 1D)

| | |
|---|---|
| Compound (P-4) | 0.60 g |
| Compound (A1) (Structural formula was described above) | 0.12 g |
| Tetrabutylammonium hydroxide (Basic compound) | 0.02 g |
| Surfactant PF6320 (manufactured by OMNOVA Solutions | 0.001 g |
| Inc.) | |
| Propylene glycol monomethyl ether acetate (solvent) | 18.0 g |

The composition solution was thoroughly filtrated with a polytetrafluoroethylene filter having a hole diameter of 0.04 μm, and a resist coating solution was obtained.

(3) Creating of Resist Film

The 6-inch wafer was coated with a resist coating solution by using a spin coater Mark8 manufactured by Tokyo Electron Limited., and drying was performed on a hot plate at 110° C. for 90 seconds, so as to obtain a resist film having a film thickness of 50 nm. That is, a resist-coated mask blank was obtained.

(4) Manufacturing of Positive Resist Pattern

The pattern irradiation was performed on the resist film by using an electron beam drawing apparatus (manufactured by Elionix Inc.; ELS-7500, acceleration voltage: 50 KeV). After the irradiation, heating was performed on a hot plate at 120° C. for 90 seconds, dipping was performed for 60 seconds by using 2.38% by mass of a tetramethylammonium hydroxide (TMAH) aqueous solution, rinsing with water was performed for 30 seconds, and drying was performed.

(5) Evaluation of Resist Pattern

The obtained pattern was evaluated in the following method, with respect to sensitivity, resolving power, a pattern form, LER, outgassing, and temporal stability.

[Sensitivity]

A cross-sectional form of the obtained pattern was observed by using a scanning electron microscope (S-4300 manufactured by Hitachi, Ltd.). An exposure amount (electron beam irradiation amount) when a resist pattern having a line width of 50 nm (line:space=1:1) was resolved was set to be sensitivity. As this value becomes smaller, the sensitivity becomes higher.

[Resolving Power Evaluation (LS)]

Marginal resolving power (minimum line width in which a line and a space are separately resolved) in the exposure amount (electron beam irradiation amount) indicating the sensitivity above was set to be resolving power.

[Pattern Form]

A cross-sectional form of a line pattern (L/S=1/1) having the line width of 50 nm having the exposure amount (electron beam irradiation amount) indicating the sensitivity above was observed by using a scanning electron microscope (S-4300 manufactured by Hitachi, Ltd.). In the cross-sectional form of a line pattern, a form of which a ratio expressed by [line width in a bottom portion (base portion) of a line pattern/line width in a middle portion (a position in a half height of a height of a line pattern) of a line pattern] was 1.2 or greater was evaluated as a “forward taper”, a form of which the ratio was 1.05 or greater and less than 1.2 was evaluated as a “almost forward taper”, and a form of which the ratio was less than 1.05 was evaluated as a “rectangle shape”.

[Line Edge Roughness (LER)]

A line pattern (L/S=1/1) having a line width of 50 nm in the irradiation amount (electron beam irradiation amount) indicating the sensitivity above was formed. In addition, with respect to arbitrary 30 points included in 10 μm in the length direction, the distance from a reference line which had to have an edge was measured by using the scanning electron microscope (S-9220 manufactured by Hitachi, Ltd.). Also, standard deviation of the distance was obtained, so as to calculate 3σ. A smaller value indicates a more satisfactory performance.

[Outgassing Performances: Film Thickness Variation Rate after Exposure]

A line pattern (L/S=1/1) having a line width of 50 nm was formed with an irradiation amount (μC/cm²) indicating the sensitivity above, film thickness after exposure (before post baking) was measured, and a variation rate from the film thickness at the time of being unexposed was obtained from the formula below.

Film thickness variation rate (%)=[(film thickness at the time of being unexposed−film thickness after exposure)/film thickness at the time of being unexposed]×100

(Determination Criteria)

A: A film thickness variation rate was less than 5%.

B: A film thickness variation rate was 5% to 10%.

C: A film thickness variation rate was greater than 10%.

[Temporal Stability]

After the resist composition was preserved at room temperature for one month, a degree of sensitivity variation was visually evaluated according to the determination criteria below.

(Determination Criteria)

A: An observed sensitivity variation was less than 1 μC/cm².

B: An observed sensitivity variation was 1 μC/cm² to 3 μC/cm².

C: An observed sensitivity variation was greater than 3 μC/cm².

### Example 2P to Example 24P, and Comparative Example 1P to Comparative Example 3P

### Electron Beam Exposure: Positive Type

In the resist liquid formulation, in the same manner as in Example 1P except for the components described in Table 1 below, the preparation of the resist solution (positive resist compositions 2D to 24D, positive resist comparative compositions 1D to 3D), positive patterning and evaluation thereof were performed.

TABLE 1
[Electron beam exposure; Positive type]

| | | | Basic | Surfac- | Solvent |
|---|---|---|---|---|---|
| | Acid | Com- | com- | tant | (mass |
| Composi- | generator | pound (P) | pound | (0.001 | ratio) |
| tion | (0.12 g) | (0.60 g) | (0.02 g) | g) | (18.0 g) |
| 1D | A1 | P-4 | B1 | W-1 | S1 |
| 2D | A2 | P-4 | B1 | W-1 | S1/S2 (6/4) |
| 3D | A3 | P-4 | B1 | W-1 | S1/S2 (6/4) |
| 4D | A4 | P-4 | B1 | W-1 | S1/S2 (6/4) |
| 5D | A5 | P-4 | B1 | W-1 | S1/S2 (6/4) |
| 6D | A6 | P-4 | B1 | W-1 | S1/S2 (6/4) |
| 7D | A7 | P-4 | B1 | W-1 | S1/S2 (6/4) |
| 8D | A8 | P-4 | B1 | W-1 | S1/S2 (6/4) |
| 9D | A9 | P-4 | B1 | W-1 | S1/S2 (6/4) |
| 10D | A10 | P-4 | B1 | W-1 | S1/S2 (6/4) |
| 11D | A11 | P-4 | B1 | W-1 | S1/S2 (6/4) |
| 12D | A12 | P-4 | B1 | W-1 | S1/S2 (6/4) |
| 13D | A2 | P-5 | B1 | W-1 | S1/S4 (6/4) |
| 14D | A2 | P-6 | B5 | W-1 | S1/S3 (6/4) |
| 15D | A9 | P-9 | B2 | W-1 | S1/S5 (6/4) |
| 16D | A13 | p-11 | B2 | W-1 | S1/S2/S6 |
| | | | | | (6/3/1) |
| 17D | A13 | P-10 | B2 | W-2 | S1/S7 (6/4) |
| 18D | A13 | P-12 | B3 | W-2 | S1/S2 (6/4) |
| 19D | A2 | P-3 | B4 | W-3 | S1/S2 (6/4) |
| 20D | A2 | P-7 | B5 | W-1 | S1/S2 (6/4) |
| 21D | A2 | P-8 | B3 | W-3 | S1/S2 (6/4) |
| 22D | A2 (0.06 g)/ | P-2 (0.3 g)/ | B6 | None | S1/S2 (6/4) |
| | A1 (0.06 g) | P-5 (0.3 g) | | | |
| 23D | A13 | P-4 | B1 | W-1 | S1/S2 (6/4) |
| 24D | A2 (0.06 g)/ | P-4 | B1 | W-1 | S1/S2 (6/4) |
| | Comparative | | | | |
| | Compound 2 | | | | |
| | (0.06 g) | | | | |
| Compar- | Comparative | P-1 | B2 | W-1 | S1/S2 (6/4) |
| ative | Compound 1 | | | | |
| Composi- | | | | | |
| tion 1D | | | | | |
| Compar- | Comparative | P-1 | B2 | W-1 | S1/S2 (6/4) |
| ative | Compound 2 | | | | |
| Composi- | | | | | |
| tion 2D | | | | | |
| Compar- | Comparative | P-1 | B2 | W-1 | S1/S2 (6/4) |
| ative | Compound 3 | | | | |
| Composi- | | | | | |
| tion 3D | | | | | |

[Compound (P)]

Structures, composition ratios (molar ratios), weight average molecular weights (Mw) and dispersity (Mw/Mn) of the used compound (P) are provided below.

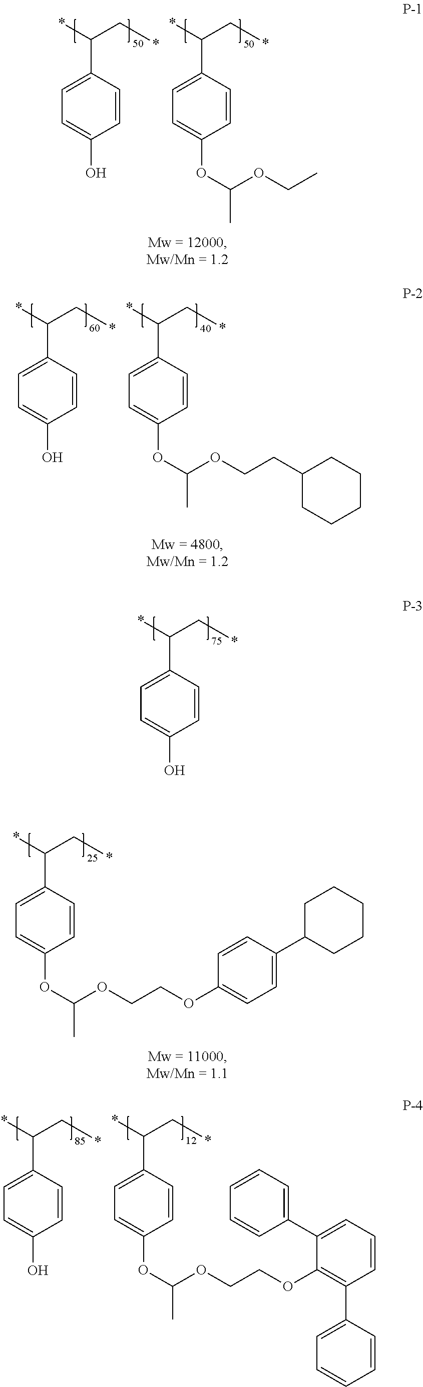

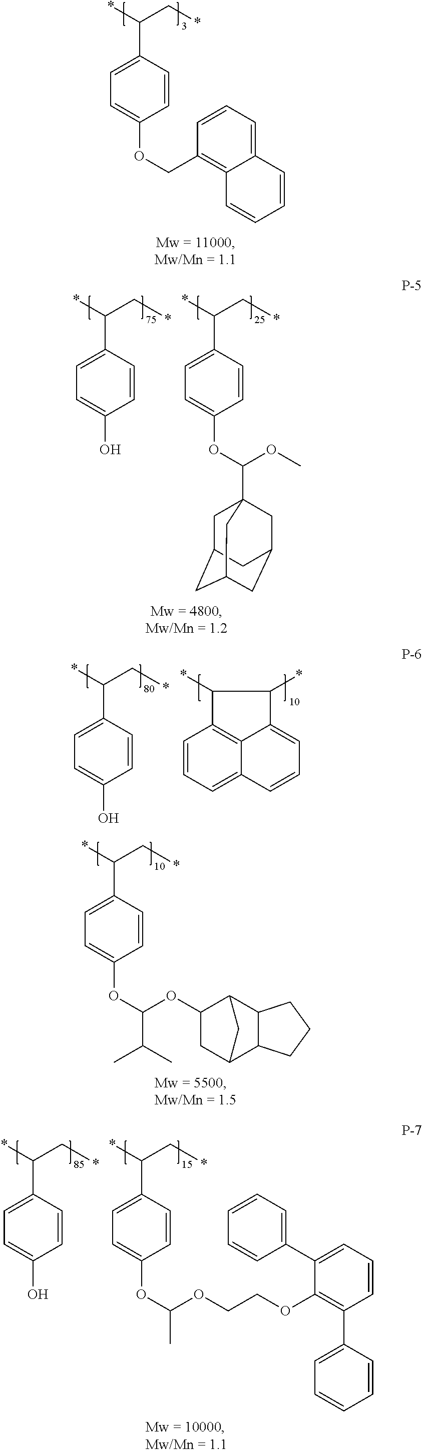

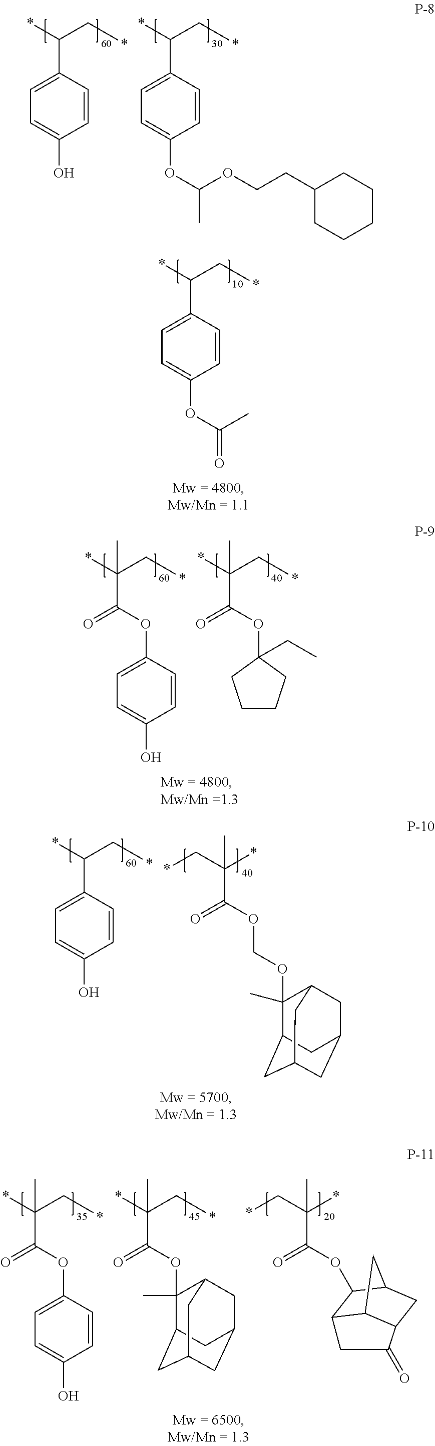

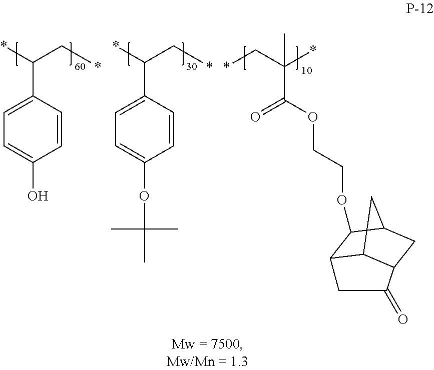

[Basic Compound]

B1: Tetrabutylammonium hydroxide

B2: Tri(n-octyl)amine

B3: 2,4,5-triphenylimidazole

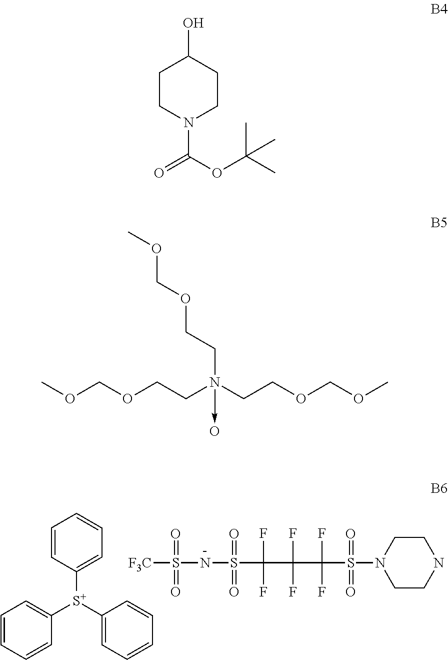

[Surfactant]

W-1: PF6320 (manufactured by OMNOVA Solutions Inc.)

W-2: MEGAFACE F176 (manufactured by Dainippon Ink and Chemicals; fluorine-based)

W-3: Polysiloxane polymer KP-341 (manufactured by Shin-Etsu Chemical Co., Ltd.; silicon-based)

[Solvent]

S1: Propylene glycol monomethyl ether acetate (1-methoxy-2-acetoxypropane)

S2: Propylene glycol monomethyl ether (1-methoxy-2-propanol)

S3: 2-heptanone

S4: Ethyl lactate

S5: Cyclohexanone

S6: γ-butyrolactone

S7: Propylene carbonate

The evaluation results are provided in the table below.

TABLE 2
(Electron beam exposure; Positive type)

| | | Sensitivity | Resolving power | | LER | Out- | Temporal |
|---|---|---|---|---|---|---|---|
| Example | Composition | (μC/cm²) | (nm) | Pattern form | (nm) | gassing | stability |
| 1P | 1D | 10.8 | 25 | Rectangular | 3.5 | A | A |
| 2P | 2D | 10.9 | 25 | Rectangular | 3.5 | A | A |
| 3P | 3D | 10.7 | 25 | Rectangular | 3.5 | A | A |
| 4P | 4D | 10.7 | 25 | Rectangular | 3.5 | A | A |
| 5P | 5D | 11.8 | 25 | Rectangular | 3.5 | A | A |
| 6P | 6D | 10.8 | 25 | Rectangular | 3.5 | A | A |
| 7P | 7D | 10.7 | 25 | Rectangular | 3.5 | A | A |
| 8P | 8D | 10.8 | 25 | Rectangular | 3.5 | A | A |
| 9P | 9D | 10.9 | 30 | Almost | 4.0 | A | A |
| | | | | forward taper | | | |
| 10P | 10D | 10.8 | 30 | Almost | 4.0 | A | B |
| | | | | forward taper | | | |
| 11P | 11D | 10.8 | 35 | Almost | 4.0 | A | A |
| | | | | forward taper | | | |
| 12P | 12D | 10.8 | 25 | Rectangular | | A | A |
| 13P | 13D | 10.7 | 25 | Rectangular | 3.5 | A | A |
| 14P | 14D | 10.8 | 25 | Rectangular | 3.5 | A | A |
| 15P | 15D | 10.8 | 25 | Rectangular | 4.0 | A | A |
| 16P | 16D | 10.6 | 25 | Rectangular | 4.0 | A | A |
| 17P | 17D | 10.8 | 25 | Rectangular | 4.0 | A | A |
| 18P | 18D | 10.6 | 25 | Rectangular | 4.0 | A | A |
| 19P | 19D | 10.6 | 25 | Rectangular | 3.5 | A | A |
| 20P | 20D | 10.8 | 25 | Rectangular | 3.5 | A | A |
| 21P | 21D | 10.8 | 25 | Rectangular | 3.5 | A | A |
| 22P | 22D | 10.8 | 25 | Rectangular | 3.5 | A | A |
| 23P | 23D | 11.8 | 25 | Rectangular | 3.5 | A | A |
| 24P | 24D | 12.4 | 35 | Rectangular | 4.0 | A | A |
| Comparative | Comparative | 12.9 | 50 | Almost | 5.0 | B | C |
| Example 1P | Composition 1D | | | forward taper | | | |
| Comparative | Comparative | 13.9 | 45 | Almost | 5.0 | B | C |
| Example 2P | Composition 2D | | | forward taper | | | |
| Comparative | Comparative | 12.9 | 45 | Forward taper | 5.0 | C | A |
| Example 3P | Composition 3D | | | | | | |

As can be clearly understood from the results in the table above, it is understood that in Comparative Examples 1P to 3P in which acid generators that did not satisfy General Formula (I) were used, sensitivity and resolving power were inferior, the patterns were forward tapers, LER was great, and the generation of outgassing was great, and with respect to Comparative Examples 1P and 2P, temporal stability was also inferior.

Meanwhile, it was understood that, in Examples 1P to 24P in which the compound expressed by General Formula (I) was used as the acid generator, sensitivity and resolving power were excellent, patterns were a rectangle shape, LER was small, the generation of outgassing was small, and temporal stability was excellent.

### Examples 1Q to 9Q and Comparative Examples 1Q to 3Q

### EUV Exposure Positive Type

(Preparation of Resist Solution)

The positive resist compositions presented in the tables below were filtrated with a polytetrafluoroethylene filter having a pore size of 0.04 μm, so as to prepare the positive resist solutions.

(Resist Evaluation)

The silicon substrate subjected to a hexamethyldisilazane treatment was evenly coated with the prepared positive resist solution by using a spin coater, and heating and drying were performed on a hot plate at 100° C. for 60 seconds, so as to form a resist film having the film thickness of 50 nm.

With respect to the obtained resist film, sensitivity, resolving power, pattern form, LER, outgassing, and temporal stability were evaluated by the following methods.

[Sensitivity]

Exposure was performed on the obtained resist film by using an EUV exposure apparatus (Micro Exposure Tool manufactured by Exitech Corporation, NA0.3. Quadrupole, outer sigma: 0.68, inner sigma: 0.36), while changing the exposure amount by 0.1 mJ/cm² in the range of 0 mJ/cm² to 20.0 mJ/cm², via a reflection-type mask with a 1:1 line-and-space pattern having a line width of 50 nm, and then baking was performed at 110° C. for 90 seconds. Thereafter, developing was performed using 2.38% by mass of a tetramethylammonium hydroxide (TMAH) aqueous solution.

An exposure amount that reproduces a line-and-space (L/S=1/1) mask pattern having a line width of 50 nm was set to be sensitivity. As this value becomes smaller, the sensitivity becomes higher.

[Resolving Power]

A marginal resolving power (minimum line width in which a line and a space are separately resolved) in the exposure amount indicating the sensitivity above was set to be resolving power (nm).

[Pattern Form]

A cross-sectional form of a line pattern (L/S=1/1) having a line width of 50 nm in the exposure amount indicating the sensitivity above was observed by using a scanning electron microscope (S-4300 manufactured by Hitachi, Ltd.). In the cross-sectional form of the line pattern, a form of which the ratio expressed by [line width, in a bottom portion (base portion) of a line pattern/line width in a middle portion (a position in a half height of a height of a line pattern) of a line pattern] was 1.2 or greater was evaluated as a “forward taper”, a form having the ratio of 1.05 or greater and less than 1.2 was evaluated as an “almost forward taper”, and a form having the ratio of less than 1.05 was evaluated as a “rectangle shape”.

[LER]

A line pattern (L/S=1/1) having a line width of 50 nm was formed in the exposure amount indicating the sensitivity above. In addition, with respect to arbitrary 30 points included in 10 μm in the length direction, the distance from a reference line which had to have an edge was measured by using the scanning electron microscope (S-9220 manufactured by Hitachi, Ltd.). Also, standard deviation of the distance was obtained, so as to calculate 3σ. The smaller value indicates a more satisfactory performance.

[Outgassing Performance: Film Thickness Variation Rate after Exposure]

A line pattern (L/S=1/1) having a line width of 50 nm was formed in the exposure amount (mJ/cm²) indicating the sensitivity above, film thickness after exposure (before post baking) was measured and a variation rate from the film thickness at the time of being unexposed was obtained from the formula below.

Film thickness variation rate (%)=[(film thickness at the time of being unexposed−film thickness after exposure)/film thickness at the time of being unexposed]×100

(Determination Criteria)

A: A film thickness variation rate was less than 5%.

B: A film thickness variation rate was 5% to 10%.

C: A film thickness variation rate was greater than 10%.

[Temporal Stability]

After the resist composition was preserved for one month in room temperature, the degree of sensitivity variation was visually evaluated according to the determination criteria below.

(Determination Criteria)

A: An observed sensitivity variation was less than 1 mJ/cm².

B: An observed sensitivity variation was 1 mJ/cm² to 3 mJ/cm².

C: An observed sensitivity variation was greater than 3 mJ/cm².

Evaluation results above were provided below.

TABLE 3
(EUV Exposure: Positive type)

| | | Sensitivity | Resolving power | | LER | Out- | Temporal |
|---|---|---|---|---|---|---|---|
| Example | Composition | (mJ/cm²) | (nm) | Pattern form | (nm) | gassing | stability |
| 1Q | 1D | 10.8 | 20 | Rectangular | 3.5 | A | A |
| 2Q | 2D | 10.8 | 20 | Rectangular | 3.5 | A | A |
| 3Q | 10D | 10.8 | 25 | Almost | 4.0 | A | B |
| | | | | forward taper | | | |
| 4Q | 11D | 11.7 | 25 | Almost | 4.0 | A | A |
| | | | | forward taper | | | |
| 5Q | 14D | 10.8 | 20 | Rectangular | 3.5 | A | A |
| 6Q | 15D | 10.8 | 20 | Rectangular | 4.0 | A | A |
| 7Q | 16D | 10.7 | 20 | Rectangular | 4.0 | A | A |
| 8Q | 17D | 10.8 | 20 | Rectangular | 3.5 | A | A |
| 9Q | 12D | 12.9 | 20 | Rectangular | 3.5 | A | A |
| Comparative | Comparative | 13.9 | 50 | Almost | 5.0 | B | C |
| Example 1Q | Composition 1D | | | forward taper | | | |
| Comparative | Comparative | 13.9 | 45 | Almost | 5.0 | B | C |
| Example 2Q | Composition 2D | | | forward taper | | | |
| Comparative | Comparative | 13.9 | 50 | Forward taper | 5.0 | C | A |
| Example 3Q | Composition 3D | | | | | | |

As can be clearly understood from the results in the table above, it is understood that in Comparative Examples 1Q to 3Q in which acid generators that did not satisfy General Formula (I) was used, sensitivity and resolving power were inferior, the patterns were a reverse taper shape, LER was great, and the generation of outgassing was great, and with respect to Comparative Examples 1Q and 2Q, temporal stability was inferior.

Meanwhile, it was understood that, in Examples 1Q to 9Q in which the compound expressed by General Formula (I) was used as the acid generator, sensitivity and resolving power were excellent, patterns were a rectangle shape, LER was small, the generation of outgassing was small, and temporal stability was excellent.

### Examples 1E to 29E, and Comparative Examples 1E to 3E

### Electron Beam Exposure; Negative Crosslinking Type

(1) Preparation of Support

A 6-inch wafer (generally, a product subjected to a shielding film process used in a photomask blank) on which Cr oxide vapor deposition was performed was prepared.

(2) Preparation of Resist Coating Liquid

(Coating liquid composition of negative resist composition N1)

| | |
|---|---|
| Compound (P-24) | 4.21 g |
| Compound (A1) (Structural formula is described above) | 0.47 g |
| Crosslinking agent CL-1 (Structural formula is described | 0.59 g |
| above) | |
| Crosslinking agent CL-4 (Structural formula is described | 0.30 g |
| above) | |
| Tetrabutylammonium hydroxide (basic compound) | 0.04 g |
| 2-hydroxy-3-naphthoic acid (organic carboxylic acid) | 0.11 g |
| Surfactant PF6320 (manufactured by OMNOVA Solutions | 0.005 g |
| Inc.) | |
| Propylene glycol monomethyl ether acetate (solvent) | 18.8 g |
| Propylene glycol monomethyl ether (solvent) | 75.0 g |

TABLE 4

| | Acid | Compound | Organic car- | Basic | | Crosslinking | |
|---|---|---|---|---|---|---|---|
| Composition | generator | (P) | boxylic acid | compound | Surfactant | agent | Solvent |
| N1 | A1 | P-24 | D1 | B1 | W-1 | CL-1/CL-4 | S2/S1 |
| | (0.47 g) | (4.21 g) | (0.11 g) | (0.04 g) | (0.005 g) | (0.59 g/0.30 g) | (75.0 g/18.8 g) |
| N2 | A2 | P-24 | D1 | B1 | W-1 | CL-1/CL-4 | S1/S3 |
| | (0.47 g) | (4.21 g) | (0.11 g) | (0.04 g) | (0.005 g) | (0.59 g/0.30 g) | (75.0 g/18.8 g) |
| N3 | A3 | P-24 | D1 | B1 | W-1 | CL-1/CL-4 | S2/S3 |
| | (0.47 g) | (4.21 g) | (0.11 g) | (0.04 g) | (0.005 g) | (0.59 g/0.30 g) | (75.0 g/18.8 g) |
| N4 | A4 | P-24 | D1 | B1 | W-1 | CL-1/CL-4 | S2/S7 |
| | (0.47 g) | (4.21 g) | (0.11 g) | (0.04 g) | (0.005 g) | (0.59 g/0.30 g) | (75.0 g/18.8 g) |
| N5 | A5 | P-24 | D1 | B1 | W-1 | CL-1/CL-4 | S2/S1 |
| | (0.47 g) | (4.21 g) | (0.11 g) | (0.04 g) | (0.005 g) | (0.59 g/0.30 g) | (75.0 g/18.8 g) |
| N6 | A6 | P-24 | D1 | B1 | W-1 | CL-1/CL-4 | S2/S1 |
| | (0.47 g) | (4.21 g) | (0.11 g) | (0.04 g) | (0.005 g) | (0.59 g/0.30 g) | (75.0 g/18.8 g) |
| N7 | A7 | P-24 | D1 | B1 | W-1 | CL-1/CL-4 | S2/S1 |
| | (0.47 g) | (4.21 g) | (0.11 g) | (0.04 g) | (0.005 g) | (0.59 g/0.30 g) | (75.0 g/18.8 g) |
| N8 | A8 | P-24 | D1 | B1 | W-1 | CL-1/CL-4 | S2/S1 |
| | (0.47 g) | (4.21 g) | (0.11 g) | (0.04 g) | (0.005 g) | (0.59 g/0.30 g) | (75.0 g/18.8 g) |
| N9 | A9 | P-24 | D1 | B1 | W-1 | CL-1/CL-4 | S2/S1 |
| | (0.47 g) | (4.21 g) | (0.11 g) | (0.04 g) | (0.005 g) | (0.59 g/0.30 g) | (75.0 g/18.8 g) |
| N10 | A10 | P-24 | D1 | B1 | W-1 | CL-1/CL-4 | S2/S1 |
| | (0.47 g) | (4.21 g) | (0.11 g) | (0.04 g) | (0.005 g) | (0.59 g/0.30 g) | (75.0 g/18.8 g) |
| N11 | A1 | P-21 | D1 | B1 | W-1 | CL-1/CL-4 | S2/S1 |
| | (0.47 g) | (4.21 g) | (0.11 g) | (0.04 g) | (0.005 g) | (0.59 g/0.30 g) | (75.0 g/18.8 g) |
| N12 | A1 | P-22 | D1 | B1 | W-1 | CL-1/CL-4 | S1/S2/S6 |
| | (0.47 g) | (4.21 g) | (0.11 g) | (0.04 g) | (0.005 g) | (0.59 g/0.30 g) | (50.0 g/25.0 g/18.8 g) |
| N13 | A1 | P-23 | D1 | B1 | W-1 | CL-1/CL-4 | S1/S2/S5 |
| | (0.47 g) | (4.21 g) | (0.11 g) | (0.04 g) | (0.005 g) | (0.59 g/0.30 g) | (50.0 g/25.0 g/18.8 g) |
| N14 | A1 | P26 | D1 | B1 | W-1 | CL-1/CL-4 | S1/S2/S4 |
| | (0.47 g) | (4.21 g) | (0.11 g) | (0.04 g) | (0.005 g) | (0.59 g/0.30 g) | (50.0 g/25.0 g/18.8 g) |
| N15 | A1 | P-24 | D1 | B2 | W-1 | CL-1/CL-4 | S2/S1 |
| | (0.47 g) | (4.21 g) | (0.11 g) | (0.04 g) | (0.005 g) | (0.59 g/0.30 g) | (75.0 g/18.8 g) |
| N16 | A1 | P-27 | D1 | B3 | None | None | S2/S1 |
| | (0.47 g) | (5.10 g) | (0.11 g) | (0.04 g) | | | (75.0 g/18.8 g) |

TABLE 5
(Continued from Table 4 above)

| | Acid | Compound | Organic car- | Basic | | Crosslinking | |
|---|---|---|---|---|---|---|---|
| Composition | generator | (P) | boxylic acid | compound | Surfactant | agent | Solvent |
| N17 | A1 | P-25 | D1 | B1 | None | CL-3 | S2/S1 |
| | (0.47 g) | (4.21 g) | (0.11 g) | (0.04 g) | | (0.89 g) | (75.0 g/18.8 g) |
| N18 | A1 | P-24 | D1 | B1/B6 | None | CL-1/CL-5 | S2/S1 |
| | (0.47 g) | (4.21 g) | (0.11 g) | (0.02 g/0.02 g) | | (0.59 g/0.30 g) | (75.0 g/18.8 g) |
| N19 | A1 | P-24 | D1 | B5 | None | CL-2/CL-3 | S2/S1 |
| | (0.47 g) | (4.21 g) | (0.11 g) | (0.04 g) | | (0.59 g/0.30 g) | (75.0 g/18.8 g) |
| N20 | A1 | P-25 | D1 | B4 | None | CL-3 | S2/S1 |
| | (0.47 g) | (4.21 g) | (0.11 g) | (0.04 g) | | (0.89 g) | (75.0 g/18.8 g) |
| N21 | A1 | P-24 | D2 | B1 | W-2 | CL-1/CL-5 | S2/S1 |
| | (0.47 g) | (4.21 g) | (0.11 g) | (0.04 g) | (0.005 g) | (0.59 g/0.30 g) | (75.0 g/18.8 g) |
| N22 | A1 | P-23 | D2 | B3 | W-3 | CL-3 | S2/S1 |
| | (0.47 g) | (4.21 g) | (0.11 g) | (0.04 g) | (0.005 g) | (0.89 g) | (75.0 g/18.8 g) |
| N23 | A1 | P-21/P-23 | D3 | B2 | None | CL-2 | S2/S1 |
| | (0.47 g) | (2.0 g/2.21 g) | (0.11 g) | (0.04 g) | | (0.89 g) | (75.0 g/18.8 g) |
| N24 | A1 | P-24 | None | B6 | None | CL-1/CL-5 | S2/S1 |
| | (0.47 g) | (4.21 g) | | (0.04 g) | | (0.59 g/0.30 g) | (75.0 g/18.8 g) |
| N25 | A1/A2 | P-24 | D3 | B6 | None | CL-1/CL-5 | S2/S1 |
| | (0.20 g/0.27 g) | (4.21 g) | (0.11 g) | (0.04 g) | | (0.59 g/0.30 g) | (75.0 g/18.8 g) |
| N26 | A11 | P-24 | D1 | B1 | W-1 | CL-1/CL-4 | S2/S1 |
| | (0.47 g) | (4.21 g) | (0.11 g) | (0.04 g) | (0.005 g) | (0.59 g/0.30 g) | (75.0 g/18.8 g) |
| N27 | A12 | P-24 | D1 | B1 | W-1 | CL-1/C1/-4 | S2/S1 |
| | (0.47 g) | (4.21 g) | (0.11 g) | (0.04 g) | (0.005 g) | (0.59 g/0.30 g) | (75.0 g/18.8 g) |
| N28 | A13 | P-24 | D1 | B1 | W-1 | CL-1/CL-4 | S2/S1 |
| | (0.47 g) | (4.21 g) | (0.11 g) | (0.04 g) | (0.005 g) | (0.59 g/0.30 g) | (75.0 g/18.8 g) |
| N29 | A1/Comparative | P-24 | D1 | B1 | W-1 | CL-1/CL-4 | S2/S1 |
| | Compound 2 | (4.21 g) | (0.11 g) | (0.04 g) | (0.005 g) | (0.59 g/0.30 g) | (75.0 g/18.8 g) |
| | (0.20 g/0.27 g) | | | | | | |
| Comparative | Comparative | P-22 | D1 | B2 | W-1 | CL-3 | S1 |
| Composition N1 | Compound 1 | (4.80 g) | (0.11 g) | (0.04 g) | (0.005 g) | (0.89 g) | (93.8 g) |
| | (0.47 g) | | | | | | |
| Comparative | Comparative | P-22 | D1 | B2 | W-1 | CL-3 | S1 |
| Composition N2 | Compound 2 | (4.21 g) | (0.11 g) | (0.04 g) | (0.005 g) | (0.89 g) | (93.8 g) |
| | (0.47 g) | | | | | | |
| Comparative | Comparative | P-22 | D1 | B2 | W-1 | CL-3 | S1 |
| Composition N3 | Compound 3 | (4.21 g) | (0.11 g) | (0.04 g) | (0.005 g) | (0.89 g) | (93.8 g) |
| | (0.47 g) | | | | | | |

[Compound (P)]

Structures, composition ratios (molar ratios), weight average molecular weights (Mw) and dispersity (Mw/Ma) of the compound (P) used are provided below.

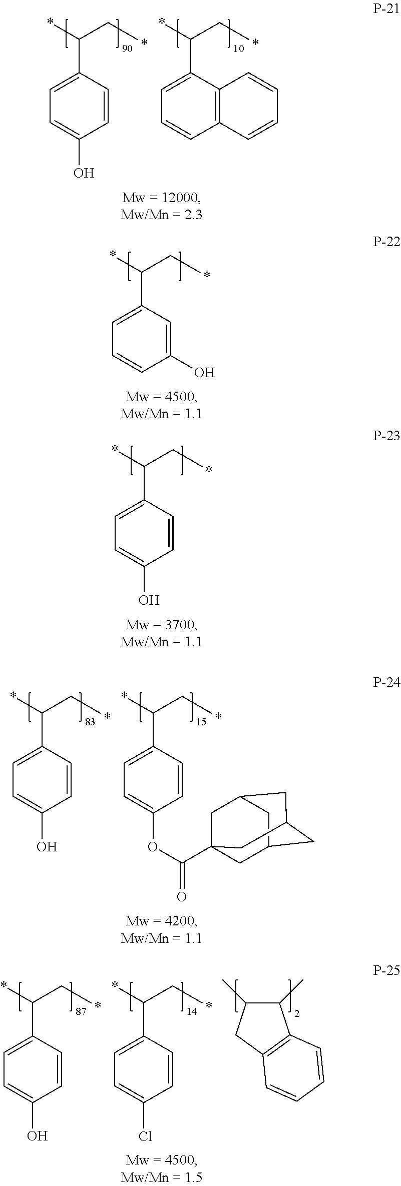

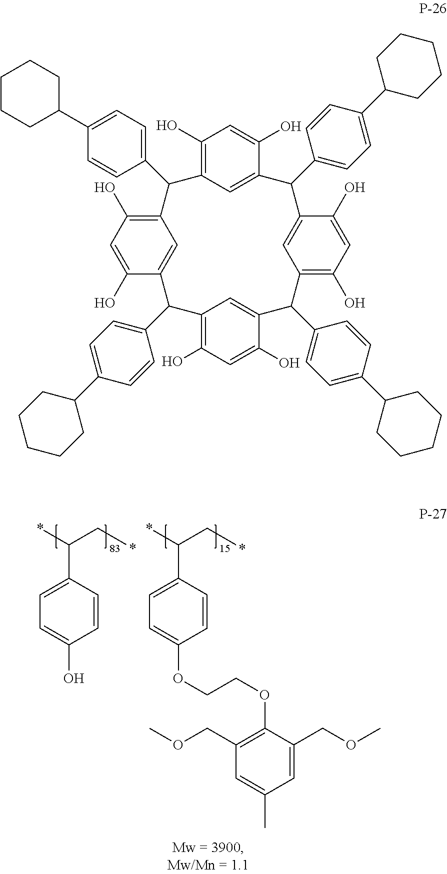

[Crosslinking Agent]

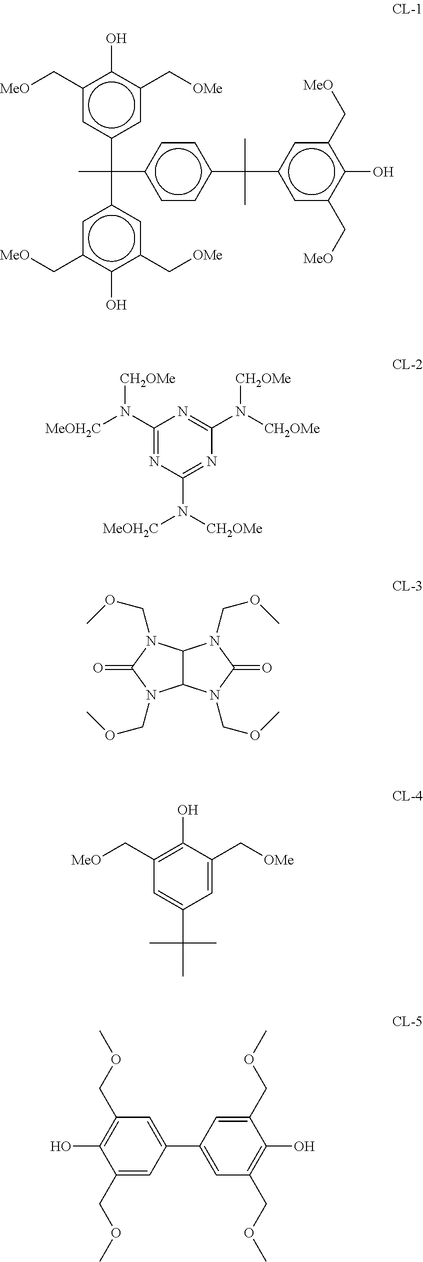

[Basic Compound]

Basic compounds B1 to B6 are as described above.

### [Organic Carboxylic Acid]

D1: 2-hydroxy-3-naphthoic acid

D2: 2-naphthoic acid

D3: Benzoic acid

### [Surfactant]

Surfactants W1 to W3 are as described above.

### [Solvent]

Solvents S1 to S7 are as described above.

The composition solution was precisely filtrated with a polytetrafluoroethylene filer having a hole diameter of 0.04 μm, so as to obtain a resist coating solution.

(3) Creating of Resist Film

The 6-inch wafer was coated with a resist coating solution by using a spin coater Mark8 manufactured by Tokyo Electron Limited, and drying was performed on a hot plate at 110° C. for 90 seconds, so as to obtain a resist film having a film thickness of 50 nm. That is, a resist-coated mask blank was obtained.

(4) Manufacturing of Negative Resist Pattern

Pattern irradiation was performed on the resist film by using an electron beam drawing apparatus (manufactured by Elionix Inc.; ELS-7500, acceleration voltage: 50 KeV). After the irradiation, heating was performed on a hot plate at 120° C. for 90 seconds, dipping was performed for 60 seconds by using 2.38% by mass of a tetramethylammonium hydroxide (TMAH) aqueous solution, and rinsing with water was performed for 30 seconds and dried.

(5) Evaluation of Resist Pattern

The obtained pattern was evaluated in the following method, with respect to sensitivity, resolving power, a pattern form, LER, outgassing, and temporal stability.

[Sensitivity]

A cross-sectional form of the obtained pattern was observed by using a scanning electron microscope (S-4300 manufactured by Hitachi. Ltd.). An exposure amount (electron beam irradiation amount) when a resist pattern having a line width of 50 nm (line:space=1:1) was resolved was set to be sensitivity. As this value becomes smaller, sensitivity becomes higher.

[Resolving Power]

A marginal resolving power (minimum line width in which a line and a space are separately resolved) in the exposure amount (electron beam irradiation amount) indicating the sensitivity above was set to be resolving power (nm).

### [Pattern Form]

A cross-sectional form of a line pattern (L/S=1/1) having a line width of 50 nm in the exposure amount (electron beam irradiation amount) indicating the sensitivity above was observed by using a scanning electron microscope (S-4300 manufactured by Hitachi, Ltd.). In the cross-sectional form of the line pattern, a form of which the ratio expressed by [line width in a top portion (surface portion) of a line pattern/line width in a middle portion (a position in a half height of a height of a line pattern) of a line pattern] was 1.5 or greater was evaluated as a “reverse taper”, a form having the ratio of 1.2 or greater and less than 1.5 was evaluated as an “almost reverse taper”, and a form having the ratio of less than 1.2 was evaluated as a “rectangle shape”.

[LER]

A line pattern (L/S=1/1) having a line width of 50 nm was formed in the irradiation amount indicating the sensitivity above. In addition, with respect to arbitrary 30 points included in 50 μm in the length direction, the distance from a reference line which had to have an edge was measured by using the scanning electron microscope (S-9220 manufactured by Hitachi, Ltd.). Also, standard deviation of the distance was obtained, so as to calculate 3σ. The smaller value indicates a more satisfactory performance.

[Outgassing Performance: Film Thickness Variation Rate after Exposure]

A line pattern (L/S=1/1) having a line width of 50 nm was formed in the irradiation amount (μC/cm²) indicating the sensitivity above, film thickness after exposure (before post baking) was measured and a variation rate from the film thickness at the time of being unexposed was obtained from the formula below.

Film thickness variation rate (%)=[(film thickness at the time of being unexposed−film thickness after exposure/film thickness at the time of being unexposed]×100

(Determination Criteria)

A: A film thickness variation rate was less than 5%.

B: A film thickness variation rate was 5% to 10%.

C: A film thickness variation rate was greater than 10%.

[Temporal Stability]

After the resist composition was preserved for one month at room temperature, a degree of sensitivity variation was visually evaluated according to the determination criteria below.

(Determination Criteria)

A: An observed sensitivity variation was less than 1 μC/cm².

B: An observed sensitivity variation was 1 μC/cm³ to 3 μC/cm².

C: An observed sensitivity variation was greater than 3 μC/cm².

TABLE 6
(Electronic beam exposure; Negative crosslinking type)

| | | Sensitivity | Resolving | | LER | Out- | Temporal |
|---|---|---|---|---|---|---|---|
| Example | Composition | (μC/cm²) | power (nm) | Pattern form | (nm) | gassing | stability |
| 1E | N1 | 10.2 | 25 | Rectangular | 3.5 | A | A |
| 2E | N2 | 10.0 | 25 | Rectangular | 3.5 | A | A |
| 3E | N3 | 10.2 | 25 | Rectangular | 3.5 | A | A |
| 4E | N4 | 10.2 | 25 | Rectangular | 3.5 | A | A |
| 5E | N5 | 11.3 | 25 | Rectangular | 3.5 | A | A |
| 6E | N6 | 10.3 | 25 | Rectangular | 3.5 | A | A |
| 7E | N7 | 10.0 | 25 | Rectangular | 3.5 | A | A |
| 8E | N8 | 10.2 | 25 | Rectangular | 3.5 | A | A |
| 9E | N9 | 10.2 | 30 | Almost | 4.0 | A | A |
| | | | | reverse taper | | | |
| 10E | N10 | 10.2 | 30 | Almost | 4.0 | A | B |
| | | | | reverse taper | | | |
| 11E | N11 | 10.3 | 25 | Rectangular | 3.5 | A | A |
| 12E | N12 | 10.2 | 25 | Rectangular | 3.5 | A | A |
| 13E | N13 | 10.3 | 25 | Rectangular | 3.5 | A | A |
| 14E | N14 | 10.4 | 25 | Rectangular | 3.5 | A | A |
| 15E | N15 | 10.3 | 25 | Rectangular | 3.5 | A | A |
| 16E | N16 | 10.2 | 25 | Rectangular | 3.5 | A | A |
| 17E | N17 | 10.3 | 25 | Rectangular | 3.5 | A | A |
| 18E | N18 | 10.5 | 25 | Rectangular | 3.5 | A | A |
| 19E | N19 | 10.2 | 25 | Rectangular | 3.5 | A | A |
| 20E | N20 | 10.2 | 25 | Rectangular | 3.5 | A | A |
| 21E | N21 | 10.3 | 25 | Rectangular | 3.5 | A | A |
| 22E | N22 | 10.2 | 25 | Rectangular | 3.5 | A | A |
| 23E | N23 | 10.4 | 25 | Rectangular | 3.5 | A | A |
| 24E | N24 | 10.2 | 25 | Rectangular | 3.5 | A | A |
| 25E | N25 | 10.3 | 25 | Rectangular | 3.5 | A | A |
| 26E | N26 | 11.2 | 35 | Almost | 4.0 | A | A |
| | | | | reverse taper | | | |
| 27E | N27 | 12.2 | 25 | Rectangular | 3.5 | A | A |
| 28E | N28 | 11.2 | 25 | Rectangular | 3.5 | A | A |
| 29E | N29 | 12.2 | 35 | Rectangular | 4.5 | A | A |
| Comparative | Comparative | 13.8 | 40 | Almost | 5.0 | B | C |
| Example 1E | Composition N1 | | | reverse taper | | | |
| Comparative | Comparative | 14.8 | 40 | Almost | 5.0 | B | C |
| Example 2E | Composition N2 | | | reverse taper | | | |
| Comparative | Comparative | 13.8 | 40 | Reverse taper | 5.0 | C | A |
| Example 3E | Composition N3 | | | | | | |

As clearly understood from the results in the table above, it was understood that in Comparative Examples 1E to 3E in which acid generators that did not satisfy General Formula (I) was used, sensitivity and resolving power were inferior, the patterns were forward tapers, LER was great, and the generation of outgassing was great, and with respect to Comparative Examples 1E and 2E, temporal stability was inferior.

Meanwhile, it was understood that, in Examples 1E to 29E in which the compound expressed by General Formula (I) was used as the acid generator, sensitivity and resolving power were excellent, patterns were rectangle, LER was small, the generation of outgassing was small, and temporal stability was excellent.

### Examples 1F to 6F and Comparative Examples 1F to 3F

### EUV Exposure; Negative Crosslinking Type

(Preparation of Resist Solution)

The negative resist compositions presented in the tables below were filtrated with a polytetrafluoroethylene filter having a pore size of 0.04 μm, so as to prepare the negative resist solutions.

(Resist Evaluation)

The silicon substrate subjected to a hexamethyldisilazane treatment was evenly coated with the prepared negative resist solution by using a spin coater, and heating and drying were performed on a hot plate at 100° C. for 60 seconds, so as to form a resist film having the film thickness of 50 nm.

With respect to the obtained resist film, sensitivity, resolving power, pattern form, LER, outgassing, and temporal stability were evaluated by the following methods.

[Sensitivity]

Exposure was performed on the obtained resist film by using an EUV exposure apparatus (Micro Exposure Tool manufactured by Exitech Corporation, NA0.3, Quadrupole, outer sigma: 0.68, inner sigma: 0.36), while changing the exposure amount by 0.1 mJ/cm² in the range of 0 mJ/cm² to 20.0 mJ/cm², via a reflection-type mask with a 1:1 line-and-space pattern having a line width of 50 nm, and then baking was performed at 110° C. for 90 seconds. Thereafter, developing was performed using 2.38% by mass of a tetramethylammonium hydroxide (TMAH) aqueous solution.

An exposure amount that reproduces a line-and-space (L/S=1/1) mask pattern having a line width of 50 nm was set to be sensitivity. As this value is smaller, the sensitivity becomes high.

[Resolving Power]

A marginal resolving power (minimum line width in which a line and a space are separately resolved) in the exposure amount indicating the sensitivity above was set to be resolving power (nm).

[Pattern Form]

A cross-sectional form of a line pattern (L/S=1/1) having a line width of 50 nm in the exposure amount indicating the sensitivity above was observed by using a scanning electron microscope (S-4300 manufactured by Hitachi, Ltd.). In the cross-sectional form of the line pattern, a form of which the ratio expressed by [line width in a top portion (surface portion) of a line pattern/line width in a middle portion (a position in a half height of a height of a line pattern) of a line pattern] was 1.5 or greater was evaluated as a “reverse taper”, a form having the ratio of 1.2 or greater and less than 1.5 was evaluated as an “almost reverse taper”, and a form having the ratio of less than 1.2 was evaluated as a “rectangle shape”.

[LER]

A line pattern (L/S=1/1) having a line width of 50 nm was formed in the exposure amount indicating the sensitivity above. In addition, with respect to arbitrary 30 points included in 10 μm in the length direction, the distance from a reference line which had to have an edge was measured by using the scanning electron microscope (S-9220 manufactured by Hitachi, Ltd.). Also, standard deviation of the distance was obtained, so as to calculate 3σ. The smaller value indicates a more satisfactory performance.

[Outgassing Performance: Film Thickness Variation Rate after Exposure]

A line pattern (L/S=1/1) having a line width of 50 nm was formed in the exposure amount (mJ/cm²) indicating the sensitivity above, film thickness after exposure (before post baking) was measured and a variation rate from the film thickness at the time of being unexposed was obtained from the formula below.

Film thickness variation rate (%)=[(film thickness at the time of being unexposed−film thickness after exposure)/film thickness at the time of being unexposed]×100

(Determination Criteria)

A: A film thickness variation rate was less than 5%.

B: A film thickness variation rate was 5% to 10%.

C: A film thickness variation rate was greater than 10%.

[Temporal Stability]

After the resist composition was preserved for one month at room temperature, a degree of sensitivity variation was visually evaluated according to the determination criteria below.

(Determination Criteria)

A: An observed sensitivity variation was less than 1 mJ/cm².

B: An observed sensitivity variation was 1 mJ/cm² to 3 mJ/cm².

C: An observed sensitivity variation was greater than 3 mJ/cm².

Evaluation results above were provided below.

TABLE 7
(EUV exposure; Negative crosslinking type)

| | | Sensitivity | Resolving power | | LER | Out- | Temporal |
|---|---|---|---|---|---|---|---|
| Example | Composition | (mJ/cm²) | (nm) | Pattern form | (nm) | gassing | stability |
| 1F | N1 | 12.8 | 20 | Rectangular | 4.0 | A | A |
| 2F | N2 | 12.7 | 20 | Rectangular | 4.0 | A | A |
| 3F | N3 | 12.8 | 20 | Rectangular | 4.0 | A | A |
| 4F | N12 | 12.8 | 20 | Rectangular | 4.0 | A | A |
| 5F | N14 | 12.0 | 20 | Rectangular | 4.0 | A | A |
| 6F | N27 | 12.5 | 20 | Almost | 4.0 | A | A |
| | | | | reverse taper | | | |
| Comparative | Comparative | 15.9 | 40 | Almost | 5.0 | B | C |
| Example 1F | Composition N1 | | | reverse taper | | | |
| Comparative | Comparative | 15.8 | 40 | Almost | 5.0 | B | C |
| Example 2F | Composition N2 | | | reverse taper | | | |
| Comparative | Comparative | 16.8 | 40 | Reverse taper | 5.0 | C | A |
| Example 3F | Composition N3 | | | | | | |

As can be clearly understood from the results in the table above, it is understood that in Comparative Examples 1F to 3F in which acid generators that did not satisfy General Formula (I) were used, sensitivity and resolving power were inferior, the patterns were a forward taper shape, LER was great, and the generation of outgassing was great, and with respect to Comparative Examples 1F and 2F, temporal stability was inferior.

Meanwhile, it was understood that, in Examples 1F to 6F in which the compound expressed by General Formula (I) was used as the acid generator, sensitivity and resolving power were excellent, the patterns were a rectangle shape, LER was small, the generation of outgassing was small, and temporal stability was excellent.

### Example 1G

### EUV Exposure; Organic Solvent Development Type (Negative Type)

Preparation of Resist Coating Liquid

(Coating Liquid Composition of Negative Resist Composition 1R for Developing Organic Solvent)

| | |
|---|---|
| Compound (P-31) | 0.60 g |
| Compound (A2) (Structural formula is described above) | 0.12 g |
| Tetrabutylammonium hydroxide (basic compound) | 0.02 g |
| Surfactant PF6320 (manufactured by OMNOVA Solutions | 0.001 g |
| Inc.) | |
| Propylene glycol monomethyl ether acetate (solvent) | 5.4 g |
| Propylene glycol monomethyl ether (solvent) | 3.6 g |

(Preparation of resist solution)

The resist compositions described above below were filtrated with a polytetrafluoroethylene filter having a pore size of 0.04 μm, so as to prepare the resist solutions.

(Resist Evaluation)

The silicon substrate subjected to a hexamethyldisilazane treatment was evenly coated with the prepared resist solution using a spin coater, and heating and drying were performed on a hot plate at 100° C. for 60 seconds, so as to form a resist film having the film thickness of 50 nm.

With respect to the obtained resist film, sensitivity, resolving power, pattern form, LER, outgassing, and temporal stability were evaluated by the following methods.

[Sensitivity]

Exposure was performed on the obtained resist film by using an EUV exposure apparatus (Micro Exposure Tool manufactured by Exitech Corporation, NA0.3, Quadrupole, outer sigma: 0.68, inner sigma: 0.36), while changing the exposure amount by 0.1 mJ/cm² in the range of 0 mJ/cm² to 20.0 mJ/cm², via a reflection-type mask with a 1:1 line-and-space pattern having a line width of 50 nm, and then baking was performed at 110° C. for 90 seconds. Thereafter, the organic-based developer described in the table below was developed for 30 seconds by paddling, rinsing was performed using the rinse liquid described in the table below, a wafer was rotated at the number of revolutions of 4,000 rpm for 30 seconds, and baking was performed at 90° C. for 60 seconds, so as to form a pattern.

An exposure amount that reproduces a 1:1 line-and-space mask pattern having a line width of 50 nm was set to be sensitivity. As this value is smaller, the sensitivity becomes high.

[Resolving Power]

A marginal resolving power (minimum line width in which a line and a space are separately resolved) in the exposure amount indicating the sensitivity above was set to be resolving power (nm).

[Pattern Form]

A cross-sectional form of a 1:1 line-and-space resist pattern having a line width of 50 nm in the exposure amount indicating the sensitivity above was observed by using a scanning electron microscope (S-4300 manufactured by Hitachi, Ltd.). In the cross-sectional form of the line pattern, a form of which the ratio expressed by [line width in a top portion (surface portion) of a line pattern/line width in a middle portion (a position in a half height of a height of a line pattern) of a line pattern] was 1.5 or greater was evaluated as a “reverse taper”, a form having the ratio of 1.2 or greater and less than 1.5 was evaluated as an “almost reverse taper”, and a form having the ratio of less than 1.2 was evaluated as a “rectangle shape”.

[LER]

A 1:1 line-and-space resist pattern having a line width of 50 nm was formed in the exposure amount indicating the sensitivity above. In addition, with respect to arbitrary 30 points included in 10 μm in the length direction, the distance from a reference line which had to have an edge was measured by using the scanning electron microscope (S-9220 manufactured by Hitachi, Ltd.). Also, standard deviation of the distance was obtained, so as to calculate 3σ. The smaller value indicates a more satisfactory performance.

[Outgassing Performance: Film Thickness Variation Rate after Exposure]

A line pattern (L/S=1/1) having a line width of 50 nm was formed in the exposure amount (mJ/cm²) indicating the sensitivity above, film thickness after exposure (before post baking) was measured and a variation rate from the film thickness at the time of being unexposed was obtained from the formula below.

Film thickness variation rate (%)=[(film thickness at the time of being unexposed−film thickness after exposure)/film thickness at the time of being unexposed]×100

(Determination Criteria)

A: A film thickness variation rate was less than 5%.

B: A film thickness variation rate was 5% to 10%.

C: A film thickness variation rate was greater than 10%.

[Temporal Stability]

After the resist composition was preserved at room temperature for one month, a degree of sensitivity variation was visually evaluated according to the determination criteria below.

(Determination Criteria)

A: An observed sensitivity variation was less than 1 mJ/cm².

B: An observed sensitivity variation was 1 mJ/cm² to 3 mJ/cm².

C: An observed sensitivity variation was greater than 3 mJ/cm².

### Example 2G to Example 12G, and Comparative Example 1G to Comparative Example 3G

### EUV Exposure; Organic Solvent Development Type (Negative Type)

In the resist liquid formulation, in the same manner as in Example 1G except for the components described in the table below, the preparation of the resist solution (negative resist compositions 2R to 12R, negative resist comparative compositions 1R to 3R for developing organic solvents), negative patterning and evaluation thereof were performed.

TABLE 8
[EUV Exposure; Organic solvent development type (Negative type)]

| | | | Basic compound | Surfactant | Solvent (molar |
|---|---|---|---|---|---|
| Composition | Acid generator | Compound (P) | (0.02 g) | (0.001 g) | ratio) (9.0 g) |
| 1R | A2 (0.12 g) | P-31 (0.6 g) | B2 | W-1 | S1/S2 (6/4) |
| 2R | A1 (0.12 g) | P-31 (0.6 g) | B2 | W-1 | S1/S2/S6 (6/3/1) |
| 3R | A7 (0.12 g) | P-32 (0.6 g) | B2 | W-2 | S1/S7 (6/4) |
| 4R | A8 (0.12 g) | P-34 (0.6 g) | B3 | W-2 | S1/S2 (6/4) |
| 5R | A10 (0.12 g) | P-35 (0.6 g) | B4 | W-3 | S1/S2 (6/4) |
| 6R | A11 (0.12 g) | P-36 (0.6 g) | B5 | W-1 | S1/S2 (6/4) |
| 7R | A13 (0.12 g) | P-37 (0.6 g) | B3 | W-3 | S1/S2 (6/4) |
| 8R | A2/A1 | P-1/P-6 | B6 | None | S1/S2 (6/4) |
| | (0.06 g/0.06 g) | (0.3 g/0.3 g) | | | |
| 9R | A14 (0.12 g) | P-38 (0.6 g) | B5 | W-1 | S1/S2 (6/4) |
| 10R | A2 (0.12 g) | P-33 (0.6 g) | B4 | W-1 | S1/S2 (6/4) |
| 11R | A6 (0.12 g) | P-39 (0.6 g) | B6 | W-1 | S1/S2 (6/4) |
| 12R | A2 (0.12 g) | P-40 (0.6 g) | B2 | W-1 | S1/S2 (6/4) |
| Comparative | Comparative | P-1 (0.6 g) | B2 | W-1 | S1/S2 (6/4) |
| Composition 1R | Compound 1 | | | | |
| | (0.12 g) | | | | |
| Comparative | Comparative | P-1 (0.6 g) | B2 | W-1 | S1/S2 (6/4) |
| Composition 2R | Compound 2 | | | | |
| | (0.12 g) | | | | |
| Comparative | Comparative | P-1 (0.6 g) | B2 | W-1 | S1/S2 (6/4) |
| Composition 3R | Compound 3 | | | | |
| | (0.12 g) | | | | |

Components (compounds) other than those described above used in the examples and the comparative examples are described below.

[Compound (P)]

Structures, composition ratios (molar ratios), weight average molecular weights (Mw), and dispersity (Mw/Mn) of the used compound (P) are provided below.

Structures, composition ratios (molar ratios), weight average molecular weights (Mw), and dispersity (Mw/Mn) of P-1 and P-6 are as described above.

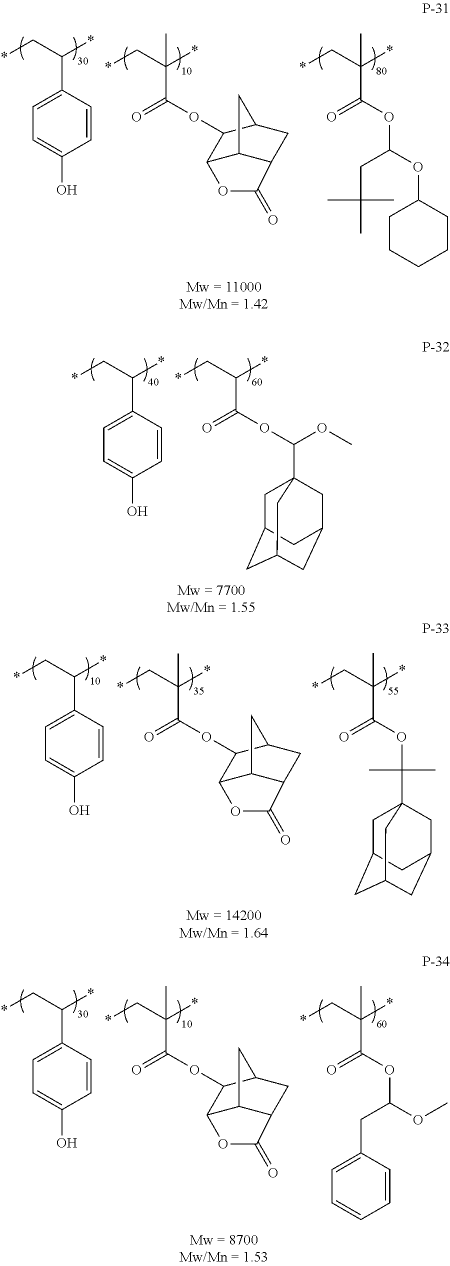

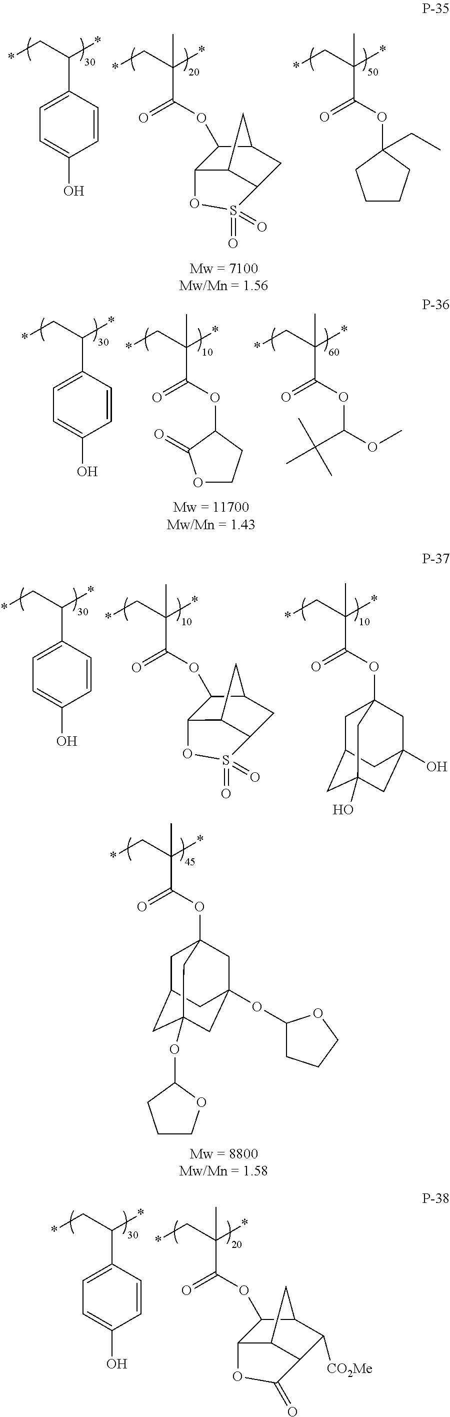

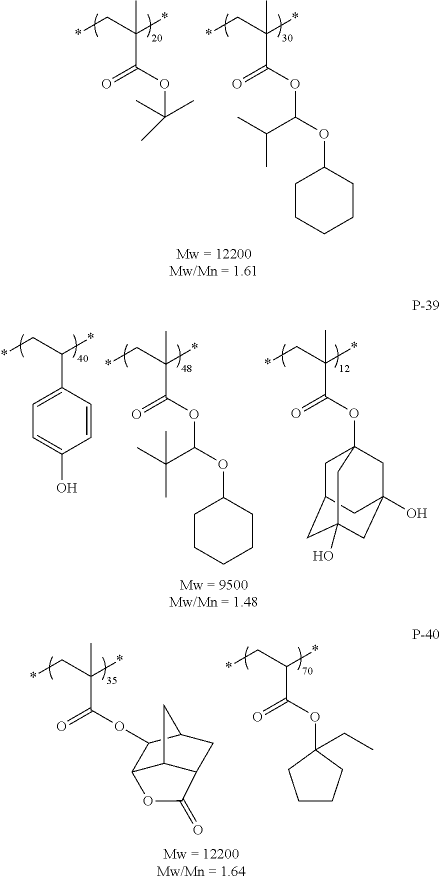

Evaluation results are provided in the table below.

TABLE 9
(EUV Exposure; Organic solvent development type)

| | | | Rinse | Sensitivity | Resolving power | | LER | Out- | Temporal |
|---|---|---|---|---|---|---|---|---|---|
| Example | Composition | Developer | liquid | (mJ/cm²) | (nm) | Pattern form | (nm) | gassing | stability |
| 1G | 1R | SG-3 | — | 10.8 | 20 | Rectangular | 3.5 | A | A |
| 2G | 2R | SG-3 | — | 10.8 | 20 | Rectangular | 3.5 | A | A |
| 3G | 3R | SG-3 | — | 10.8 | 20 | Rectangular | 3.5 | A | A |
| 4G | 4R | SG-2 | SR-1 | 11.7 | 20 | Rectangular | 3.5 | A | A |
| 5G | 5R | SG-1 | SR-2 | 10.8 | 25 | Almost | 4.0 | A | B |
| | | | | | | reverse taper | | | |
| 6G | 6R | SG-3 | SR-3 | 10.8 | 25 | Almost | 4.0 | A | A |
| | | | | | | reverse taper | | | |
| 7G | 7R | SG-3 | — | 11.9 | 20 | Rectangular | 3.5 | A | A |
| 8G | 8R | SG-3 | — | 11.9 | 20 | Rectangular | 3.5 | A | A |
| 9G | 9R | SG-3 | — | 10.9 | 20 | Rectangular | 3.5 | A | A |
| 10G | 10R | SG-3 | — | 10.8 | 20 | Rectangular | 3.5 | A | A |
| 11G | 11R | SG-3 | — | 10.8 | 20 | Rectangular | 3.5 | A | A |
| 12G | 12R | SG-3 | — | 11.0 | 20 | Rectangular | 3.5 | A | A |
| Comparative | Comparative | SG-3 | — | 15.8 | 40 | Reverse taper | 5.0 | B | C |
| Example 1G | Composition 1R | | | | | | | | |
| Comparative | Comparative | SG-3 | — | 15.3 | 40 | Reverse taper | 5.0 | B | C |
| Example 2G | Composition 2R | | | | | | | | |
| Comparative | Comparative | SG-3 | — | 15.8 | 40 | Reverse taper | 5.0 | C | A |
| Example 3G | Composition 3R | | | | | | | | |

Components (compounds) other than those described above used in the examples and the comparative examples are described below.

[Developer]

As the developer, the following were used.

SG-1: 2-Nonanone

SG-2: Methylamylketone (2-heptanone)

SG-3: Butyl acetate

[Rinse Liquid]

As the rinse liquid, the following were used.

SR-1: 4-Methyl-2-pentanol

SR-2: 1-Hexanol

SR-3: Methylisobutylcarbinol

As can be clearly understood from the results shown in the table above, it is understood that in Comparative Examples 1G to 3G in which using acid generators that did not satisfy General Formula (I) were used, sensitivity and resolving power were also inferior, the patterns were a reverse taper shape, LER was great, and the generation of outgassing was great, and with respect to Comparative Examples 1G and 2G, temporal stability was also inferior,

Meanwhile, it was understood that, in Examples 1G to 12G in which the compound expressed by General Formula (I) was used as the acid generator, sensitivity and resolving power were excellent, patterns were a rectangle shape, LER was small, the generation of outgassing was small, and temporal stability was excellent.

### INDUSTRIAL APPLICABILITY

According to the invention, in the ultrafine (for example, line width of 50 nm or less) patterning, it is possible to provide a resist composition for the semiconductor manufacturing process having high sensitivity and resolving power, small LER, an excellent pattern form, and excellent temporal stability, and decreased generation of outgassing.

According to the invention, it is possible to provide a resist film, a resist-coated mask blank, a photomask, a resist patterning method, an electronic-device manufacturing method, and an electronic device which use the resist composition for a semiconductor manufacturing process described above.

The invention was described in detail with reference to specific embodiments, but it is clear to a person skilled in the art that various modification and changes can be made without departing from the gist and the scope of the invention.

This application is based on Japanese patent application (JP2013-148762) filed on Jul. 17, 2013, and the entire contents thereof is incorporated herein by reference.

What is claimed is:

1. A resist composition for a semiconductor manufacturing process comprising:
(A) a compound expressed by General Formula (I) below: 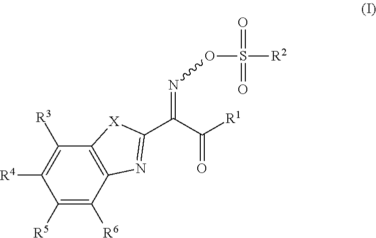
wherein, in General Formula (I) above,
R¹ represents an alkyl group, a cycloalkyl group, or an aryl group,
R² represents a univalent organic group,
each of R³ to R⁶ represents a hydrogen atom, an alkyl group, a cycloalkyl group, an aryl group, or a halogen atom, R³ and R⁴, R⁴ and R⁵, or R⁵ and R⁶ may be bonded to each other to form an alicyclic ring or an aromatic ring, and
X represents an oxygen atom or a sulfur atom.

2. The resist composition for a semiconductor manufacturing process according to claim 1,
wherein R¹ represents an alkyl group having 3 to 10 carbon atoms, a cycloalkyl group having 3 to 10 carbon atoms, and an aryl group having 6 to 12 carbon atoms.

3. The resist composition for a semiconductor manufacturing process according to claim 1,
wherein R¹ represents an alkyl group having a branch structure, a cycloalkyl group, or a phenyl group.

4. The resist composition for a semiconductor manufacturing process according to claim 1, further comprising:
(P) a compound having a phenolic hydroxy group.

5. The resist composition for a semiconductor manufacturing process according to claim 1,
wherein the compound (P) is a resin having a repeating unit expressed by General Formula (1) below: 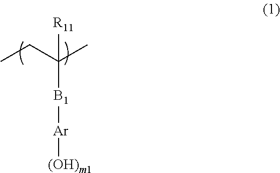
wherein, in General Formula (1) above,
R₁₁ represents a hydrogen atom, a methyl group, or a halogen atom,
B₁ represents a single bond or a bivalent linking group,
Ar represents an aromatic ring, and
m1 represents an integer of 1 or greater.

6. The resist composition for a semiconductor manufacturing process according to claim 1, further comprising:
(C) an acid crosslinking compound.

7. The resist composition for a semiconductor manufacturing process according to claim 6,
wherein the compound (C) includes 2 or more of hydroxymethyl groups or alkoxymethyl groups in a molecule.

8. The resist composition for a semiconductor manufacturing process according to claim 1,
wherein the resist composition is for exposure with electron beams or extreme ultraviolet rays.

9. A resist film which is formed of the resist composition for a semiconductor manufacturing process according to claim 1.

10. A resist-coated mask blank which is coated with the resist film according to claim 9.

11. A photomask obtained by exposing and developing the resist-coated mask blank according to claim 10.

12. A resist patterning method comprising:
a step of exposing the resist film according to claim 9; and
a step of developing the exposed film.

13. A resist patterning method comprising:
a step of exposing the resist-coated mask blank according to claim 10; and
a step of developing the exposed mask blank.

14. An electronic-device manufacturing method comprising:
the resist patterning method according to claim 12.

15. An electronic device manufactured by the electronic-device manufacturing method according to claim 14.
